(19) United States
(12) Patent Application Publication
(10) Pub. No.: US 2026/0362748 A1
(43) Pub. Date: Nov. 12, 2026

(54) Semiconductor Device And Method For Manufacturing Semiconductor Device

(71) Applicant: Semiconductor Energy Laboratory Co., Ltd., Kanagawa-ken (JP)

(72) Inventors: Shunpei YAMAZAKI, Tokyo (JP); Hiromichi GODO, Isehara (JP); Yuji EGI, Atsugi (JP)

(73) Assignee: Semiconductor Energy Laboratory Co., Ltd., Kanagawa-ken (JP)

(21) Appl. No.: 19/668,145

(22) Filed: May 5, 2026

(30) Foreign Application Priority Data
May 9, 2025 (JP) 2025-078691

(51) Int. Cl. H10D 30/67; H10B 12/00; H10D 1/68; H10D 30/00; H10D 30/01; H10D 86/00; H10D 86/01; H10D 86/40; H10D 86/60; H10K 59/121; H10K 59/123; H10W 20/41

(52) U.S. Cl. CPC H10D 30/6755; H10D 30/502; H10D 30/6728; H10D 30/6731; H10D 30/6732; H10D 30/6734; H10D 30/6736; H10D 30/6757; H10B 12/30; H10D 1/714; H10D 30/0312; H10D 30/0314; H10D 30/0316; H10D 30/0318; H10D 86/0221; H10D 86/201; H10D 86/423; H10D 86/481; H10D 86/60; H10K 59/1213; H10K 59/123; H10W 20/435

(57) ABSTRACT

A semiconductor device having favorable electrical characteristics is provided. The semiconductor device includes a first metal oxide layer, a second metal oxide layer, a first insulating layer, and a conductive layer. The first insulating layer is over the first metal oxide layer. The conductive layer is over the first insulating layer. The second metal oxide layer is in contact with the first metal oxide layer. The first metal oxide layer contains indium. The second metal oxide layer contains indium and divalent silicon oxide. Alternatively, the second metal oxide layer contains indium and divalent silicon.

### BACKGROUND OF THE INVENTION

### 1. Field of the Invention

One embodiment of the present invention relates to a semiconductor device, a memory device, a display device, and an electronic apparatus. One embodiment of the present invention relates to a method for manufacturing a semiconductor device.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be said that a display device (e.g., a liquid crystal display device and a light-emitting display device), a projection device, a lighting device, an electro-optical device, a power storage device, a memory device, a semiconductor circuit, an imaging device, an electronic apparatus, and the like include a semiconductor device in some cases.

Note that one embodiment of the present invention is not limited to the above technical field. One embodiment of the invention disclosed in this specification and the like relates to an object, a method, or a manufacturing method. Furthermore, one embodiment of the present invention relates to a process, a machine, manufacture, or a composition of matter.

### 2. Description of the Related Art

In recent years, semiconductor devices have been developed and mainly used for a large scale integration (LSI), a central processing unit (CPU), a memory, and the like. A CPU is an aggregation of semiconductor elements; the CPU includes a semiconductor integrated circuit (including at least a transistor and a capacitor) formed into a chip by processing a semiconductor wafer, and is provided with an electrode that is a connection terminal.

A semiconductor circuit (an IC chip) such as an LSI, a CPU, or a memory is mounted on a circuit board, for example, a printed wiring board, and used as one of components of a variety of electronic apparatuses.

A technique by which a transistor is formed using a semiconductor thin film formed over a substrate having an insulating surface has been attracting attention. The transistor is used in a wide range of electronic devices such as an integrated circuit and an image display device (also simply referred to as a display device). A silicon-based semiconductor material is widely known as a material of a semiconductor thin film that can be used in a transistor. As another material, an oxide semiconductor has been attracting attention.

It is known that a transistor using an oxide semiconductor has an extremely low leakage current in a non-conduction state. For example, Patent Document 1 discloses a low-power CPU utilizing the characteristic of a low leakage current of a transistor using an oxide semiconductor. Patent Document 2 discloses a memory device or the like that uses an oxide semiconductor and can retain stored data for a long time.

Non-Patent Document 1 reports use of In₂O₃ for a thin film transistor. Non-Patent Document 2 discloses a thin film transistor in which hydrogenated polycrystal indium oxide formed by low-temperature solid phase crystallization is used for an active layer. Non-Patent Document 3 discloses a thin film transistor in which indium oxide formed by an atomic layer deposition (ALD) method is used for an active layer.

### REFERENCES

### Patent Documents

[Patent Document 1] Japanese Published Patent Application No. 2012-257187
[Patent Document 2] Japanese Published Patent Application No. 2011-151383

### Non-Patent Documents

[Non-Patent Document 1] Dhananjay and C. W. Chu, “Realization of In₂O₃ thin film transistors through reactive evaporation process”, Appl. Phys. Lett. 91, 132111 (2007).
[Non-Patent Document 2]Y. Magari et al., “High-mobility hydrogenated polycrystalline In₂O₃ (In₂O₃. H) thin-film transistors”, Nature Communications 13, 1078, (2022).
[Non-Patent Document 3]J. Y. Lin et al., “First Demonstration of Top-Gate Enhancement-Mode ALD In₂O₃ FETs With High Thermal Budget of 600 °C for DRAM Applications”, IEEE Electron Device Letters, 45, 10, pp. 1851-1854 (2024).
[Non-Patent Document 4] Takashi Koida, “High-mobility transparent conductive film”, National Institute of Advanced Industrial Science and Technology, AIST Photovoltaic Technology Research Symposium 2019, Internet URL: https://unit.aist.go.jp/rpd-envene/PV/ja/results/2019/oral/T13.pdf

### SUMMARY OF THE INVENTION

An object of one embodiment of the present invention is to provide a metal oxide layer with high carrier mobility. An object of one embodiment of the present invention is to provide a novel metal oxide layer. An object of one embodiment of the present invention is to provide a transistor, semiconductor device, or memory device including a metal oxide layer.

An object of one embodiment of the present invention is to provide a transistor having favorable electrical characteristics. An object of one embodiment of the present invention is to provide a transistor having a high on-state current. An object of one embodiment of the present invention is to provide a transistor having small parasitic capacitance. An object of one embodiment of the present invention is to provide a semiconductor device including a transistor having excellent characteristics. An object of one embodiment of the present invention is to provide a semiconductor device having excellent characteristics. An object of one embodiment of the present invention is to provide a highly reliable transistor, semiconductor device, display device, or memory device. An object of one embodiment of the present invention is to provide a transistor, semiconductor device, or memory device which can be scaled down or highly integrated. An object of one embodiment of the present invention is to provide a semiconductor device, display device, or memory device with low power consumption. An object of one embodiment of the present invention is to provide a memory device with high operating speed. An object of one embodiment of the present invention is to provide a semiconductor device with high layout flexibility of transistors.

An object of one embodiment of the present invention is to provide a semiconductor device having a novel structure. An object of one embodiment of the present invention is to at least alleviate at least one of problems in the conventional art.

Note that the description of these objects does not preclude the existence of other objects. In one embodiment of the present invention, there is no need to achieve all of these objects. Objects other than these can be derived from the description of the specification, the drawings, the claims, and the like.

One embodiment of the present invention is a semiconductor device including a first metal oxide layer, a second metal oxide layer, a first insulating layer, and a conductive layer. The first insulating layer is over the first metal oxide layer. The conductive layer is over the first insulating layer. The second metal oxide layer is in contact with the first metal oxide layer. The first metal oxide layer contains indium. The second metal oxide layer contains indium and divalent silicon oxide.

One embodiment of the present invention is a semiconductor device including a first metal oxide layer, a second metal oxide layer, a first insulating layer, and a conductive layer. The first insulating layer is over the first metal oxide layer. The conductive layer is over the first insulating layer. The second metal oxide layer is in contact with the first metal oxide layer. The first metal oxide layer contains indium. The second metal oxide layer contains indium and divalent silicon.

In the above semiconductor device, the second metal oxide layer is preferably below the first metal oxide layer.

The above semiconductor device preferably includes a third metal oxide layer between the first metal oxide layer and the first insulating layer. The third metal oxide layer preferably has a lower electron affinity than the first metal oxide layer.

In the above semiconductor device, the third metal oxide layer preferably contains indium and gallium.

The above semiconductor device preferably includes a second insulating layer in contact with a bottom surface of the second metal oxide layer. The second insulating layer preferably contains silicon and oxygen.

In the above semiconductor device, the second metal oxide layer is preferably between the first metal oxide layer and the first insulating layer.

Another embodiment of the present invention is a method for manufacturing a semiconductor device, which includes a first step of forming a first insulating layer containing silicon and oxygen, a second step of forming a first metal oxide layer over the first insulating layer, and a third step of forming a second metal oxide layer over the first metal oxide layer. The first, second, and third steps are performed sequentially. The first metal oxide layer and the second metal oxide layer are each formed by a sputtering method using an indium oxide sputtering target. The first metal oxide layer is formed at a higher power than the second metal oxide layer to add divalent silicon oxide to the first metal oxide layer.

Another embodiment of the present invention is a method for manufacturing a semiconductor device, which includes a first step of forming a first insulating layer containing silicon and oxygen, a second step of forming a first metal oxide layer over the first insulating layer, and a third step of forming a second metal oxide layer over the first metal oxide layer. The first, second, and third steps are performed sequentially. The first metal oxide layer is formed by a sputtering method using an indium oxide sputtering target to add divalent silicon oxide to the first metal oxide layer. The second metal oxide layer is formed by an atomic layer deposition method using an oxidizer and a precursor containing indium.

Another embodiment of the present invention is a method for manufacturing a semiconductor device, which includes a first step of forming a first insulating layer, a second step of forming a first metal oxide layer over the first insulating layer, and a third step of forming a second metal oxide layer over the first metal oxide layer. The first, second, and third steps are performed sequentially. The first metal oxide layer and the second metal oxide layer are each formed by an atomic layer deposition method using an oxidizer and a first precursor containing indium. Delta doping is performed in forming the first metal oxide layer to add divalent silicon oxide to the first metal oxide layer.

In the above method for manufacturing a semiconductor device, the second step preferably includes a fourth step of introducing the first precursor and introducing the oxidizer after the introduction of the first precursor and a fifth step of introducing a second precursor containing silicon. The fifth step is preferably performed a smaller number of times than the fourth step.

In the above semiconductor device, the conductive layer can include a region functioning as a gate electrode, and the first insulating layer can include a region functioning as a gate insulating layer.

One embodiment of the present invention can provide a metal oxide layer with high carrier mobility. One embodiment of the present invention can provide a novel metal oxide layer. One embodiment of the present invention can provide a transistor, semiconductor device, or memory device including a metal oxide layer.

One embodiment of the present invention can provide a transistor having favorable electrical characteristics. One embodiment of the present invention can provide a transistor having a high on-state current. One embodiment of the present invention can provide a transistor having small parasitic capacitance. One embodiment of the present invention can provide a semiconductor device including a transistor having excellent characteristics. One embodiment of the present invention can provide a semiconductor device having excellent characteristics. One embodiment of the present invention can provide a highly reliable transistor, semiconductor device, display device, or memory device. One embodiment of the present invention can provide a transistor, semiconductor device, or memory device which can be scaled down or highly integrated. One embodiment of the present invention can provide a semiconductor device, display device, or memory device with low power consumption. One embodiment of the present invention can provide a memory device with high operating speed. One embodiment of the present invention can provide a semiconductor device with high layout flexibility of transistors.

One embodiment of the present invention can provide a semiconductor device having a novel structure. One embodiment of the present invention can at least alleviate at least one of problems in the conventional art.

Note that the description of these effects does not preclude the existence of other effects. One embodiment of the present invention does not necessarily have all of these effects. Effects other than these can be derived from the description of the specification, the drawings, the claims, and the like.

### BRIEF DESCRIPTION OF THE DRAWINGS

FIGS. 1A to 1F illustrate structure examples of a semiconductor device.

FIGS. 2A and 2B each show part of the periodic table, and FIG. 2C illustrates a crystal structure of indium oxide.

FIGS. 3A to 3C illustrate a structure example of a semiconductor device.

FIGS. 4A and 4B illustrate structure examples of a semiconductor device.

FIGS. 5A to 5C illustrate structure examples of a semiconductor device.

FIGS. 6A and 6B illustrate structure examples of a semiconductor device.

FIGS. 7A to 7C illustrate structure examples of a semiconductor device.

FIGS. 8A and 8B illustrate structure examples of a semiconductor device.

FIG. 9 illustrates a structure example of a semiconductor device.

FIGS. 10A and 10B illustrate structure examples of a semiconductor device.

FIGS. 11A and 11B illustrate structure examples of a semiconductor device.

FIGS. 12A to 12C illustrate structure examples of a semiconductor device.

FIGS. 13A to 13C illustrate structure examples of a semiconductor device.

FIGS. 14A to 14C illustrate structure examples of a semiconductor device.

FIGS. 15A to 15D illustrate structure examples of a semiconductor device.

FIGS. 16A and 16B illustrate structure examples of a semiconductor device.

FIG. 17 illustrates a structure example of a semiconductor device.

FIGS. 18A and 18B are cross-sectional views illustrating an example of a semiconductor device.

FIGS. 19A and 19B show the dependence of Hall mobility on carrier concentration, and FIG. 19C is a cross-sectional view illustrating an indium oxide film.

FIG. 20 illustrates a structure example of a memory device.

FIGS. 21A and 21B illustrate a structure example of a memory device.

FIGS. 22A and 22B illustrate a structure example of a display device.

FIG. 23 illustrates a structure example of a display device.

FIGS. 24A and 24B illustrate a structure example of a pixel circuit.

FIGS. 25A to 25F illustrate structure examples of pixel circuits.

FIGS. 26A to 26D illustrate structure examples of pixel circuits.

FIGS. 27A to 27D illustrate structure examples of pixel circuits.

FIGS. 28A and 28B illustrate structure examples of a pixel circuit.

FIGS. 29A and 29B illustrate structure examples of a pixel circuit.

FIGS. 30A and 30B illustrate structure examples of a pixel circuit.

FIGS. 31A to 31D illustrate structure examples of electronic apparatuses.

FIGS. 32A to 32F illustrate structure examples of electronic apparatuses.

FIGS. 33A to 33G illustrate structure examples of electronic apparatuses.

FIGS. 34A and 34B are perspective views of a semiconductor device.

FIG. 35 is a perspective view of a semiconductor device.

FIGS. 36A and 36B illustrate structure examples of electronic components.

FIGS. 37A to 37C illustrate a structure example of a large computer.

### DETAILED DESCRIPTION OF THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of the embodiments below.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of current or voltage, a switching operation for controlling conduction or non-conduction, and the like. A transistor in this specification includes, in its category, an insulated-gate field effect transistor (IGFET) and a thin film transistor (TFT).

The functions of a “source” and a “drain” are sometimes replaced with each other when a transistor of different polarity is used or when the direction of current flow is changed in a circuit operation, for example. Thus, the terms “source” and “drain” can be used interchangeably in this specification.

In this specification and the like, the expression “electrically connected” includes the case where components are connected through an “object having any electric function”. There is no particular limitation on the “object having any electric function” as long as electric signals can be transmitted and received between components that are connected through the object.

Examples of the “object having any electric function” are a switching element such as a transistor, a resistor, a coil, and an element with a variety of functions as well as an electrode and a wiring.

Note that in this specification and the like, “electrical connection” does not include the case where two nodes are connected to each other with an insulator (e.g., a dielectric of a capacitor, a gate insulating film of a transistor, or an interlayer insulating film) provided between the two nodes.

In this specification and the like, the expression “level with” indicates components having the same level from a reference surface (e.g., a flat surface such as a substrate surface) in a cross-sectional view. For example, the expression “level with” also includes the case where two layers (here, a layer A and a layer B) have different levels with respect to a reference surface and the difference in the top-surface level between the layer A and the layer B is less than or equal to 10 nm.

In this specification and the like, the expression “side end portions are aligned with each other” indicates that at least outlines of stacked layers partly overlap with each other in a plan view. For example, the expression “side end portions are aligned with each other” also includes the case where two layers (here, a layer A and a layer B) are stacked and the shortest distance between a side end portion of the layer A and a side end portion of the layer B is less than or equal to 10 nm in a plan view.

In general, it is sometimes difficult to clearly differentiate “completely aligned” from “substantially aligned”. Thus, in this specification and the like, the expression “aligned” sometimes includes both “completely aligned” and “substantially aligned”.

Note that in this specification and the like, a top surface shape of a component means the outline of the component in a plan view. A plan view means a view to observe the component from a normal direction of a surface where the component is formed or from a normal direction of a surface of a support (e.g., a substrate) where the component is formed.

Note that the expressions indicating directions such as “over” and “under” are basically used to correspond to the directions of drawings. However, in some cases, the term “over” or “under” in the specification indicates a direction that does not correspond to the apparent direction in the drawings, for the purpose of easy description or the like. For example, in the description of the stacked order (formation order) of a stacked body or the like, even in the case where a surface on which the stacked body is provided (e.g., a formation surface, a support surface, a bonding surface, or a planarization surface) is positioned over the stacked body in the drawings, the following expressions are used in some cases: the formation surface side is under the stacked body or the stacked body side is over the formation surface side.

In this specification and the like, the terms “film” and “layer” can be interchanged with each other. For example, in some cases, the term “insulating layer” can be interchanged with the term “insulating film”.

Unless otherwise specified, an off-state current in this specification and the like refers to a drain current of a transistor in an off state (also referred to as a non-conduction state or a cutoff state). Unless otherwise specified, the off state of an n-channel transistor means that gate-source voltage Vgs is lower than threshold voltage Vth, and the off state of a p-channel transistor means that Vgs is higher than Vth.

In this specification and the like, a space group is represented using the short symbol of the international notation (or the Hermann-Mauguin notation). In addition, the Miller index is used for the expression of crystal planes and crystal orientations. In the crystallography, a bar is placed over a number in the expression of space groups, crystal planes, and crystal orientations; in this specification and the like, because of format limitations, space groups, crystal planes, and crystal orientations are sometimes expressed by placing a minus sign (−) in front of a number instead of placing a bar over the number. Furthermore, an individual orientation that shows an orientation in crystal is expressed with “[ ]”, a set orientation that shows all of the equivalent orientations is expressed with “< >”, an individual plane that shows a crystal plane is expressed with “( )”, and a set plane having equivalent symmetry is expressed with “{ }”.

### Embodiment 1

Described in this embodiment are structure examples of a semiconductor device of one embodiment of the present invention and a manufacturing method example thereof.

The semiconductor device of one embodiment of the present invention includes a first metal oxide layer, a second metal oxide layer, a first insulating layer, and a conductive layer. The first insulating layer is positioned over the first metal oxide layer, and the conductive layer is positioned over the first insulating layer. The second metal oxide layer is in contact with the first metal oxide layer.

The semiconductor device of one embodiment of the present invention includes a transistor. The conductive layer includes a portion functioning as a gate electrode of the transistor, the first insulating layer includes a portion functioning as a gate insulating layer of the transistor, and the first metal oxide layer includes a portion functioning as a semiconductor layer of the transistor. The second metal oxide layer functions as the semiconductor layer of the transistor in some cases.

The first metal oxide layer contains indium. In this case, the first metal oxide layer contains indium oxide. The transistor containing indium oxide in the semiconductor layer can have higher field-effect mobility and a higher on-state current. Furthermore, the transistor having at least one of favorable electrical characteristics, favorable frequency characteristics, and favorable reliability can be provided.

The second metal oxide layer preferably contains indium and a partial structure (also referred to as an atomic group). The second metal oxide layer preferably contains indium oxide having the partial structure. The partial structure is a partial structure forming negative charge in the metal oxide layer or a partial structure reducing the carrier concentration of the indium oxide, and is typically divalent silicon oxide (also referred to as Si═O or SiO(II)). The indium oxide containing divalent silicon oxide is provided in contact with the semiconductor layer, whereby the metal oxide layer in which negative charge is formed can be provided in the vicinity of a channel. Alternatively, the carrier concentration of the semiconductor layer can be reduced. Thus, the threshold voltage of the transistor can be shifted positively. Moreover, the transistor can have normally-off characteristics. Accordingly, the transistor having favorable electrical characteristics can be provided.

Note that the second metal oxide layer can contain indium and divalent silicon (also referred to as Si(II)). The second metal oxide layer containing divalent silicon can have an effect similar to that of the second metal oxide layer containing divalent silicon oxide.

The second metal oxide layer can be positioned below the first metal oxide. Alternatively, the second metal oxide layer can be positioned between the first metal oxide layer and the first insulating layer.

The semiconductor device of one embodiment of the present invention can include a third metal oxide layer. The third metal oxide layer is positioned between the first metal oxide layer and the first insulating layer. The second metal oxide layer includes a region overlapping with the third metal oxide layer with the first metal oxide layer therebetween.

The electron affinity of the third metal oxide layer is preferably lower than that of the first metal oxide layer. With such a structure, a carrier flow path can be kept away from the interface between the first insulating layer and the third metal oxide layer, so that the influence of surface scattering can be reduced in some cases. As a result, the transistor can have a higher on-state current, higher reliability, or the like.

### Structure Example

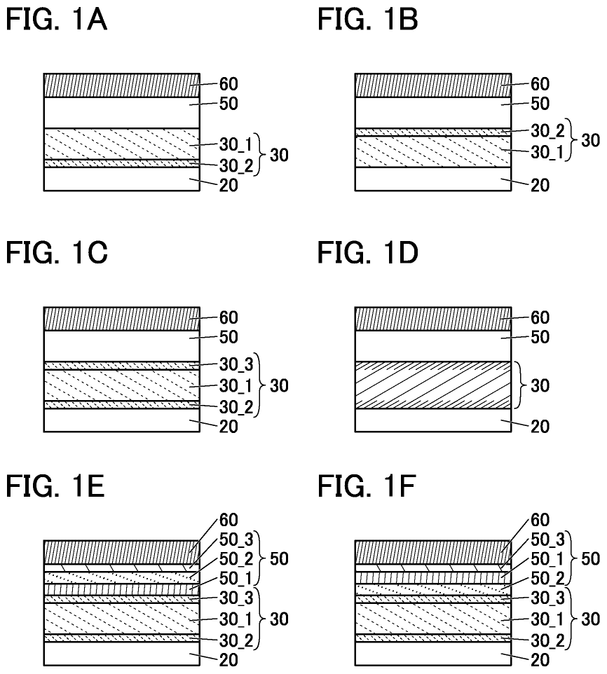

FIGS. 1A to 1F are schematic views illustrating structure examples of a semiconductor device of one embodiment of the present invention. FIGS. 1A to 1F are each a cross-sectional view of a semiconductor device including a transistor.

The semiconductor device of one embodiment of the present invention includes an insulating layer 20, a metal oxide layer 30, an insulating layer 50, and a conductive layer 60. The metal oxide layer 30 is positioned over the insulating layer 20, the insulating layer 50 is positioned over the metal oxide layer 30, and the conductive layer 60 is positioned over the insulating layer 50. In FIG. 1A, the metal oxide layer 30 is in contact with the top surface of the insulating layer 20, the insulating layer 50 is in contact with the top surface of the metal oxide layer 30, and the conductive layer 60 is in contact with the top surface of the insulating layer 50.

The conductive layer 60 includes a portion functioning as a gate electrode of the transistor, and the insulating layer 50 includes a portion functioning as a gate insulating layer of the transistor. The metal oxide layer 30 includes a channel formation region of the transistor. That is, the metal oxide layer 30 includes a portion functioning as a semiconductor layer of the transistor.

In the transistor of one embodiment of the present invention, the semiconductor layer including the channel formation region includes a metal oxide functioning as a semiconductor (such a metal oxide is also referred to as an oxide semiconductor). That is, the transistor can be regarded as an OS transistor. When oxygen vacancies (V_{O}), defects in which hydrogen enters oxygen vacancies (V_{O}H), and impurities are in the channel formation region in the oxide semiconductor in an OS transistor, the electrical characteristics of the OS transistor easily vary and the reliability thereof may worsen in some cases. Therefore, V_{O}, V_{O}H, and impurities are preferably reduced as much as possible in the channel formation region in the oxide semiconductor.

The band gap of the metal oxide layer 30 is preferably larger than that of silicon (typically 1.1 eV), and is preferably larger than or equal to 2 eV, further preferably larger than or equal to 2.5 eV. When a metal oxide layer having a larger band gap than silicon is used as the semiconductor layer of the transistor, the transistor can have a lower off-state current and higher withstand voltage. Since the OS transistor has a low off-state current, the power consumption of the semiconductor device can be sufficiently reduced.

The metal oxide layer 30 may have a single-layer structure or a stacked-layer structure of two or more layers. For example, the metal oxide layer 30 can have a two-layer structure of a metal oxide layer 30_1 and a metal oxide layer 30_2 in contact with the metal oxide layer 301. FIG. 1A illustrates an example in which the metal oxide layer 30_2 is positioned below the metal oxide layer 30_1 and the insulating layer 20 is in contact with the bottom surface of the metal oxide layer 302. Specifically, the metal oxide layer 30_2 is in contact with the top surface of the insulating layer 20, and the metal oxide layer 301 is in contact with the top surface of the metal oxide layer 30_2.

The metal oxide layer 30_1 preferably contains indium. Indium oxide is preferably used for the metal oxide layer 301. When indium oxide is used for the metal oxide layer 30_1 including the channel formation region of the transistor, the transistor can have higher field-effect mobility and a higher on-state current. Thus, the transistor can have high frequency characteristics.

The metal oxide layer 30_2 preferably contains indium and a partial structure. The partial structure is a partial structure forming negative charge in the metal oxide layer or a partial structure reducing the carrier concentration of indium oxide. An example of the partial structure is divalent silicon oxide (also referred to as Si═O or SiO(II)). The metal oxide layer 30_2 preferably contains indium and divalent silicon oxide, for example. Indium exists mainly as a trivalent cation in the metal oxide layer. Hence, when the divalent silicon oxide is substituted for an indium atom, negative charge can be formed in the metal oxide layer 302. Alternatively, the carrier concentration of the metal oxide layer 30 can be reduced. Thus, the threshold voltage of the transistor can be shifted positively. Moreover, the transistor can have normally-off characteristics. That is, by adjusting the amount of divalent silicon oxide, the threshold voltage of the transistor can be controlled. Accordingly, the transistor having favorable electrical characteristics can be provided.

The electron affinity of silicon oxide is lower than that of indium oxide; thus, the electron affinity of the metal oxide layer 30_2 containing Si═O is lower than that of the metal oxide layer 30_1 in some cases. In this case, the metal oxide layer 30_1 serves as a main current path in the transistor including the metal oxide layer 30 as the semiconductor layer. That is, the metal oxide layer 30_1 includes the channel formation region. With such a structure, the channel can be kept away from the surface of the insulating layer 20, so that the influence of surface scattering can be reduced. Thus, the transistor can have higher field-effect mobility and a higher on-state current.

Silicon can exist as a divalent cation as in dibromosilicon (Br₂Si). Thus, the metal oxide layer 30_2 can contain divalent silicon (also referred to as Si(II)) instead of the above partial structure. When the metal oxide layer 30_2 contains indium and divalent silicon, the divalent silicon is substituted for an indium atom, whereby negative charge can be formed in the metal oxide layer 302. Thus, such a metal oxide layer 30_2 can have an effect similar to that of the metal oxide layer 30_2 having the above partial structure. Note that silicon substituted for an indium atom is sometimes referred to as Sim. Thus, divalent silicon can also be referred to as Sim.

Formation of negative charge in the metal oxide layer 30_2 containing Si═O or Si(II) is presumably derived from a large band gap of indium oxide and silicon substituted for indium coordinated to six oxygen atoms. For example, the valence of Si═O is −1, which is the sum of a valence of −3 derived from an indium vacancy, a valence of +4 derived from silicon substituted for an indium atom, and a valence of −2 derived from oxygen between lattices or in a later-described structural interstitial position, presumably leading to formation of negative charge in the metal oxide layer 30_2. Alternatively, the valence of Si═O is −1, which is the sum of a valence of −3 derived from an indium vacancy, a valence of +2 derived from silicon substituted for an indium atom, and a valence of 0 derived from oxygen between lattices or in a later-described structural interstitial position, presumably leading to formation of negative charge in the metal oxide layer 30_2. Alternatively, the valence of Si_{In} is −1, which is the sum of a valence of −3 derived from an indium vacancy and a valence of +2 derived from silicon substituted for an indium atom, presumably leading to formation of negative charge in the metal oxide layer 30_2.

Note that the metal oxide layer 30_2 may contain both Si═O and Si(II). In the case where the metal oxide layer 30_2 contains Si═O or Si(II), Si═O or Si(II) may also serve as part or the whole of a partial structure represented by InOX (Xis an integer greater than or equal to 1 and less than or equal to 5) in indium oxide.

Whether Si═O or Si(II) exists in the metal oxide layer can be evaluated from the valence of a silicon atom or the number of oxygen atoms bonded to a silicon atom (also referred to as the coordination number of oxygen atoms with respect to a silicon atom). Note that the coordination number of oxygen atoms with respect to a silicon atom can be evaluated from the chemical bonding state between the silicon atom and the oxygen atom. The valence of an atom or the chemical bonding state between atoms can be evaluated by X-ray photoelectron spectroscopy (XPS), for example.

For example, in the case where the proportion of divalent silicon to silicon in the metal oxide layer 30_2 is greater than or equal to 0.001 and less than or equal to 1, the metal oxide layer 30_2 can be regarded as containing Si(II).

A silicon atom in silicon oxide is bonded to four oxygen atoms. That is, the coordination number of oxygen atoms with respect to a silicon atom is 4. Meanwhile, since Si═O also serves as part or the whole of InOX, the coordination number of oxygen atoms with respect to a silicon atom in the metal oxide layer 30_2 containing Si═O is not limited to 4 and can be 5 or 6. Thus, in the case where a silicon atom with respect to which the coordination number of oxygen atoms is 5 or 6 is detected in the metal oxide layer 302, the metal oxide layer 30_2 can be regarded as containing Si═O.

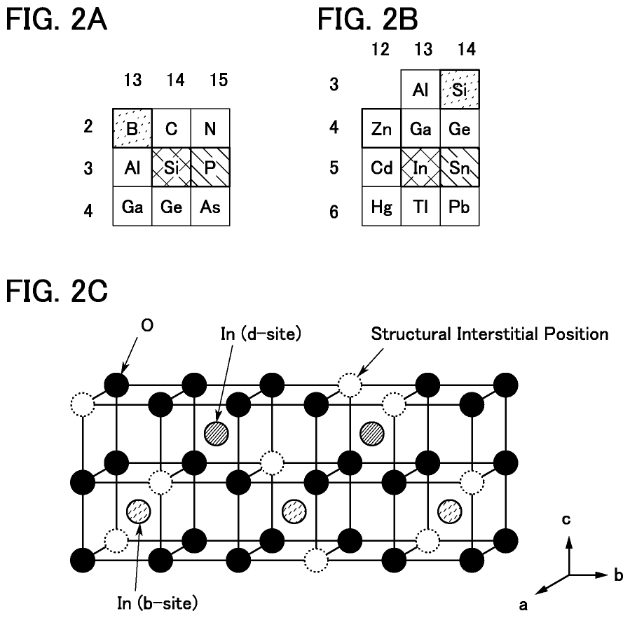

Here, elements to be added to a semiconductor are described with reference to FIGS. 2A to 2C. FIG. 2A shows elements belonging to both Periods 2 to 4 and Groups 13 to 15 of the periodic table. FIG. 2B shows elements belonging to both Periods 3 to 6 and Groups 12 to 14 of the periodic table.

FIG. 2C is a schematic view of an indium oxide crystal taken along the (100) plane. In FIG. 2C, lattice distortion is ignored. In addition, two kinds of sites (a d-site and a b-site) of indium (In) are distinguished from each other. Structural interstitial positions near In in the d-site are positioned face-diagonally. An octahedron formed of In in the d-site at the center and six oxygen (O) atoms around In has distortion. Structural interstitial positions near In in the b-site are positioned body-diagonally. An octahedron formed of In in the b-site at the center and six oxygen atoms around In does not have distortion. As illustrated in FIG. 2C, the indium oxide crystal includes structural interstitial positions. In the following description, when the d-site and the b-site are not distinguished from each other, they are each simply referred to as an indium site.

Silicon can function as an n-type semiconductor when doped with phosphorus. Indium oxide containing tin is a conductive oxide and is known to have n-type conductivity. In the periodic table, phosphorus (P) is on the right side of silicon (Si), and tin (Sn) is on the right side of indium (In). That is, in the periodic table, the positional relationship between Si and P corresponds to the positional relationship between In and Sn.

Silicon can function as a p-type semiconductor when doped with boron. In the periodic table, boron (B) is on the upper left side of silicon (Si). In consideration of these, according to the positional relationship between Si and B in the periodic table, zinc (Zn) in indium oxide is presumably an element corresponding to a p-type dopant for silicon. Zinc mainly exists as a divalent cation. Thus, a zinc atom positioned in at least one of the indium sites can presumably allow formation of negative charge in the metal oxide layer. Accordingly, it is presumed that with the metal oxide layer provided in the vicinity of the channel of the transistor, the threshold voltage of the transistor can be shifted positively.

It is possible that Si(II) existing as a divalent cation might have an effect similar to that of zinc. However, in the periodic table, the positional relationship between Si and B does not correspond to the positional relationship between In and Si. That is, addition of Si(II) to indium oxide cannot be conceived from the positional relationship between silicon and a p-type dopant in the periodic table.

The above is the description of the elements to be added to the semiconductor.

The metal oxide layer 302 can contain a first element in addition to or instead of indium. For example, the metal oxide layer 30_2 contains indium, the first element, and the above-described partial structure. Alternatively, the metal oxide layer 30_2 contains the first element and the above-described partial structure. The first element is more strongly bonded to oxygen than indium is and can be a trivalent cation. Examples of the first element include Group 13 elements in the periodic table such as gallium and aluminum and Group 3 elements in the periodic table such as scandium and yttrium. When the metal oxide layer 30_2 contains the first element, formation of V_{O} and V_{O}H in the metal oxide layer 30 can be inhibited while the carrier concentration of the metal oxide layer 30 is maintained. Thus, the threshold voltage of the transistor can be shifted positively. Moreover, the transistor can have normally-off characteristics. Accordingly, the transistor having favorable electrical characteristics can be provided.

The first element is preferably gallium or aluminum, further preferably gallium. Gallium and aluminum are suitable because they are strongly bonded to oxygen. Gallium is further suitable because the bond length between gallium and oxygen is close to that between indium and oxygen. Scandium oxide and yttrium oxide can each have a bixbyite crystal structure like indium oxide; thus, scandium and yttrium are suitable in terms of facilitating maintenance of the crystal structure of indium oxide even when the contents of scandium and yttrium are increased.

Examples of the metal oxide containing indium, the first element, and Si═O or Si(II) include indium gallium oxide, indium aluminum oxide, indium scandium oxide, indium yttrium oxide, and indium aluminum gallium oxide each containing silicon. Examples of the metal oxide containing the first element and Si═O or Si(II) include gallium oxide, aluminum oxide, scandium oxide, yttrium oxide, and aluminum gallium oxide each containing silicon.

The content of the first element in the metal oxide layer 30_2 is preferably higher than or equal to 1% and lower than or equal to 30%, further preferably higher than or equal to 1% and lower than or equal to 20%, still further preferably higher than or equal to 1% and lower than or equal to 10%, yet still further preferably higher than or equal to 1% and lower than or equal to 5%. When the content of the first element in the metal oxide layer 302 is too low, an effect of inhibiting formation of V_{O} and V_{O}H might be reduced. In contrast, when the content of the first element in the metal oxide layer 30_2 is too high, the on-state current of the transistor might be low.

In this specification and the like, the content of a certain metal element in a metal oxide layer refers to the proportion of the number of atoms of the metal element to the total number of metal element atoms contained in the metal oxide layer. For example, in the case where a metal oxide layer contains a metal element X, a metal element Y, and a metal element Z and the numbers of atoms of the metal element X, the numbers of atoms of the metal element Y, and the numbers of atoms of the metal element Z contained in the metal oxide layer are expressed as A_{X}, A_{Y}, and A_{Z}, the content of the metal element X can be represented by A_{X}/(A_{X}+A_{Y}+A_{Z}). Moreover, in the case where the atomic ratio between the metal element X, the metal element Y, and the metal element Z contained in the metal oxide layer is represented by B_{X}:B_{Y}:B_{Z}, the content of the metal element X can be represented by B_{X}/(B_{X}+B_{Y}+B_{Z}).

Note that silicon contained in indium oxide is regarded as a metalloid element in this specification and the like, and the category of a “metal element” in this specification and the like includes a metalloid element. For example, in a metal oxide layer containing indium (In), gallium (Ga), and Si═O or Si(II), the content of indium can be calculated from A_{In}/(A_{In}+A_{Ga}+A_{Si}) or B_{In}/(B_{In}+B_{Ga}+B_{Si}). The content of gallium can be calculated from A_{Ga}/(A_{In}+A_{Ga}+A_{Si}) or B_{Ga}/(B_{In}+B_{Ga}+B_{Si}).

The purity of the metal oxide layer 30_1 is preferably high. The impurity concentration in the metal oxide layer 30_1 is preferably low. In particular, when the metal oxide layer 30_1 includes the channel formation region of the transistor, the purity in the channel formation region is preferably high. The impurity concentration in the channel formation region is preferably low. For example, the purity of the metal oxide layer 30_1 or the channel formation region is preferably higher than or equal to 3N (99.9%), further preferably higher than or equal to 4N (99.99%), still further preferably higher than or equal to 5N (99.999%), yet further preferably higher than or equal to 6N (99.9999%), yet still further preferably higher than or equal to 7N (99.99999%), yet still further preferably higher than or equal to 8N (99.999999%), yet still further preferably higher than or equal to 9N (99.9999999%), yet still further preferably higher than or equal to ION (99.99999999%). It is presumed that impurity elements (elements other than indium and oxygen) in the metal oxide layer 30_1 are likely to be unevenly distributed at a crystal grain boundary. In other words, it is presumed that when the metal oxide layer 30_1 contains impurity elements, uneven distribution of the impurity elements facilitates formation of a crystal grain boundary. Thus, a reduction in the amount of impurity elements in the metal oxide layer 30_1 can inhibit formation of a crystal grain boundary in the metal oxide layer 30_1. This inhibits grain boundary scattering or impurity scattering, so that the transistor can have a higher on-state current and higher field-effect mobility.

When the purity is increased or the impurity concentration is reduced in the metal oxide layer 30_1, a crystal grain of the metal oxide layer 30_1 has a cubic crystal structure, specifically, a bixbyite crystal structure. Note that in the case where the content of the first element in the metal oxide layer 30_2 is within the above range, a crystal grain of the metal oxide layer 30_2 can have a cubic crystal structure, specifically, a bixbyite crystal structure.

Examples of a film including a crystal grain include a single crystal film, a polycrystal film, and a microcrystal film. The use of a single crystal film as the semiconductor layer of the transistor can inhibit carrier scattering at a crystal grain boundary, thereby achieving high field-effect mobility. In addition, a variation in transistor characteristics caused by the crystal grain boundary can be reduced. A polycrystal film can reduce carrier scattering as compared with an amorphous film and enables a transistor to have high field-effect mobility. In a microcrystal film, for example, a microscopic region (for example, a region with a size greater than or equal to 1 nm and less than or equal to 10 nm) has a periodic atomic order. Thus, a microcrystal film can have a lower density of defect states than an amorphous film, enabling a highly reliable semiconductor device.

A transistor including the above indium oxide film can have a field-effect mobility higher than or equal to 50 cm²/(V·s), preferably higher than or equal to 100 cm²/(V·s), further preferably higher than or equal to 150 cm²/(V·s), still further preferably higher than or equal to 200 cm²/(V·s), yet still further preferably higher than or equal to 250 cm²/(V·s).

Moreover, indium oxide has a large effective mass of holes, which allows a transistor to have an extremely low off-state current. For example, the off-state current per micrometer of channel width of a transistor including an indium oxide film can be lower than or equal to 1 fA (1×10⁻¹⁵ A) or lower than or equal to 1 aA (1×10⁻¹⁸ A) at 125 °C, and can be lower than or equal to 1 aA (1×10⁻¹⁸ A) or lower than or equal to 1 zA (1×10⁻²¹ A) at room temperature (25 °C).

As described above, a transistor including indium oxide, particularly crystal indium oxide, in a semiconductor layer has features such as high field-effect mobility, an extremely low off-state current, and controllable threshold voltage.

In the structure illustrated in FIG. 1A, the metal oxide layer 301, the metal oxide layer 30_2, the insulating layer 50, and the conductive layer 60 respectively correspond to the first metal oxide layer, the second metal oxide layer, the first insulating layer, and the conductive layer that are described above.

Although FIG. 1A illustrates the structure where the metal oxide layer 30_2 is positioned below the metal oxide layer 301, the present invention is not limited thereto. For example, as illustrated in FIG. 1B, the metal oxide layer 30_2 can be positioned above the metal oxide layer 30_1. In this case, the metal oxide layer 30_2 can be regarded as being positioned between the metal oxide layer 30_1 and the insulating layer 50. The structure illustrated in FIG. 1B can have an effect similar to that of the structure illustrated in FIG. 1A.

Although FIGS. 1A and 1B each illustrate the structure where the metal oxide layer 30 has a two-layer structure, the present invention is not limited thereto. For example, as illustrated in FIG. 1C, the metal oxide layer 30 can have a three-layer structure of the metal oxide layer 302, the metal oxide layer 301 over the metal oxide layer 302, and a metal oxide layer 30_3 over the metal oxide layer 30_1. In this case, the metal oxide layer 30_3 is positioned between the metal oxide layer 301 and the insulating layer 50.

The metal oxide layers 30_1 and 30_2 can be formed using the above-described material. The metal oxide layer 30_3 can be formed using a material usable for the metal oxide layer 302. With such a structure, the threshold voltage of the transistor can be shifted positively. Moreover, the transistor can have normally-off characteristics. Accordingly, the transistor having favorable electrical characteristics can be provided. Moreover, with the above structure, the electron affinity of the metal oxide layer 303 can be lower than that of the metal oxide layer 30_1 in some cases. In this case, the channel can be kept away from the surface of the insulating layer 50, so that the influence of surface scattering can be reduced. Thus, the transistor can have higher field-effect mobility and a higher on-state current.

When the metal oxide layer 30 has the three-layer structure illustrated in FIG. 1C, the metal oxide layer 30_1 is interposed between the metal oxide layers 30_2 and 30_3 each having a wider band gap and mainly functions as a current path (channel). Accordingly, a buried-channel transistor where a channel is kept away from the interface between the metal oxide layer 30 and an insulating layer can be achieved. Furthermore, the density of trap states can be reduced at the interface between the metal oxide layers 30_2 and 30_1 and in the vicinity thereof and at the interface between the metal oxide layers 30_1 and 30_3 and in the vicinity thereof. Thus, the transistor can have higher field-effect mobility and a higher on-state current.

Note that in the case where the metal oxide layer 30_1 is provided between the metal oxide layers 30_2 and 303, one of the metal oxide layers 30_2 and 30_3 can contain indium and Si═O or Si(II) and the other can contain indium and the first element. For example, the metal oxide layer 302 can contain indium and Si═O or Si(II) and the metal oxide layer 303 can contain indium and gallium. Since the electron affinity of the oxide of the first element is lower than that of indium oxide, a buried-channel transistor can be achieved even with such a structure. In addition, formation of V_{O} and V_{O}H in the metal oxide layer 30 can be inhibited. Furthermore, the threshold voltage of the transistor can be shifted positively.

When the metal oxide layers 30_1 and 30_2 contain a common element as the main component, the density of defect states at the interface therebetween can be reduced. Similarly, when the metal oxide layers 30_1 and 30_3 contain a common element as the main component, the density of defect states at the interface therebetween can be reduced. Thus, carrier traps or the like due to defect states are reduced, so that the transistor having favorable characteristics and high reliability can be provided. Here, the main component refers to a metal element whose content is higher than or equal to 0.1% in the metal oxide layer. A metal element whose content is lower than 0.1% is referred to as an impurity in some cases.

The content of an element in a layer can be evaluated by, for example, energy dispersive X-ray spectroscopy (EDX), XPS, secondary ion mass spectrometry (SIMS), time-of-flight secondary ion mass spectrometry (ToF-SIMS), auger electron spectroscopy (AES), inductively coupled plasma-mass spectrometry (ICP-MS), inductively coupled plasma-atomic emission spectroscopy (ICP-AES), or the like.

The electron affinity or the conduction band minimum can be calculated using a band gap and an ionization potential, which is a difference in energy between the vacuum level and the valence band maximum. The ionization potential can be evaluated by ultraviolet photoelectron spectroscopy (UPS), for example. The band gap can be evaluated using optical evaluation with a spectrophotometer, spectroscopic ellipsometry, a photoluminescence method, XPS, or an X-ray absorption fine structure (XAFS). Alternatively, these methods can be combined as appropriate for the analysis.

A crystal structure can be analyzed with X-ray diffraction (XRD), a transmission electron microscope (TEM), a scanning transmission electron microscope (STEM), or electron diffraction (ED), for example. Alternatively, a crystal structure can be analyzed with a fast Fourier transform (FFT) pattern obtained by performing FFT processing on a TEM image. Alternatively, two or more of these methods may be combined for the analysis.

A TEM image and a STEM image can be obtained through thinning performed on a region whose crystal structure is intended to specify. For the thinning, a focused ion beam (FIB), an ion milling method, or the like can be used.

The metal oxide layers 30_2 and 30_3 each function as the semiconductor layer of the transistor in some cases depending on the content of the first element. Alternatively, the metal oxide layers 30_2 and 30_3 can each be referred to as an insulating layer in some cases.

Note that a boundary between layers included in a metal oxide layer is sometimes difficult to observe. That is, even a metal oxide layer having a stacked-layer structure is sometimes observed as one metal oxide layer (a metal oxide layer having a single-layer structure) containing indium and the first element. For example, the metal oxide layer 30 illustrated in FIG. 1C is sometimes observed as a layer including a first portion, a second portion, and a third portion corresponding to the metal oxide layer 301, the metal oxide layer 302, and the metal oxide layer 30_3, respectively. In this case, the metal oxide layer 30_1, the metal oxide layer 302, and the metal oxide layer 30_3 can be respectively rephrased as the first portion, the second portion, and the third portion of the metal oxide layer 30.

The metal oxide layer 30 can also have a stacked-layer structure of four or more layers. For example, in the structure illustrated in FIG. 1C, a metal oxide layer may be provided between the metal oxide layer 302 and the insulating layer 20. The metal oxide layer provided under the metal oxide layer 30 can inhibit diffusion of impurities from components formed below the metal oxide layer into the metal oxide layer 30.

For the metal oxide layer, indium gallium zinc oxide (In—Ga—Zn oxide, also referred to as IGZO), gallium zinc oxide (Ga—Zn oxide), gallium oxide, or the like can be used. Specifically, In—Ga—Zn oxide that can be used for the metal oxide layer can have an atomic ratio of In:Ga:Zn=1:1:1 or a composition in the neighborhood thereof, an atomic ratio of In:Ga:Zn=1:3:2 or a composition in the neighborhood thereof, or an atomic ratio of In:Ga:Zn=1:3:4 or a composition in the neighborhood thereof. Note that in this specification and the like, a composition in the neighborhood of an atomic ratio includes ±30% of an intended atomic ratio.

The structure of the metal oxide layer 30 is not limited to a structure where layers having different contents of the first element are stacked. In the metal oxide layer 30, for example, the concentration of the first element can have a gradient shown in FIG. 1D by hatching density, in which the concentration increases from the inner portion toward the surface (top or bottom surface) of the metal oxide layer 30. This not only increases the range of choices for design without need for use of a layer with a predetermined composition but also prevents formation of an interface state or the like between layers with different compositions; thus, the electrical characteristics and reliability of the transistor can be improved. Note that the inner portion of the metal oxide layer 30 refers to a position and its vicinity whose distance to an interface (referred to as a first interface) between the bottom surface of the metal oxide layer 30 and a layer in contact with the bottom surface is equal to its distance to an interface (referred to as a second interface) between the top surface of the metal oxide layer 30 and a layer in contact with the top surface.

The category of a “concentration gradient” in this specification includes a “concentration gradient that gradually changes” and a “concentration gradient that continuously changes”. The concentration gradient that gradually changes means that the concentration increases or decreases step-by-step in the thickness direction. For example, when a graph in which the horizontal axis indicates the thickness and the vertical axis indicates the concentration is formed, a line which connects a plurality of plotted points describes an upward-sloping or downward-sloping step-by-step line. The concentration gradient that continuously changes means that the concentration changes gently in the thickness direction. For example, when a graph in which the horizontal axis indicates the thickness and the vertical axis indicates the concentration is formed, a line which connects a plurality of plotted points describes an upward-sloping or downward-sloping curve or straight line.

In the case of having the above-described concentration gradient, the metal oxide layer 30 includes the second portion on or near its bottom surface, the third portion on or near its top surface, and the first portion between the second and third portions.

Here, a value obtained by dividing the thickness of the metal oxide layer 30 by 3 is referred to as a length A. For example, the second portion is positioned in a region extending from the first interface to a position whose distance from the first interface is the length A, the third portion is positioned in a region extending from the second interface to a position whose distance from the second interface is the length A, and the first portion includes a portion whose distance to the first interface is equal to its distance to the second interface.

Note that the concentration gradient of an element in a layer can be evaluated by analyzing the element distribution in the depth direction of the layer. For example, the concentration gradient can be confirmed by EDX composition line analysis or SIMS. Alternatively, the concentration gradient can be confirmed by ToF-SIMS using a sputtering ion source. Alternatively, the concentration gradient can be confirmed by a combination of ion etching and XPS or AES.

Fluorine may be added to the metal oxide layer 30_3. In this case, the metal oxide layer 30_3 contains fluorine. At the time of turning on the transistor, a potential is supplied to the gate electrode, whereby electrons are injected into the semiconductor layer. In some cases, some of the injected electrons are trapped by fluorine in the metal oxide layer 303, and fluorine that traps the electrons functions as negative fixed charge. When fluorine in the metal oxide layer 30_3 functions as negative fixed charge, the threshold voltage of the transistor can be shifted positively. Moreover, the transistor can have normally-off characteristics. Accordingly, the transistor having favorable electrical characteristics can be provided.

Fluorine in the metal oxide layer 30_3 is positioned between lattices or in a structural interstitial position (see FIG. 2C) in some cases. Fluorine positioned between lattices or in a structural interstitial position has negative charge and thus can function as negative fixed charge. In addition, fluorine in the metal oxide layer 30_3 is positioned in an oxygen vacancy in some cases. Entry of fluorine into an oxygen vacancy can reduce the amount of oxygen vacancies. Fluorine positioned in an oxygen vacancy (also referred to as V_{O}F) exists more stably than V_{O}H; thus, formation of V_{O}H can be inhibited.

Fluorine is preferably added by plasma treatment using a fluorine-containing gas. As the fluorine-containing gas, for example, a gas such as NF₃, SF₆, CF₄, CHF₃, or C₄F₆ can be used. By subjecting the metal oxide layer 30_3 to treatment using the gas that has been changed into plasma, fluorine can be added to the metal oxide layer 30_3.

Although the example in which fluorine is added to the metal oxide layer 30_3 is described above, the present invention is not limited thereto. Fluorine may be added to the metal oxide layer 30_2 or the metal oxide layer provided between the metal oxide layer 30_2 and the insulating layer 20. Such a structure can have an effect similar to that of the structure where fluorine is added to the metal oxide layer 303.

Although fluorine is described above as an example of the element added to the metal oxide layer 303, the present invention is not limited thereto. A halogen element other than fluorine, such as chlorine, can be added.

The metal oxide layer 30_3 may have a partial structure where an oxygen atom and a hydrogen atom are bonded (such a structure is referred to as OH). An oxygen atom and a hydrogen atom that are positioned between lattices or in a structural interstitial position are bonded to form OH in some cases. Moreover, OH is positioned between lattices or in a structural interstitial position in some cases. At the time of turning on the transistor, a potential is supplied to the gate electrode, whereby electrons are injected into the semiconductor layer; in some cases, some of the injected electrons are trapped by OH in the metal oxide layer 30_3, and OH that traps the electrons (referred to as OH⁻) functions as negative fixed charge. When OH⁻ in the metal oxide layer 303 functions as negative fixed charge, the threshold voltage of the transistor can be shifted positively. Moreover, the transistor can have normally-off characteristics. Accordingly, the transistor having favorable electrical characteristics can be provided.

Although the example in which OH is contained in the metal oxide layer 30_3 is described above, the present invention is not limited thereto. OH may be contained in the metal oxide layer 30_2 or the metal oxide layer provided between the metal oxide layer 30_2 and the insulating layer 20. Such a structure can have an effect similar to that of the structure where OH is contained in the metal oxide layer 30_3.

The insulating layer 50 can have a single-layer structure or a stacked-layer structure of two or more layers. For example, FIG. 1E illustrates an example in which the insulating layer 50 has a three-layer structure of an insulating layer 50_1 over the metal oxide layer 30, an insulating layer 50_2 over the insulating layer 50_1, and an insulating layer 50_3 over the insulating layer 502.

The insulating layer 50 is preferably formed of two or more kinds of films. When the insulating layer 50 is formed of two or more kinds of films, the insulating layer 50 can have a plurality of functions. Examples of the functions of the insulating layer 50 include a function of supplying oxygen to the metal oxide layer 30, a function of extracting excess oxygen from the metal oxide layer 30, a function of extracting hydrogen from the metal oxide layer 30, and a function of inhibiting diffusion of hydrogen into the metal oxide layer 30.

The insulating layer 50_1 preferably contains an insulating material having a function of capturing and fixing hydrogen. Such a structure enables hydrogen in the metal oxide layer 30 to be captured or fixed by the insulating layer 50_1 through heat treatment or the like, so that the hydrogen concentration in the metal oxide layer 30 can be reduced.

Examples of the insulating material having a function of capturing or fixing hydrogen include a metal oxide such as magnesium oxide, aluminum oxide, hafnium oxide, and an oxide containing aluminum and hafnium (hafnium aluminate).

Note that hafnium oxide has a function of capturing and fixing oxygen as well as a function of capturing and fixing hydrogen. When the insulating layer 50_1 includes hafnium oxide, excess oxygen contained in the metal oxide layer 30 can be captured and fixed. Since hafnium oxide is also a material having a high dielectric constant (a high-k material), the use of hafnium oxide can reduce the gate leakage current of the transistor.

The insulating layer 50_2 preferably contains an insulating material having a function of supplying oxygen. Such a structure enables oxygen vacancies in the metal oxide layer 30 to be filled with oxygen in the insulating layer 502.

Examples of the insulating material having a function of supplying oxygen include silicon oxide and silicon oxynitride. Silicon oxide, silicon oxynitride, or the like is also a material with high withstand voltage. Accordingly, the use of silicon oxide, silicon oxynitride, or the like can increase the withstand voltage of the transistor.

The insulating layer 50_3 preferably contains an insulating material having a high barrier property against hydrogen. Such a structure can inhibit diffusion of hydrogen from above the insulating layer 50 into the metal oxide layer 30.

Examples of the insulating material having a barrier property against hydrogen include a nitride such as silicon nitride and an oxide such as tantalum oxide. Silicon nitride is suitable for the insulating layer 50_3 because of its high hydrogen barrier property.

The above three-layer structure of the insulating layer 50 enables the metal oxide layer 30 to be closer to an i-type layer. Thus, the transistor has high field-effect mobility and high reliability. The insulating layer 50 can have a three-layer structure where a hafnium oxide film, a silicon oxide film, and a silicon nitride film are stacked in this order from the metal oxide layer 30 side, for example.

Note that as illustrated in FIG. 1F, the insulating layer 50 can have a three-layer structure of the insulating layer 50_2 over the metal oxide layer 30, the insulating layer 50_1 over the insulating layer 502, and the insulating layer 503 over the insulating layer 501. Such a structure can have an effect similar to that of the structure illustrated in FIG. 1E. The insulating layer 50 can have a three-layer structure where a silicon oxide film, a hafnium oxide film, and a silicon nitride film are stacked in this order from the metal oxide layer 30 side, for example.

In the structure illustrated in FIG. 1F, an insulating layer having a function of capturing and fixing hydrogen can be provided between the insulating layers 50_1 and 50_3. The insulating layer 50 can have a four-layer structure where a hafnium oxide film, a silicon oxide film, a hafnium oxide film, and a silicon nitride film are stacked in this order from the metal oxide layer 30 side, for example. This structure enables the hydrogen concentration in the metal oxide layer 30 to be further reduced.

The insulating layer 50 may include an insulating film having a barrier property against oxygen. For example, in the structure illustrated in FIG. 1E, an insulating film having a barrier property against oxygen may be provided between the metal oxide layer 30 and the insulating layer 50_1. Alternatively, in the structure illustrated in FIG. 1F, an insulating film having a barrier property against oxygen may be provided between the metal oxide layer 30 and the insulating layer 50_2. Examples of an insulating material having a barrier property against oxygen include aluminum oxide and gallium oxide. When an insulating film having a barrier property against oxygen is provided between the conductive layer 60 and the channel formation region in the metal oxide layer 30, diffusion of oxygen contained in the channel formation region into the conductive layer 60 and formation of oxygen vacancies in the channel formation region can be inhibited. Moreover, oxygen contained in the metal oxide layer 30 can be inhibited from being diffused into the conductive layer 60 and oxidizing the conductive layer 60.

In particular, when a gallium oxide film or an aluminum oxide film is provided between the metal oxide layer 30 and the insulating layer 50_1, hydrogen in the metal oxide layer 30 passes through the gallium oxide film or the aluminum oxide film and is captured and fixed by the insulating layer 50_1, so that the hydrogen concentration in the metal oxide layer 30 can be reduced. This is preferable because formation of oxygen vacancies is inhibited at the interface between the metal oxide layer 30 and the gallium oxide film or the aluminum oxide film. In order that hydrogen can pass through the gallium oxide film or the aluminum oxide film provided between the metal oxide layer 30 and the insulating layer 501, the thickness of the gallium oxide film or the aluminum oxide film is greater than or equal to 0.1 nm and less than or equal to 3 nm, preferably greater than or equal to 0.5 nm and less than or equal to 1.5 nm.

The conductive layer 60 can have a single-layer structure or a stacked-layer structure of two or more layers. For example, the conductive layer 60 can have a two-layer structure of a first conductive layer on the side in contact with the insulating layer 50 and a second conductive layer over the first conductive layer. In that case, the first conductive layer is preferably formed using a conductive material that is less likely to be oxidized, such as titanium, titanium nitride, tantalum, tantalum nitride, ruthenium, or ruthenium oxide, or a conductive material having a function of inhibiting diffusion of oxygen. The second conductive layer is preferably formed using a low-resistance conductive material such as tungsten, copper, or aluminum.

The conductive layer 60 is preferably formed using a material with a high work function (φ_{M}). The work function of the conductive layer 60 is preferably higher than the electron affinity of the metal oxide layer 30 (typical electron affinity of indium oxide is 4.46 eV). A transistor including a semiconductor layer containing indium oxide is an accumulation-type transistor in which electrons are majority carriers. With use of a material with a high work function for the conductive layer 60 functioning as the gate electrode of the transistor, the threshold voltage of the transistor can be shifted positively. Moreover, the transistor can have normally-off characteristics. Accordingly, the transistor having favorable electrical characteristics can be provided.

The conductive layer 60 can be formed using a conductive material with a work function higher than or equal to 4.5 eV, preferably higher than or equal to 5.0 eV, for example. Examples of the conductive material include metals such as platinum (5.64 eV), nickel (5.15 eV), copper (4.7 eV), cobalt (5.0 eV), molybdenum (4.6 eV), chromium (4.5 eV), tungsten (4.6 eV), and iron (4.5 eV). Examples of the conductive material also include a conductive metal oxide (also referred to as a conductive oxide), a conductive oxide containing nitrogen, and a conductive metal nitride (also referred to as a conductive nitride). Examples of the conductive oxide include indium tin oxide (In—Sn oxide, also referred to as ITO), indium tin oxide containing silicon (also referred to as ITSO), indium zinc oxide (In—Zn oxide, also referred to as IZO (registered trademark)), indium tin oxide containing tungsten (In—Sn—W oxide), indium titanium oxide (In—Ti oxide), and indium zirconium oxide (In—Zr oxide). Examples of the conductive oxide containing nitrogen include In—Ga—Zn oxide, indium tin oxide, indium gallium oxide, indium zinc oxide, tin oxide, and indium oxide each containing nitrogen. Examples of the conductive nitride include titanium nitride, indium nitride, and tin nitride.

Note that the conductive oxide is a material that is more likely to maintain its conductivity even after absorbing oxygen than a material containing a metal element (also referred to as a metal material). For example, the use of the conductive oxide is preferable because it enables the conductive layer 60 to maintain its conductivity even in the case where an oxide insulating film is used as the insulating layer 50.

The work function of a material can be evaluated by, for example, photoelectron spectroscopy such as XPS, UPS, or AES. It is also possible to use a Kelvin probe method, a thermionic emission method, a field emission method, or the like.

The insulating layer 20 can have a single-layer structure or a stacked-layer structure of two or more layers. The insulating layer 20 can be formed using a material usable for the insulating layer 50. For example, the insulating layer 20 can have a three-layer structure of a silicon oxide film under the metal oxide layer 30, a hafnium oxide film under the silicon oxide film, and a silicon nitride film under the hafnium oxide film. With this structure, oxygen vacancies in the metal oxide layer 30 are filled with oxygen in the silicon oxide film. Moreover, hydrogen in the metal oxide layer 30 is captured in the hafnium oxide film by heat treatment or the like. Providing the silicon nitride film inhibits entry of oxygen and hydrogen from below the insulating layer 20. That is, the above film structure enables the metal oxide layer 30 to be closer to an i-type layer. Thus, the transistor has high field-effect mobility and high reliability.

As described above, the threshold voltage of the transistor can be controlled when the transistor has at least one of the structure where one or both of the metal oxide layer 30_2 and the metal oxide layer 30_3 contain Si═O or Si(II), the structure where one or both of the metal oxide layer 30_2 and the metal oxide layer 30_3 contain fluorine, the structure where one or both of the metal oxide layer 30_2 and the metal oxide layer 303 contain OH, and the structure where the conductive layer 60 contains a conductive material with a high work function.

### Manufacturing Method Example

An example of a method for manufacturing the semiconductor device of one embodiment of the present invention is described. Here, an example of a method for manufacturing the semiconductor device illustrated in FIG. 1C is described.

Thin films included in the semiconductor device (e.g., insulating films, semiconductor films, and conductive films) can be formed by a sputtering method, a chemical vapor deposition (CVD) method, a molecular beam epitaxy (MBE) method, a vacuum evaporation method, a pulsed laser deposition (PLD) method, an ALD method, or the like.

For film formation using an insulating target, an RF sputtering method is preferably used. A DC sputtering method is used mainly in the case of film formation using a conductive target. In a DC sputtering method, not only formation of a conductive film but also formation of an insulating film is possible by reactive sputtering using a pulsed DC sputtering method. The pulsed DC sputtering method can be specifically used to form a film of a compound such as an oxide, a nitride, or a carbide by a reactive sputtering method.

Note that CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object to be processed. A wiring, an electrode, an element (e.g., a transistor or a capacitor), or the like included in a semiconductor device might be charged up by receiving charge from plasma, for example. In that case, the accumulated charge might break the wiring, electrode, element, or the like included in the semiconductor device. A thermal CVD method, which does not use plasma, does not cause such plasma damage, and thus can increase the yield of the semiconductor device. A thermal CVD method yields a film with few defects because of no plasma damage during film formation.

As an ALD method, a thermal ALD method, in which a precursor and a reactant react with each other only by a thermal energy, a PEALD method, in which a reactant excited by plasma is used, or the like can be used.

Note that some precursors used in an ALD method contain an element such as carbon or chlorine. Thus, a film formed by an ALD method sometimes contains an element such as carbon or chlorine in a larger quantity than a film formed by another film formation method. These elements can be quantified by XPS or SIMS. The film formation method of a metal oxide of one embodiment of the present invention, which employs an ALD method and one or both of a formation condition with a high substrate temperature and impurity removal treatment, can sometimes form a film with smaller amounts of carbon and chlorine than a method employing an ALD method without the formation condition with a high substrate temperature or the impurity removal treatment.

Unlike in a film formation method in which particles ejected from a target or the like are deposited, a film is formed by reaction at a surface of an object to be processed in an ALD method. Thus, an ALD method can provide good step coverage, almost regardless of the shape of an object to be processed. In particular, an ALD method allows excellent step coverage and excellent thickness uniformity and can be suitably used to cover a surface of an opening portion with a high aspect ratio, for example.

A CVD method and an ALD method differ from a sputtering method in which particles ejected from a target or the like are deposited. Thus, an ALD method and a CVD method can provide good step coverage, almost regardless of the shape of an object to be processed. In particular, an ALD method allows excellent step coverage and excellent thickness uniformity and can be suitably used to cover a surface of an opening portion with a high aspect ratio, for example. Note that an ALD method has a relatively low film formation rate; hence, in some cases, an ALD method is preferably combined with another film formation method with a high film formation rate, such as a CVD method.

By a CVD method, a film with a desired composition can be formed by adjusting the flow rate ratio of the source gases. For example, a CVD method enables formation of a film whose composition is continuously changed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer or pressure adjustment is not required. Hence, the productivity of the semiconductor device can be improved in some cases.

An ALD method in which a plurality of different kinds of precursors are used enables formation of a film with a desired composition. In the case where a plurality of different kinds of precursors are introduced, the number of cycles for each precursor is controlled, whereby a film with a desired composition can be formed.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used. The use of EUV, X-rays, or an electron beam enables extremely minute processing, which is preferable. Note that a photomask is not needed when exposure is performed by scanning with a beam such as an electron beam.

For etching of thin films, a dry etching method, a wet etching method, a sandblast method, or the like can be used.

First, a substrate (not illustrated) is prepared, and the insulating layer 20 is formed over the substrate.

Then, the metal oxide layer 30 is formed over the insulating layer 20. Specifically, the metal oxide layer 30_2 is formed over the insulating layer 20, the metal oxide layer 30_1 is formed over the metal oxide layer 302, and then the metal oxide layer 30_3 is formed over the metal oxide layer 301.

The metal oxide layer 30 is preferably formed by a sputtering method. The metal oxide layer 30 can be formed in an oxygen-containing atmosphere by a sputtering method. At this time, the use of a sputtering method that does not need to use a molecule containing hydrogen in a film formation gas can reduce the concentration of hydrogen in the metal oxide layer 30. For example, a single gas of oxygen or a mixed gas of oxygen and a noble gas can be used as the sputtering gas.

A gas containing hydrogen (H₂) can also be used as the sputtering gas. By introducing hydrogen while the metal oxide layer is formed by a sputtering method, the metal oxide layer having low crystallinity, e.g., the metal oxide layer having an amorphous structure, can be formed. In addition, nucleation can be inhibited while the metal oxide layer is formed. As the sputtering gas, a mixed gas of hydrogen, a noble gas (typically argon), and oxygen (O₂) can be used. When a gas containing water (H₂O), hydrogen peroxide (H₂O₂), or the like is used as the sputtering gas, an effect similar to the above may be obtained.

In the case where the metal oxide layer is formed by a sputtering method, the substrate temperature at the time of forming the metal oxide layer is preferably higher than or equal to room temperature (25 °C) and lower than or equal to 250 °C, further preferably higher than or equal to room temperature and lower than or equal to 200 °C, still further preferably higher than or equal to room temperature and lower than or equal to 140 °C. For example, the substrate temperature is preferably higher than or equal to room temperature and lower than or equal to 140 °C to increase the productivity and inhibit nucleation. The metal oxide layer can also be formed in the state where the substrate temperature is set at room temperature or the substrate is not heated.

The metal oxide layer 30 can also be formed by an ALD method. With the use of an ALD method in which deposition is performed at an atomic level, nucleation in a film can be inhibited as compared with the case of using a sputtering method in which particles are made to collide with the formation surface. For example, the metal oxide layer can be formed using one or more precursors and an oxidizer.

The metal oxide layer can be formed by repeating a cycle of introduction of a precursor, purge of the precursor, introduction of an oxidizer, and purge of the oxidizer. Here, the composition of the metal oxide layer can be controlled by varying the number of cycles for different kinds of precursors.

Since the metal oxide layer 30 contains indium, the metal oxide layer 30 is formed using at least a precursor containing indium.

As the precursor containing indium, it is possible to use trimethylindium (also referred to as TMI or TMIn), triethylindium (also referred to as TEI or TEIn), ethyldimethylindium, tris(1-methylethyl)indium, triisopropylindium (also referred to as TIPIn), tris(2,2,6,6-tetramethyl-3,5-heptanedionato)indium, cyclopentadienylindium (also referred to as InCp), tris(cyclopentadienyl)indium (also referred to as InCp₃ or Cp₃In), indium(III) acetylacetonate, (3-(dimethylamino)propyl)dimethylindium (also referred to as DADI), dimethylaminopropyldiisopropylindium (also referred to as DADII), (diethylphosphino)dimethylindium, chlorodimethylindium, bromodimethylindium, dimethyl(2-propanolato)indium, or the like.

As the precursor containing indium, an inorganic precursor not containing hydrocarbon may be used. As the inorganic precursor containing indium, it is possible to use a halogen-based indium compound such as trifluoroindium (indium(III) fluoride), indium trichloride (indium(III) chloride), indium tribromide (indium(III) bromide), or indium triiodide (indium(III) iodide).

In the method for forming the metal oxide layer, it is preferable to use a precursor with a low impurity concentration, i.e., a high-purity precursor. For example, the use of a precursor having a purity higher than or equal to 3N (99.9%), preferably higher than or equal to 4N (99.99%), further preferably higher than or equal to 5N (99.999%), still further preferably higher than or equal to 6N (99.9999%) can reduce impurities in the metal oxide layer.

A precursor purified by two or more times of distillation (also referred to as “rectification” or “precision distillation”) is preferably used. The use of such a precursor is preferable because it facilitates formation of a film of a metal oxide containing few impurities. Distillation is preferably performed a plurality of times to further inhibit impurities due to a starting material used to produce the precursor from remaining in the precursor. Note that the present invention is not limited to the above, and a precursor subjected to distillation once, i.e., single distillation, may be used. The single distillation is preferable in terms of a reduction in manufacturing cost. One or more times of distillation can increase the purity of the precursor.

Ozone (O₃), oxygen (O₂), water (H₂O), hydrogen peroxide (H₂O₂), or the like can be used as the oxidizer. The oxidizer preferably contains at least one of ozone and oxygen. In the case of using ozone, oxygen, or the like, which does not contain hydrogen, as the oxidizer, the amount of hydrogen entering the metal oxide layer can be reduced. Note that in the case of using water, hydrogen peroxide, or the like, which contains hydrogen, as the oxidizer, the metal oxide layer having low crystallinity can be formed. In addition, nucleation can be inhibited while the metal oxide layer is formed.

In this specification and the like, unless otherwise specified, ozone, oxygen, water, and hydrogen peroxide that can be used for an oxidizer include not only those in gas or molecular states but also those in plasma, radical, and ion states.

The substrate heating temperature at the time of introducing the precursor into a reaction chamber is preferably a temperature corresponding to the decomposition temperature of the precursor. In the case of a thermal ALD method in which triethylindium is used as the precursor containing indium, the substrate heating temperature can be higher than or equal to 100 °C and lower than or equal to 350 °C, preferably higher than or equal to 150 °C and lower than or equal to 300 °C, for example.

First, an example of a method for forming the metal oxide layer 30_2 is described.

In a sputtering method, particles are made to collide with the formation surface, which facilitates formation of a layer containing a constituent element of a layer having the formation surface. In addition, when a sputtering method employs conditions with high power and low pressure, collision energy of particles can be further increased. This further facilitates formation of a layer containing a constituent element of a layer having the formation surface. Specifically, a metal oxide layer is formed over an insulating layer containing silicon oxide by a sputtering method using an indium oxide sputtering target, whereby Si═O or Si(II) can be added to the metal oxide layer. By such a method, the metal oxide layer 30_2 containing indium and Si═O or Si(II) can be formed. Note that the insulating layer contains silicon and oxygen and corresponds to the insulating layer 20 illustrated in FIG. 1C. In the case where the insulating layer has a stacked-layer structure, the uppermost layer (a layer having the formation surface) preferably contains silicon and oxygen.

In the above, with use of an indium oxide sputtering target containing the first element, the metal oxide layer 302 containing indium, the first element, and Si═O or Si(II) can be formed.

For another example, an indium oxide film is formed by an ALD method using an oxidizer and a precursor containing indium. Moreover, by performing delta doping in the formation of the indium oxide film, Si═O or Si(II) can be added to the indium oxide film. The metal oxide layer 30_2 containing indium and Si═O or Si(II) can also be formed by such a method.

Delta doping (also referred to as sheet doping) refers to a method in which a thin layer (e.g., one atomic layer) where specific elements are localized is introduced. Elements added by delta doping are unevenly distributed in a film and thus can be inhibited from entering a layer having the formation surface or a layer formed over the film. For delta doping, an ALD method, an MBE method, or the like can be used.

The metal oxide layer 30_2 can be formed using a first precursor, a second precursor, and an oxidizer. A precursor containing indium and a precursor containing silicon are used as the first precursor and the second precursor, respectively. The metal oxide layer 30_2 containing indium and Si═O or Si(II) can also be formed with the use of the first and second precursors.

A step of forming the metal oxide layer 30_2 can include, for example, a first step of introducing the first precursor and introducing the oxidizer after the introduction of the first precursor and a second step of introducing the second precursor. It is particularly preferable that the second step be performed a smaller number of times than the first step. In such a manner, an indium oxide film containing Si═O or Si(II) can be formed.

For example, the second step is performed intermittently while the first step is performed repeatedly, whereby an indium oxide film containing Si═O or Si(II) can be formed. Specifically, the first step is performed i times (i is an integer greater than or equal to 2), the second step is performed j times (j is an integer greater than or equal to 1 and less than i), and then the first step is performed k times (k is an integer greater than j), whereby an indium oxide film containing Si═O or Si(II) can be formed. Note that i and k may be the same or different from each other. The oxidizer maybe introduced after the second step. Before the second step, treatment for increasing the crystallinity of the metal oxide layer may be performed. The details of the treatment for increasing the crystallinity of the metal oxide layer will be described later.

As the precursor containing silicon, trisilylamine, bis(diethylamino)silane, tris(dimethylamino)silane, bis(tert-butylamino)silane, or bis(ethylmethylamino)silane can be used.

For another example, the metal oxide layer 30_2 containing indium, the first element, and Si═O or Si(II) can be formed by an ALD method using the first precursor, the second precursor, a third precursor, and an oxidizer. As the third precursor, a precursor containing the first element is used.

A step of forming the metal oxide layer 30_2 can include, for example, a first step of introducing the first precursor and introducing the oxidizer after the introduction of the first precursor, a second step of introducing the second precursor, and a third step of introducing the third precursor and then introducing the oxidizer after the introduction of the third precursor. It is particularly preferable that the second step be performed a smaller number of times than the first step. In such a manner, a metal oxide film containing indium, the first element, and Si═O or Si(II) can be formed.

For example, the second step and the third step are each performed intermittently while the first step is performed repeatedly, whereby an indium oxide film containing Si═O or Si(II) and the first element can be formed. Note that the second step and the third step may be successively performed, or the first step may be performed between the second step and the third step. The oxidizer may be introduced after the second step.

In the case where gallium is used as the first element, triethylgallium (also referred to as TEGa), trimethylgallium (also referred to as TMGa), gallium trichloride, tris(dimethylamido)gallium(III), gallium(III) acetylacetonate, tris(2,2,6,6-tetramethyl-3,5-heptanedionato)gallium, tri(tert-butyl)gallium (also referred to as TTBGa), dimethylchlorogallium, or diethylchlorogallium can be used as the precursor containing the first element, for example.

In the case where aluminum is used as the first element, aluminum trichloride, trimethylaluminum (also referred to as TMAl), triethylaluminum (also referred to as TEAl), triisobutylaluminum, dimethylaluminum hydride, tris(dimethylamino)aluminum, tris(diethylamino)aluminum, or tri(tert-butyl)aluminum (also referred to as TTBAl) can be used as the precursor containing the first element, for example.

In the case where yttrium is used as the first element, tris(methylcyclopentadienyl)yttrium(III) (also referred to as Y(MeCp)₃), tris(isopropylcyclopentadienyl)yttrium(III) (also referred to as Y(iPrCp)₃), or tris[N,N-bis(trimethylsilyl)amide]yttrium(III) (also referred to as Y(tmsa)₃) can be used as the precursor containing the first element, for example.

In the case where scandium is used as the first element, tris(cyclopentadienyl)scandium, bis(ethylcyclopentadienyl) (N,N-bis(dimethylamino)acetoamidinate)scandium (also referred to as (EtCp)₂Sc(bdma)), bis(ethylcyclopentadienyl) (di-tert-butyl-triazenide)scandium (also referred to as (EtCp)₂Sc(dtbt)), bis-methylcyclopentadienyl-scandium chloride (also referred to as (MCp)₂ScCl), or triscyclopentadienyl scandium (also referred to as Cp₃Sc) can be used as the precursor containing the first element, for example.

Note that a method for adding Si═O or Si(II) is not limited to the above. For example, an ion implantation method, an ion doping method, a plasma immersion ion implantation method, or plasma treatment can also be used. In this specification and the like, whether or not mass separation is performed is not limited, unless otherwise specified. In this specification and the like, a method by which mass-separated ions are supplied is referred to as an ion implantation method, and a method by which non-mass-separated ions are supplied is referred to as an ion doping method, for example.

For example, an indium oxide film is formed, and then Si═O or Si(II) can be added to the indium oxide film by an ion implantation method, an ion doping method, a plasma immersion ion implantation method, or plasma treatment. Note that the indium oxide film may be an oxide film containing indium and the first element.

Next, an example of a method for forming the metal oxide layer 30_1 is described.

The metal oxide layer 301 can be formed by a sputtering method.

In the case where the metal oxide layers 302 and 30_1 are each formed by a sputtering method using an indium oxide sputtering target, the metal oxide layer 30_2 is preferably formed at a higher power than the metal oxide layer 30_1. In that case, Si═O or Si(II) can be added to the metal oxide layer 302 while being inhibited from entering the metal oxide layer 30_1. Thus, the purity of the metal oxide layer 30_1 can be increased. In addition, the impurity concentration in the metal oxide layer 30_1 can be reduced. When the metal oxide layers 30_2 and 30_1 are formed by the same method, the kinds of targets used for a sputtering method can be reduced, so that the manufacturing cost of the semiconductor device can be reduced.

The metal oxide layer 30_1 can be formed by an ALD method using the first precursor and an oxidizer. The use of an ALD method for forming the metal oxide layer 301 can reduce film formation damage and inhibit entry of Si═O or Si(II) into the metal oxide layer 30_1. Thus, the purity of the metal oxide layer 30_1 can be increased. In addition, the impurity concentration in the metal oxide layer 30_1 can be reduced.

In the case where the metal oxide layer 301 is formed by an ALD method, there is no limitation on the method for forming the metal oxide layer 302. The metal oxide layer 30_2 may be formed by either the above-described sputtering method or the above-described ALD method.

Before the formation of the metal oxide layer 303, the metal oxide layer 30_1 is preferably a sparser film than the metal oxide layer 30_2. Here, a sparse film refers to a film having a lower film density or a higher wet etching rate than a comparative film. A sparse film can also be referred to as a soft film. In the case where the metal oxide layer 30_1 is a sparse film, impurities such as carbon and hydrogen in the metal oxide layer 301 are diffused relatively easily. Thus, when treatment in a later step is performed, impurities such as carbon and hydrogen can be reduced and crystal growth can be promoted in the metal oxide layer 30_1.

For example, an indium oxide film formed by an ALD method may contain impurities, such as carbon and hydrogen, derived from a precursor. Note that an indium oxide film formed by an ALD method is assumed to be a sparse film having an amorphous structure.

Next, an example of a method for forming the metal oxide layer 30_3 is described.

The metal oxide layer 303 can be formed by the ALD method described in the example of the method for forming the metal oxide layer 302. The use of an ALD method for forming the metal oxide layer 30_3 can inhibit entry of Si═O or Si(II) into the metal oxide layer 301. Accordingly, the metal oxide layer 30_1 can maintain its high purity or low impurity concentration.

For another example, an indium oxide film is formed and then Si═O or Si(II) is added to the indium oxide film, whereby the metal oxide layer 30_3 can be formed. Note that the indium oxide film may be an oxide film containing indium and the first element. In addition, Si═O or Si(II) can be added by an ion implantation method, an ion doping method, a plasma immersion ion implantation method, or plasma treatment.

For another example, after the formation of the metal oxide layer 30_1, Si═O or Si(II) is added to the vicinity of the top surface of the metal oxide layer 30_1 by an ion implantation method, an ion doping method, a plasma immersion ion implantation method, or plasma treatment. A portion to which Si═O or Si(II) is added may be regarded as the metal oxide layer 30_3.

The metal oxide layer 30_3 is preferably a denser film than the metal oxide layer 301. Here, a dense film refers to a film having a higher film density or a lower wet etching rate than a comparative film. A dense film can also be referred to as a hard film. With such a structure, impurities from the layer above the metal oxide layer 30_1 can be blocked by the metal oxide layer 30_3.

The metal oxide layers 30_1 to 30_3 are preferably formed successively without exposure to the air. For example, a multi-chamber film formation apparatus can be used. As a result, the amount of hydrogen in the formed metal oxide layers 30_1 to 30_3 can be reduced, and furthermore, entry of hydrogen in the films between film formation steps can be inhibited.

In the above manner, the metal oxide layer 30 including the metal oxide layers 30_1 to 30_3 can be formed.

Note that fluorine is preferably added to the metal oxide layer 30_3 after the treatment for increasing the crystallinity of the metal oxide layer, which will be described later. In some cases, a hydrogen atom contained in the metal oxide layer reacts with fluorine and hydrogen fluoride (denoted as HF) is formed. However, since HF does not function as negative fixed charge, it is difficult to control the threshold voltage of the transistor with HF. In view of this, the treatment for increasing the crystallinity of the metal oxide layer is performed to reduce the hydrogen concentration in the metal oxide layer and then fluorine is added, whereby formation of HF can be inhibited.

After the formation of the metal oxide layer 30, the treatment for increasing the crystallinity of the metal oxide layer is preferably performed. Examples of the treatment for increasing the crystallinity of the metal oxide layer include heat treatment, plasma treatment (including microwave plasma treatment), and light (e.g., ultraviolet light) irradiation treatment. Some of these treatments can be performed concurrently or sequentially. By the treatment, the crystallinity of the metal oxide layer can be increased. Furthermore, impurities such as hydrogen and carbon in the metal oxide layer can be reduced.

As described above, in the case where a metal oxide layer is formed by a sputtering method, a gas containing hydrogen is sometimes used as a sputtering gas so that the formed metal oxide layer has low crystallinity. In the case where a metal oxide layer is formed by an ALD method, a precursor containing hydrocarbon is sometimes used as a precursor containing indium. In these cases, the metal oxide layer contains hydrogen. Along with an increase in the volume of a crystal region (a crystal grain, or a region without grain boundary) in the metal oxide layer, hydrogen is pushed out from the crystal region to a region with low crystallinity (which can also be referred to as the outside of the crystal region). When the hydrogen remains in the metal oxide layer, an increase in crystallinity might be hindered.

In view of this, in the case of performing the treatment for increasing the crystallinity of the metal oxide layer, the insulating layer 20 preferably includes an insulating film having a function of capturing or fixing hydrogen. For example, the insulating layer 20 preferably includes a hafnium oxide film. With such a structure, hydrogen pushed out from the crystal region can be captured or fixed by the insulating layer 20, so that the amount of hydrogen in the metal oxide layer can be reduced. Consequently, an increase in crystallinity can be promoted.

Alternatively, hydrogen pushed out from the crystal region may be outwardly diffused by the treatment for increasing the crystallinity of the metal oxide layer so that the amount of hydrogen in the metal oxide layer is reduced. Consequently, an increase in crystallinity can be promoted.

As the treatment for increasing the crystallinity of the metal oxide layer, microwave plasma treatment is preferable, and microwave plasma treatment in an oxygen-containing atmosphere is particularly preferable.

In this specification and the like, a microwave refers to an electromagnetic wave having a frequency greater than or equal to 300 MHz and less than or equal to 300 GHz. Microwave plasma treatment refers to, for example, treatment using an apparatus including a power source for generating high-density plasma using microwaves. Microwave plasma treatment can also be referred to as microwave-excited high-density plasma treatment.

The microwave plasma treatment is preferably performed under reduced pressure, and the pressure is preferably higher than or equal to 10 Pa and lower than or equal to 1000 Pa, further preferably higher than or equal to 50 Pa and lower than or equal to 700 Pa, still further preferably higher than or equal to 100 Pa and lower than or equal to 400 Pa. The treatment temperature is preferably higher than or equal to room temperature (25 °C) and lower than or equal to 750 °C, further preferably higher than or equal to 300 °C and lower than or equal to 500 °C, and can be higher than or equal to 400 °C and lower than or equal to 450 °C.

In the microwave plasma treatment, substrate heating is preferably performed. For example, the substrate heating temperature is preferably higher than or equal to room temperature (e.g., 25 °C) and lower than or equal to 500 °C, further preferably higher than or equal to 100 °C and lower than or equal to 450 °C, still further preferably higher than or equal to 200 °C and lower than or equal to 450 °C, yet still further preferably higher than or equal to 300 °C and lower than or equal to 450 °C, yet still further preferably higher than or equal to 400 °C and lower than or equal to 450 °C.

The microwave plasma treatment can be performed using an oxygen gas and an argon gas, for example. Note that when the oxygen flow rate ratio (O₂/(O₂+Ar)) in the microwave plasma treatment is too high, discharging tends to be unstable. In view of this, the oxygen flow rate ratio (O₂/(O₂+Ar)) is, for example, preferably higher than 0% and lower than or equal to 50%, further preferably higher than 0% and lower than or equal to 40%, still further preferably higher than 0% and lower than or equal to 30%.

As the microwave plasma treatment time is shorter, the productivity becomes higher. In view of this, the microwave plasma treatment time is preferably longer than or equal to 1 minute and shorter than or equal to 60 minutes, further preferably longer than or equal to 1 minute and shorter than or equal to 30 minutes, still further preferably longer than or equal to 1 minute and shorter than or equal to 10 minutes.

As the treatment for increasing the crystallinity of the metal oxide layer, heat treatment can also be performed. The heat treatment can be performed at higher than or equal to 250 °C and lower than or equal to 650 °C, preferably higher than or equal to 300 °C and lower than or equal to 500 °C, further preferably higher than or equal to 320 °C and lower than or equal to 450 °C, still further preferably higher than or equal to 320 °C and lower than or equal to 400 °C, for example. By the heat treatment, the crystal grain size in the metal oxide layer can be increased. The film density of the metal oxide layer can be increased. The amount of excess hydrogen in the metal oxide layer can be reduced.

When the temperature of the heat treatment is lower than or equal to 450 °C, preferably lower than or equal to 400 °C, for example, a transistor including the metal oxide layer can be formed over a layer including a copper wiring. Note that when the temperature is lower than 250 °C, an increase in the density of the metal oxide layer might be insufficient, and thus a high on-state current might be difficult to achieve.

The heat treatment is preferably performed under a reduced pressure. The heat treatment can also be performed in an atmosphere of an inert gas (e.g., one or both of a nitrogen gas and a noble gas) or an atmosphere containing an oxidizing gas at 10 ppm (0.001%) or more, 1% or more, or 10% or more. In the case where the heat treatment is performed in a mixed atmosphere of a nitrogen gas and an oxygen gas, for example, the proportion of the oxygen gas is preferably approximately 20%. Alternatively, the heat treatment can be performed in the following manner: heat treatment is performed in an atmosphere of an inert gas, and then another heat treatment is performed in an atmosphere containing an oxidizing gas at 10 ppm or more, 1% or more, or 10% or more in order to compensate for released oxygen.

The gas used in the heat treatment is preferably highly purified. For example, the amount of moisture contained in the gas used in the heat treatment is preferably less than or equal to 1 ppb (1×10⁻³ ppm), further preferably less than or equal to 0.1 ppb (1×10⁻⁴ ppm), still further preferably less than or equal to 0.05 ppb (5×10⁻⁵ ppm). The heat treatment using a highly purified gas can prevent entry of moisture or the like into the metal oxide layer 30 as much as possible.

A heating apparatus used for the heat treatment is not limited to a particular apparatus, and may be an apparatus for heating an object to be processed by heat conduction or heat radiation from a heating element such as a resistance heating element. For example, an electric furnace, or a rapid thermal annealing (RTA) apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas.

With an RTA apparatus, the heat treatment time can be shortened. The heat treatment time is preferably longer than or equal to 1 minute and shorter than or equal to 10 minutes, further preferably longer than or equal to 3 minutes and shorter than or equal 10 minutes, still further preferably longer than or equal to 5 minutes and shorter than or equal to 10 minutes. Note that when the heat treatment time is shortened with an RTA apparatus, the heating temperature can be higher than or equal to the strain point of the substrate. This can further shorten the heat treatment time. The heating temperature is preferably higher than or equal to 400 °C and lower than or equal to 750 °C, further preferably higher than or equal to 450 °C and lower than or equal to 700 °C.

Note that by the heat treatment performed in the above temperature range, Si═O or Si(II) is diffused into indium sites of indium oxide in some cases. Alternatively, Si═O or Si(II) is substituted for an indium atom in some cases. Alternatively, the bond forming Si═O is cut off and oxygen that has formed Si═O is bonded to an indium atom in some cases.

Then, the insulating layer 50 is formed over the metal oxide layer 30. As an oxidizer used in formation of the insulating layer 50 by an ALD method, an oxidizer that can be used in formation of the metal oxide layer 30 can be used.

Then, the conductive layer 60 is formed over the insulating layer 50.

Through the above steps, the semiconductor device illustrated in FIG. 1C can be manufactured.

This embodiment can be combined as appropriate with the other embodiments. In this specification, in the case where a plurality of structure examples are shown in one embodiment, the structure examples can be combined as appropriate.

### Embodiment 2

In this embodiment, structure examples of a semiconductor device of one embodiment of the present invention will be described. The semiconductor device of one embodiment of the present invention includes a transistor. The transistor includes a semiconductor layer, a conductive layer functioning as a gate electrode, and an insulating layer functioning as a gate insulating layer. The insulating layer includes a portion positioned between the semiconductor layer and the conductive layer. The metal oxide layer exemplified in Embodiment 1 can be used as the semiconductor layer of the transistor exemplified below.

### Structure Example of Semiconductor Device

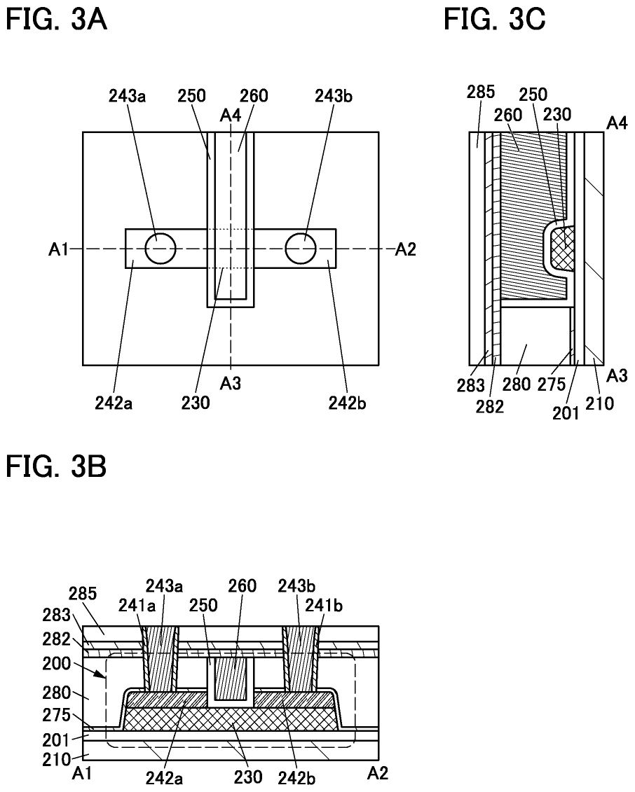

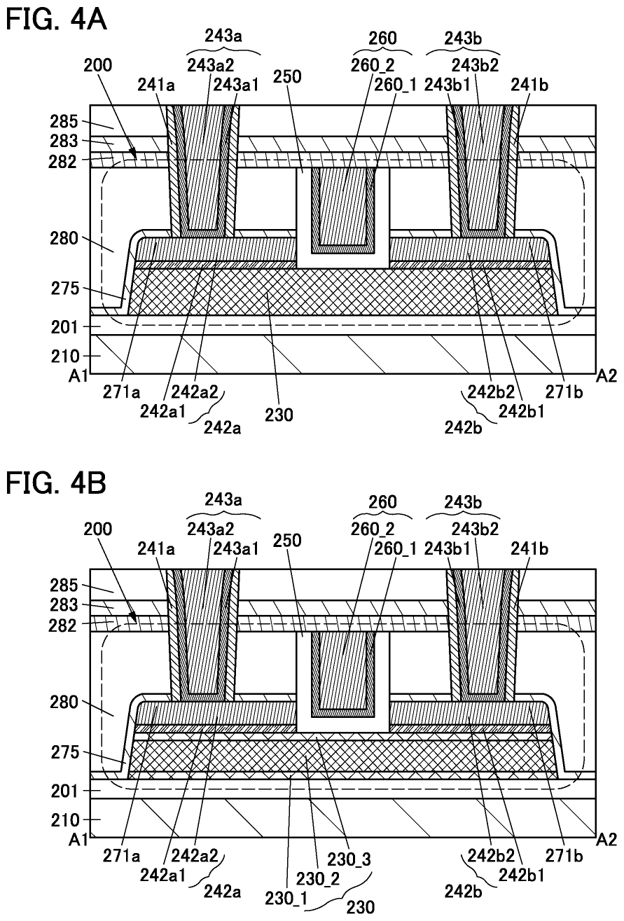

FIG. 3A is a top view of a semiconductor device including a transistor 200, and FIGS. 3B and 3C are cross-sectional views respectively corresponding to cutting lines A1-A2 and A3-A4 in FIG. 3A. FIG. 3B corresponds to a cross-sectional view of the transistor 200 in the channel length direction, and FIG. 3C corresponds to a cross-sectional view of the transistor 200 in the channel width direction. FIGS. 4A and 4B are enlarged views of FIG. 3B. Note that some components are omitted in FIG. 3A.

The semiconductor device illustrated in FIGS. 3A to 3C includes a substrate 210, an insulating layer 201 over the substrate 210, and the transistor 200 over the insulating layer 201. The transistor 200 includes a semiconductor layer 230; a conductive layer 242a, a conductive layer 242b, and an insulating layer 250 that are over the semiconductor layer 230; and a conductive layer 260 over the insulating layer 250. The conductive layers 242a and 242b are in contact with the semiconductor layer 230 and are apart from each other.

An insulating layer 275 is provided to cover the semiconductor layer 230, the conductive layer 242a, and the conductive layer 242b, and an insulating layer 280 is provided over the insulating layer 275. An opening portion (also referred to as a groove portion) reaching the semiconductor layer 230 is formed in the insulating layers 280 and 275. The insulating layer 250 is provided along the surfaces of the insulating layer 280, the insulating layer 275, the conductive layer 242a, the conductive layer 242b, the semiconductor layer 230, and the insulating layer 201 in the opening portion. The conductive layer 260 is provided to fill the opening portion. An insulating layer 282 is provided over the insulating layer 280, the insulating layer 250, and the conducting layer 260, an insulating layer 283 is provided over the insulating layer 282, and an insulating layer 285 is provided over the insulating layer 283.

In the transistor 200, the conductive layer 260 functions as a gate electrode, and the insulating layer 250 functions as a gate insulating layer. The conductive layer 242a functions as one of a source electrode and a drain electrode, and the conductive layer 242b functions as the other.

In the semiconductor layer 230, a channel formation region and source and drain regions of the transistor 200 are formed. The channel formation region is interposed between the source and drain regions. At least part of the channel formation region overlaps with the conductive layer 260. The source region and the drain region overlap with the conductive layer 242a and the conductive layer 242b, respectively. Note that the source region and the drain region can be interchanged with each other. The source region and the drain region are n-type regions (low-resistance regions) having a higher carrier concentration than the channel formation region.

The metal oxide layer 30, the insulating layer 50, the conductive layer 60, and the insulating layer 20 that are exemplified in Embodiment 1 can be used as the semiconductor layer 230, the insulating layer 250, the conductive layer 260, and the insulating layer 201, respectively.

FIG. 4A illustrates a structure where the semiconductor layer 230 is a single layer. The semiconductor layer 230 can have a stacked-layer structure. In a structure example illustrated in FIG. 4B, the semiconductor layer 230 includes a semiconductor layer 230_1, a semiconductor layer 230_2 over the semiconductor layer 230_1, and a semiconductor layer 230_3 over the semiconductor layer 230_2. The metal oxide layer 302, the metal oxide layer 30_1, and the metal oxide layer 30_3 that are exemplified in Embodiment 1 can be used as the semiconductor layer 230_1, the semiconductor layer 2302, and the semiconductor layer 2303, respectively.

In order that the transistor can have a high on-state current, the thickness of the semiconductor layer 230_2 is preferably large. Meanwhile, when the thickness of the semiconductor layer 230_2 is too large, the amount of crystal grain boundaries is increased by self-crystallization, which might cause the on-state current of the transistor to be lowered owing to the influence of carrier scattering at the crystal grain boundary. In view of this, the thickness of the semiconductor layer 230_2 is preferably equal to or smaller than the channel length of the transistor 200. The thickness of the semiconductor layer 230_2 is, for example, greater than or equal to 2 nm and less than or equal to 50 nm, preferably greater than or equal to 2 nm and less than or equal to 30 nm, further preferably greater than or equal to 2 nm and less than or equal to 20 nm, still further preferably greater than or equal to 5 nm and less than or equal to 20 nm, yet still further preferably greater than or equal to 5 nm and less than or equal to 10 nm. It is preferable that the semiconductor layer 230_2 at least partly include a region with the above-described thickness.

Note that a channel is sometimes formed in one or both of the semiconductor layers 230_1 and 230_3. In that case, the thickness of the semiconductor layer 230, i.e., the total thickness of the semiconductor layers 230_1 to 2303, is preferably equal to or smaller than the channel length.

The thicknesses of the semiconductor layers 230_1 and 230_3 are each preferably smaller than that of the semiconductor layer 230_2. The thicknesses of the semiconductor layers 230_1 and 230_3 are each greater than or equal to 0.1 nm and less than or equal to 3 nm, preferably greater than or equal to 0.1 nm and less than or equal to 2.5 nm, further preferably greater than or equal to 0.1 nm and less than or equal to 2 nm, still further preferably greater than or equal to 0.5 nm and less than or equal to 2 nm. It is preferable that each of the semiconductor layers 230_1 and 230_3 at least partly include a region with the above-described thickness.

The conductive layers 242a and 242b each preferably have a stacked-layer structure. For example, as illustrated in FIG. 4A, the conductive layer 242a can include a conductive layer 242a1 over the semiconductor layer 230 and a conductive layer 242a2 over the conductive layer 242a1. The conductive layer 242b can include a conductive layer 242b1 over the semiconductor layer 230 and a conductive layer 242b2 over the conductive layer 242b1.

The conductive layers 242a1 and 242b1 can be formed using a conductive material that is not easily oxidized, a conductive material that maintains its low electric resistance even after being oxidized, a metal oxide that has conductivity (a conductive oxide), or a conductive material that has a function of inhibiting diffusion of oxygen. With such a structure, the conductive layers 242a and 242b can each maintain its conductivity even after absorbing oxygen. The conductive layers 242a1 and 242b1 each contain indium, a second element, and oxygen, for example. The second element is preferably one or more selected from tin, zinc, tungsten, titanium, and zirconium. Specifically, the conductive layers 242a1 and 242b1 can be formed using a metal oxide such as In—Sn oxide, ITSO, In—Zn oxide, In—Sn—W oxide, In—Ti oxide, or In—Zr oxide.

When the source and drain electrodes and the semiconductor layer contain a common element as the main component, the work functions of the source and drain electrodes can be substantially equal to the electron affinity of the semiconductor layer. In this case, an energy barrier between the source and drain electrodes and the semiconductor layer can be reduced. Thus, the contact resistance between the semiconductor layer and each of the source and drain electrodes can be reduced. For example, the source and drain electrodes and the semiconductor layer can contain indium as the main component.

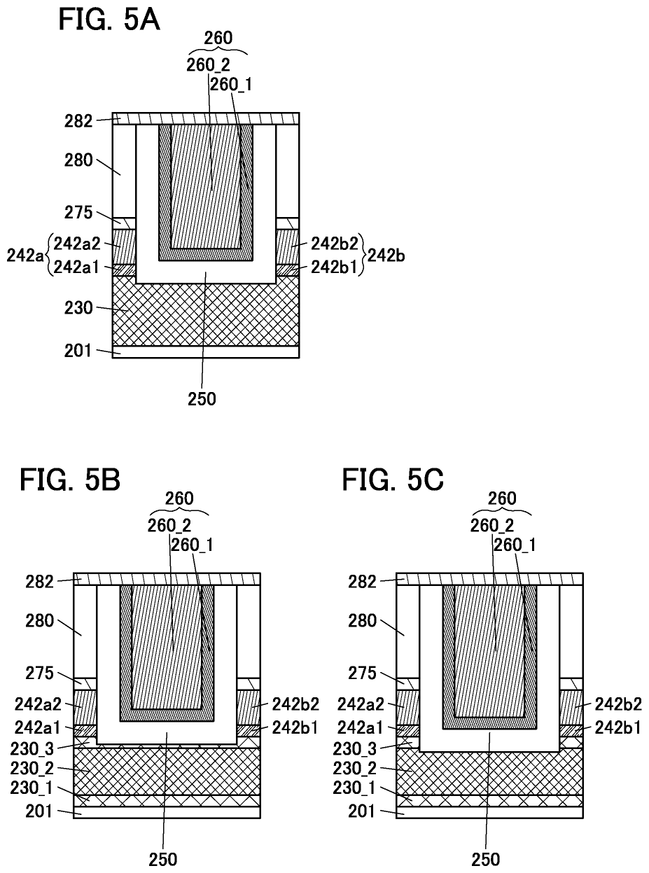

When the semiconductor layer 230 and the conductive layers 242a1 and 242b1 contain a common element as the main component, the thickness of the semiconductor layer 230 might be reduced in processing a conductive layer to be the conductive layers 242a1 and 242b1. In this case, the thickness of a portion of the semiconductor layer 230 that overlaps with the conductive layer 260 is smaller than the thickness of a portion of the semiconductor layer 230 that overlaps with the conductive layer 242a1 or the conductive layer 242b1 (see FIG. 5A).

Note that the thickness of the semiconductor layer 230 is reduced as described above also in the case where the semiconductor layer 230 has a stacked-layer structure. For example, when the semiconductor layer 230 has a three-layer structure of the semiconductor layers 230_1 to 2303, the thickness of a portion of the semiconductor layer 230_3 that overlaps with the conductive layer 260 is sometimes smaller than the thickness of a portion of the semiconductor layer 230_3 that overlaps with the conductive layer 242a1 or the conductive layer 242b1 (see FIG. 5B). Alternatively, a portion of the semiconductor layer 230_3 that overlaps with the insulating layer 250 is sometimes removed (see FIG. 5C).

The conductive layers 242a1 and 242b1 can also be formed using a conductive material having a function of inhibiting passage of impurities such as water and hydrogen, such as tantalum, tantalum nitride, titanium, titanium nitride, ruthenium, or ruthenium oxide. The conductive material having a function of inhibiting passage of impurities such as water and hydrogen can be used as a single layer or stacked layers. Providing the conductive layers 242a1 and 242b1 can inhibit entry of impurities such as water and hydrogen into the semiconductor layer 230 through the conductive layers 242a2 and 242b2.

The conductive layers 242a2 and 242b2 are preferably formed using a metal or an alloy having higher conductivity than the conductive layers 242a1 and 242b1. For example, a low-resistance conductive material such as tungsten, copper, or aluminum is preferably used. This can increase the conductivity of the conductive layers 242a and 242b.

A material containing a metal element such as gold, platinum, palladium, silver, ruthenium, copper, bismuth, lead, tin, nickel, cobalt, cadmium, or iron is a conductive material that is less likely to be oxidized and thus can be used for the conductive layers 242a1 and 242b1. Moreover, these materials tend to have low resistivity and thus can be used for the conductive layers 242a2 and 242b2.

For example, the conductive layers 242a1 and 242b1 can be formed using ITO, and the conductive layers 242a2 and 242b2 can be formed using tungsten.

The conductive layers 242a and 242b can each have a single-layer structure. In this case, the above-described metal oxide such as ITO or ITSO can be used for the conductive layers 242a and 242b.

As the substrate 210, for example, an insulator substrate, a semiconductor substrate, or a conductor substrate can be used. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate such as a silicon substrate, a germanium substrate, and the like, and a compound semiconductor substrate of silicon carbide, silicon germanium, gallium arsenide, indium phosphide, zinc oxide, or gallium oxide. Other examples include the above semiconductor substrate including an insulator region, e.g., a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided over the substrate include a capacitor, a resistor, a switching element, a light-emitting element, and a memory element.

The insulating layer 201 preferably has an amorphous structure. When the insulating layer 201 has a polycrystalline structure or a single crystal structure, in a later step of forming the semiconductor layer 230, the semiconductor layer 230 might be crystallized reflecting the crystal structure of the insulating layer 201, leading to formation of a polycrystalline structure having small crystal grains. Instead, when the insulating layer 201 has an amorphous structure, unintentional crystallization of the semiconductor layer 230 is inhibited, so that the semiconductor layer 230 having large crystal grains can be formed.

The top surface of the insulating layer 201 is preferably flat. This structure can inhibit nucleation derived from the top surface unevenness of the insulating layer 201 and promote crystal growth in the semiconductor layer.

In this specification and the like, when the average roughness (Ra) of the top surface of a layer is less than 3 nm, the top surface of the layer is regarded as flat. Note that the average roughness (Ra) is obtained by expanding arithmetic mean roughness which is defined by JIS B 0601:2013 (ISO 4287:1997) into three dimensions for application to a curved surface. The average roughness (Ra) can be evaluated using an atomic force microscope (AFM). Note that the average roughness (Ra) can be calculated from a region of 1 mm square, for example. In the case where the region of 1 mm square is not included in a plan view of an island-shaped layer, the calculation maybe performed on the entire region of the layer in the plan view. Note that average roughness (Ra) in this specification and the like may be rephrased as root-mean-square roughness (Rq or RMS) or maximum height roughness (Rz).

The flatness of the top surface of a layer can also be evaluated by image analysis of a TEM image. For example, the contrast observed in the TEM image is assumed to be at the interface between a first layer and a second layer, and the shape of the interface is assumed to be a roughness curve of the first layer. Then, the arithmetic mean roughness can be calculated from the assumed roughness curve. Note that the reference length may be the length of the top surface of the first layer observed in the TEM image, or may also be the length of the region where the first layer and the second layer overlap with each other. The reference length is 100 nm, for example. In that case, the observed range of the TEM image is preferably longer than or equal to 100 nm in either the vertical direction or the horizontal direction. Even in the case where the arithmetic mean roughness of the top surface of the first layer calculated using this method is less than 3 nm, the top surface of the first layer can be regarded as flat.

The average roughness (Ra) or the arithmetic mean roughness of the top surface of the insulating layer 201 is preferably greater than or equal to 0 nm and less than 3 nm, further preferably greater than or equal to 0 nm and less than or equal to 2 nm, still further preferably greater than or equal to 0 nm and less than or equal to 1 nm, yet still further preferably greater than or equal to 0 nm and less than or equal to 0.5 nm, yet still further preferably greater than or equal to 0 nm and less than or equal to 0.3 nm, yet still further preferably greater than or equal to 0 nm and less than or equal to 0.2 nm.

For example, the flatness of the top surface of the insulating layer 201 can be improved by chemical mechanical polishing (CMP) treatment or the like. Note that in the case where the insulating layer 201 has a stacked-layer structure of n layers (n is an integer greater than or equal to 2), CMP treatment can be performed on the uppermost layer (the n-th layer) of the insulating layer 201. Alternatively, CMP treatment may be performed on a layer other than the uppermost layer (the k-th layer: k is an integer greater than or equal to 1 and less than or equal to n−1) of the insulating layer 201, and the k+1-th to n-th layers may be formed over the planarized k-th layer.

The insulating layer 201 may include a groove portion, a depressed portion, an opening portion, a trench, a slit, or the like, or may include a projecting portion, a protruding portion, or the like, for example. Also in such a case, the semiconductor layer 230 having crystallinity can be formed.

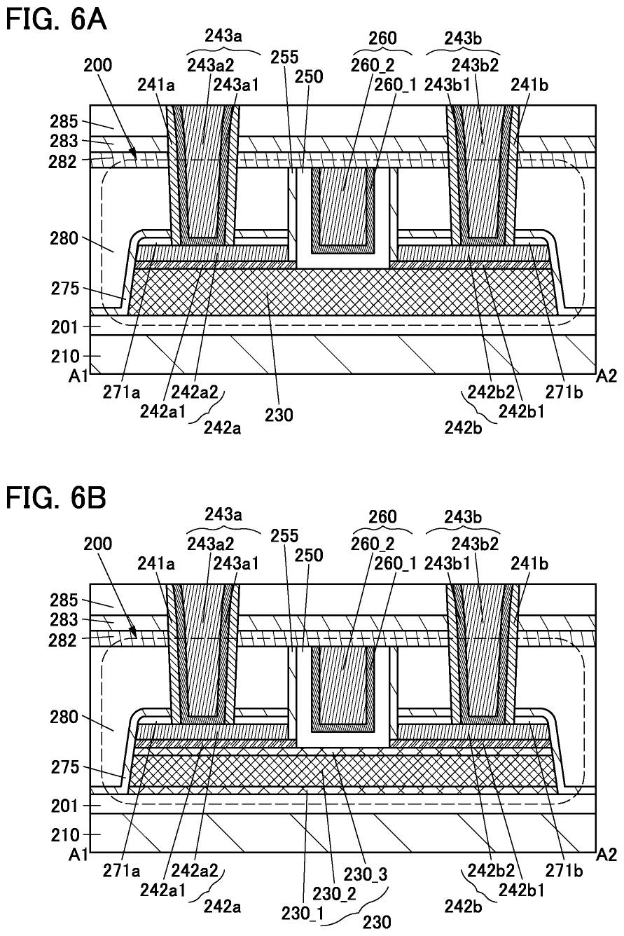

As illustrated in FIG. 6A, an insulating layer 271a can be provided between the conductive layer 242a and the insulating layer 275, and an insulating layer 271b can be provided between the conductive layer 242b and the insulating layer 275. The insulating layer 271a and the insulating layer 271b function as etching stoppers at the time of processing the conductive layer 242a and the conductive layer 242b. That is, the insulating layer 271a and the insulating layer 271b have a function of protecting the conductive layer 242a and the conductive layer 242b, respectively. The insulating layer 271a and the insulating layer 271b are in contact with the conductive layer 242a and the conductive layer 242b, respectively, and thus are preferably inorganic insulators that are less likely to oxidize the conductive layer 242a and the conductive layer 242b. The insulating layer 271a can have a stacked-layer structure of a silicon nitride film in contact with the conductive layer 242a and a silicon oxide film over the silicon nitride film, for example. The insulating layer 271b can also have such a stacked-layer structure.

As illustrated in FIG. 6A, an insulating layer 255 can be provided between the insulating layer 250 and each of the conductive layers 242a2 and 242b2. The insulating layer 255 is in contact with the conductive layers 242a2 and 242b2 and thus is preferably an inorganic insulator that is less likely to oxidize the conductive layers 242a2 and 242b2. The insulating layer 255 can prevent the conductive layers 242a2 and 242b2 from being excessively oxidized by heat treatment even when a tungsten film or the like that is relatively easily oxidized is used as the conductive layers 242a2 and 242b2. A silicon nitride film can be used as the insulating layer 255, for example.

The insulating layer 255 can be formed in the following manner: an opening portion is formed in the insulating layers 280 and 275, portions overlapping with the opening portion in an insulating layer to be the insulating layers 271a and 271b and a conductive layer to be the conductive layers 242a2 and 242b2 are removed, an insulating film to be the insulating layer 255 is formed, and the insulating film is processed by anisotropic etching. That is, the insulating layer 255 is formed in a sidewall shape in contact with the side surface of the opening portion.

FIG. 6B illustrates a structure example in which the semiconductor layer 230 has a three-layer structure of the semiconductor layers 230_1 to 230_3 in the structure illustrated in FIG. 6A.

The conductive layer 260 is preferably provided to extend in the channel width direction as illustrated in FIGS. 3A and 3C. With such a structure, the conductive layer 260 functions as a wiring when a plurality of transistors are provided.

The conductive layer 260 can have a single-layer structure or a stacked-layer structure of two or more layers. FIG. 4A illustrates an example in which the conductive layer 260 has a two-layer structure. The conductive layer 260 illustrated in FIG. 4A includes a conductive layer 260_1 and a conductive layer 260_2 over the conductive layer 260_1. The conductive layer 260_1 is in contact with the insulating layer 250. The conductive layer 260_1 is preferably formed using a conductive material that is less likely to be oxidized, such as titanium, titanium nitride, tantalum, tantalum nitride, ruthenium, or ruthenium oxide, or a conductive material having a function of inhibiting diffusion of oxygen. The conductive layer 260_2 is preferably formed using a low-resistance conductive material such as tungsten, copper, or aluminum.

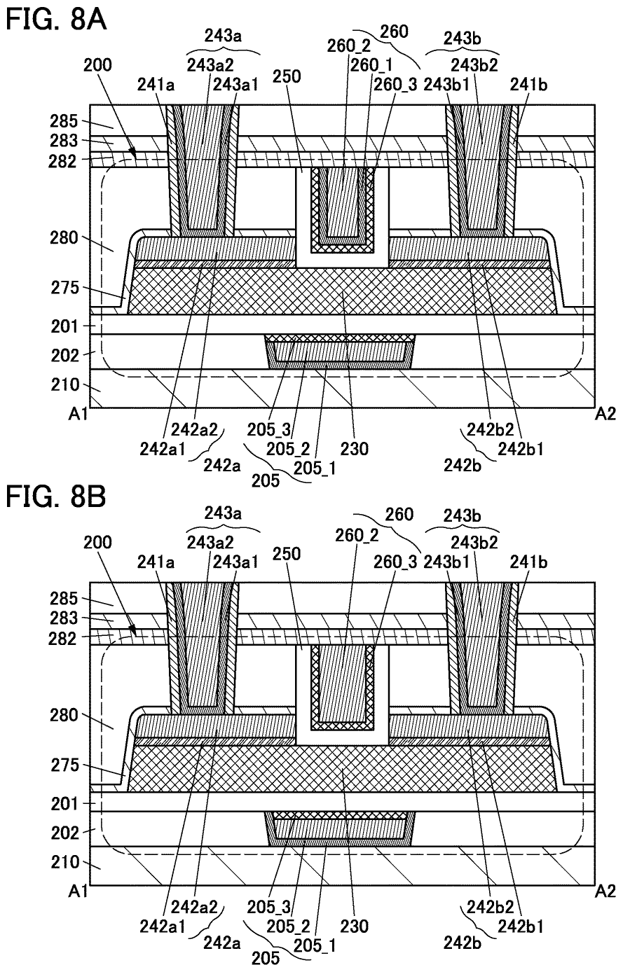

It is also possible to provide a conductive film containing a material with a high work function between the insulating layer 250 and the conductive layer 260_1. FIG. 8A illustrates a structure where a conductive layer 260_3 is provided between the insulating layer 250 and the conductive layer 260_1. The conductive layer 260_3 preferably contains a material with a high work function, and is preferably formed using nickel, cobalt, a conductive oxide, or the like. With such a structure, the threshold voltage of the transistor can be shifted positively. Moreover, the transistor can have normally-off characteristics. Accordingly, the transistor having favorable electrical characteristics can be provided. Furthermore, when silicon nitride is used for a layer (an insulating layer 2503 described later) of the insulating layer 250 that is in contact with the conductive layer 260, oxidation of the conductive layer 260_3 can be inhibited.

Note that in the structure illustrated in FIG. 8A, the conductive layer 2601 is not necessarily provided. FIG. 8B illustrates an example in which the conductive layer 260 has a two-layer structure of the conductive layer 260_3 and the conductive layer 260_2 over the conductive layer 260_3.

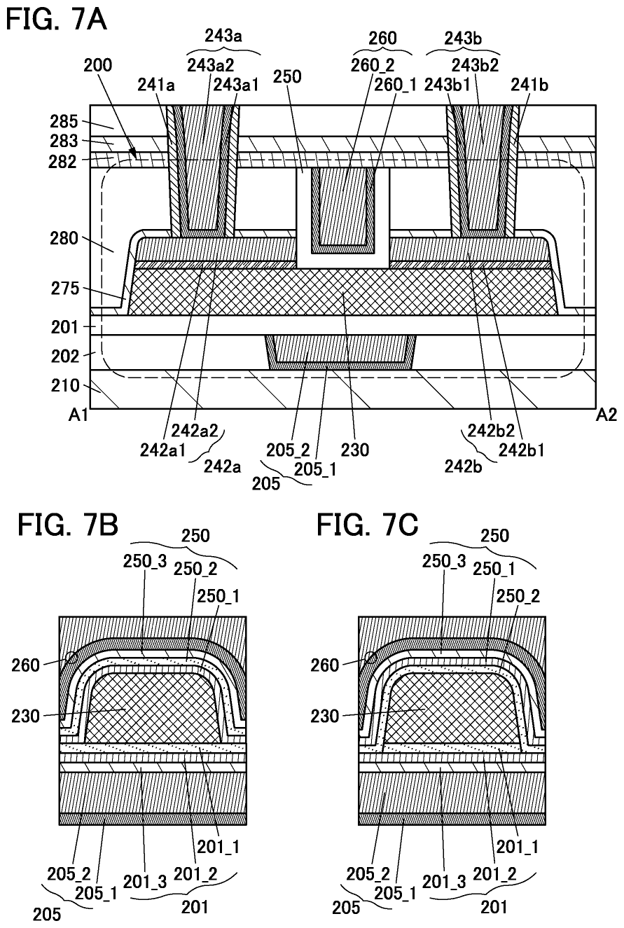

As illustrated in FIG. 7A, a conductive layer 205 functioning as a back gate of the transistor can be provided. The transistor 200 illustrated in FIG. 7A is different from the transistor illustrated in FIG. 4A mainly in including the conductive layer 205 and an insulating layer 202.

The insulating layer 202 is provided below the insulating layer 201, and the conductive layer 205 is provided to be embedded in the insulating layer 202. The top surface of the conductive layer 205 and the top surface of the insulating layer 202 are level with each other. The insulating layer 201 is provided to cover the insulating layer 202 and the conductive layer 205. When provided over the conductive layer 205 and the insulating layer 202 whose top surfaces are level with each other, the insulating layer 201 can have a top surface with high flatness.

The conductive layer 205 functions as a second gate (back gate) of the transistor 200. The conductive layer 205 is provided in a region overlapping with the conductive layer 260 with the semiconductor layer 230 therebetween. Note that the conductive layer 260 is referred to as a first gate (front gate) in some cases.

The conductive layer 205 can be formed using a material usable for the conductive layer 260. The conductive layer 205 may have a stacked-layer structure. For example, the conductive layer 205 can have a stacked-layer structure of a titanium nitride film in contact with the insulating layer 202 and the substrate 210 and a tungsten film over the titanium nitride film.

The conductive layer 205 can have a single-layer structure or a stacked-layer structure of two or more layers. FIG. 7A illustrates an example in which the conductive layer 205 has a two-layer structure. The conductive layer 205 illustrated in FIG. 7A includes a conductive layer 205_1 and a conductive layer 205_2 over the conductive layer 205_1. The conductive layer 205_1 is in contact with the insulating layer 202 and the substrate 210. The conductive layer 205_1 is preferably formed using a conductive material that is less likely to be oxidized, such as titanium, titanium nitride, tantalum, tantalum nitride, ruthenium, or ruthenium oxide, or a conductive material having a function of inhibiting diffusion of oxygen. The conductive layer 205_2 is preferably formed using a low-resistance conductive material such as tungsten, copper, or aluminum.

It is also possible to provide a conductive film containing a material with a high work function between the insulating layer 201 and the conductive layers 205_1 and 205_2. FIG. 8A illustrates the structure where a conductive layer 205_3 is provided between the insulating layer 201 and the conductive layers 205_1 and 205_2. The conductive layer 205_3 preferably contains a material with a high work function, and is preferably formed using nickel, cobalt, a conductive oxide, or the like. With such a structure, the threshold voltage of the transistor can be shifted positively. Moreover, the transistor can have normally-off characteristics. Accordingly, the transistor having favorable electrical characteristics can be provided. Furthermore, when silicon nitride is used for a layer (an insulating layer 201_3 described later) of the insulating layer 201 that is in contact with the conductive layer 205, oxidation of the conductive layer 205_3 can be inhibited.

As illustrated in FIG. 8B, the conductive layer 205_3 can be in contact with the side surface of the conductive layer 205_1. Such a structure can further inhibit oxidation of the conductive layer 205_3.

Note that in the structure illustrated in FIG. 8B, the conductive layer 205_2 is not necessarily provided. In this case, the conductive layer 2053 is embedded in a depressed portion of the conductive layer 205_1. When the conductive layer 205_2 is not provided, the manufacturing process of the semiconductor device can be shortened, so that the manufacturing cost of the semiconductor device can be reduced.

In the case where the conductive layer 205 functions as the second gate of the transistor 200, the insulating layer 201 functions as a second gate insulating layer.

A silicon oxide film can be used as the insulating layer 202. Note that it is also possible to provide an insulating film having a barrier property against oxygen between the insulating layer 202 and the conductive layer 205. In this case, oxidation of the conductive layer 205 can be inhibited.

The insulating layer 250 can have a stacked-layer structure of two or more layers. For example, as illustrated in FIG. 7B, the insulating layer 250 can have a three-layer structure of an insulating layer 250_1 in contact with the semiconductor layer 230, an insulating layer 250_2 over the insulating layer 2501, and the insulating layer 250_3 over the insulating layer 250_2. For another example, as illustrated in FIG. 7C, the insulating layer 250 can have a three-layer structure of the insulating layer 250_2 in contact with the semiconductor layer 230, the insulating layer 250_1 over the insulating layer 2502, and the insulating layer 250_3 over the insulating layer 250_1.

The insulating layer 501, the insulating layer 502, and the insulating layer 50_3 that are exemplified in Embodiment 1 can be used as the insulating layer 2501, the insulating layer 250_2, and the insulating layer 2503, respectively.

The insulating layer 201 can have a stacked-layer structure of two or more layers. For example, FIG. 7B illustrates an example in which the insulating layer 201 has a stacked-layer structure of an insulating layer 201_1 in contact with the semiconductor layer 230, an insulating layer 201_2 under the insulating layer 2011, and the insulating layer 2013 under the insulating layer 201_2.

The insulating layer 502, the insulating layer 50_1, and the insulating layer 50_3 that are exemplified in Embodiment 1 can be used as the insulating layer 2011, the insulating layer 201_2, and the insulating layer 2013, respectively.

An insulating film having a barrier property against oxygen may be provided between the semiconductor layer 230 and the insulating layer 201_1. In this case, diffusion of oxygen contained in the channel formation region into the conductive layer 205 and formation of oxygen vacancies in the channel formation region can be inhibited. Moreover, oxygen contained in the semiconductor layer 230 can be inhibited from being diffused into the conductive layer 205 and oxidizing the conductive layer 205.

In the manufacturing process of the semiconductor device, oxygen can be supplied from the insulating layers 250 and 201 to the semiconductor layer 230 by heat treatment. Here, when an insulating layer supplying oxygen when heated is provided only on the insulating layer 250 side, oxygen can be selectively supplied to the channel formation region in the semiconductor layer 230. Thus, in some cases, an insulating layer supplying oxygen when heated is not necessarily provided on the insulating layer 201 side.

In processing the semiconductor layer 230 into an island shape, a portion of the insulating layer 201_1 that does not overlap with the semiconductor layer 230 is sometimes removed. FIG. 7C illustrates a structure example in which the insulating layer 201_1 has an island shape in a plan view.

When the insulating layers 250 and 201 each have a thickness greater than or equal to 1 nm and less than or equal to 20 nm, preferably greater than or equal to 3 nm and less than or equal to 10 nm, the subthreshold swing value (also referred to as S value), which is one of transistor characteristics, can be reduced. Note that the S value means the amount of change in gate voltage in a subthreshold region when drain voltage is constant and drain current is changed by one order of magnitude.

The thicknesses of the layers included in the insulating layers 250 and 201 are each preferably greater than or equal to 0.1 nm and less than or equal to 10 nm, further preferably greater than or equal to 0.1 nm and less than or equal to 5 nm, still further preferably greater than or equal to 0.5 nm and less than or equal to 5 nm, yet still further preferably greater than or equal to 1 nm and less than 5 nm, yet still further preferably greater than or equal to 1 nm and less than or equal to 3 nm. Note that each of the layers included in the insulating layers 250 and 201 at least partly includes a region with the above-described thickness.

The insulating layer 201 is not necessarily provided in the opening portion and thus can have a thickness greater than or equal to 10 nm or greater than or equal to 20 nm. For example, the thickness of the insulating layer 201 may be greater than or equal to 10 nm and less than or equal to 100 nm or greater than or equal to 20 nm and less than or equal to 100 nm. The thickness of each layer included in the insulating layer 201 may be greater than or equal to 1 nm and less than or equal to 50 nm or greater than or equal to 3 nm and less than or equal to 50 nm.

In the case where the insulating layers 250 and 201 are formed using a material that can have ferroelectricity, the transistor can function as a ferroelectric field-effect transistor (FeFET), for example.

As an example of the material that can have ferroelectricity, an oxide containing one or both of hafnium and zirconium is given. As an example of the oxide, a metal oxide such as hafnium oxide, zirconium oxide, or hafnium zirconium oxide is given. As the material that can have ferroelectricity, a material in which an element J1 (the element J1 here is one or more selected from one of hafnium and zirconium, silicon, aluminum, scandium, yttrium, lanthanum, strontium, gadolinium, and the like) is added to a metal oxide containing the other of hafnium and zirconium may also be used.

Since the above-listed materials and the like may change their crystal structures (characteristics) according to a variety of processes and the like as well as film formation conditions, a material that exhibits ferroelectricity is referred to not only as a ferroelectric but also as a material that can have ferroelectricity in this specification and the like.

The insulating layer 275 preferably has a barrier property against hydrogen. The insulating layer 275 is provided between the insulating layer 280 and the semiconductor layer 230. Such a structure can inhibit diffusion of hydrogen contained in the insulating layer 280 into the semiconductor layer 230. Accordingly, an increase in the hydrogen concentration in the semiconductor layer 230, particularly in the channel formation region, due to hydrogen contained in the insulating layer 280 can be inhibited. For example, the insulating layer 275 is preferably formed using silicon nitride. Silicon nitride also has a barrier property against oxygen and thus can be regarded as an insulator having a barrier property against hydrogen and oxygen.

The insulating layer 280 preferably has a low dielectric constant. When an interlayer film contains a material with a low dielectric constant, parasitic capacitance generated between wirings can be reduced. For example, the insulating layer 280 preferably includes one or more of silicon oxide, silicon oxynitride, silicon oxide to which fluorine is added, silicon oxide to which carbon is added, silicon oxide to which carbon and nitrogen are added, and porous silicon oxide. Silicon oxide and silicon oxynitride, which have thermal stability, are preferable. In particular, materials such as silicon oxide, silicon oxynitride, and porous silicon oxide are preferably used, in which case a region containing oxygen that is released by heating can be easily formed.

In addition to the above structure, the semiconductor device of this embodiment preferably has a structure where hydrogen is prevented from entering the transistor 200 or the like. For example, an insulating layer having a function of inhibiting diffusion of hydrogen is preferably provided to cover the transistor 200. In the semiconductor device described in this embodiment, the insulating layer corresponds to, for example, the insulating layer 282, the insulating layer 283, and the like.

One or both of the insulating layers 282 and 283 preferably function as a barrier insulator that inhibits diffusion of impurities such as water and hydrogen into the transistor 200 or the like from above the transistor 200 or the like. Therefore, one or both of the insulating layers 282 and 283 preferably contain an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom, that is, an insulating material through which the impurities are less likely to pass. Alternatively, one or both of the insulating layers 282 and 283 preferably contain an insulating material having a function of inhibiting diffusion of oxygen (e.g., at least one of an oxygen atom, an oxygen molecule, and the like), that is, an insulating material through which the oxygen is less likely to pass.

The insulating layers 282 and 283 each preferably include an insulator having a function of inhibiting diffusion of impurities, such as water and hydrogen, and oxygen; for example, aluminum oxide, magnesium oxide, hafnium oxide, gallium oxide, silicon nitride, or silicon nitride oxide can be used. For example, the insulating layer 283 is preferably formed using silicon nitride, which has a higher hydrogen barrier property. For example, the insulating layer 282 preferably includes aluminum oxide or magnesium oxide, which has high hydrogen-capturing and hydrogen-fixing capabilities. With this structure, impurities such as water and hydrogen can be inhibited from being diffused into the transistor 200 or the like from an interlayer insulating film or the like positioned outside the insulating layer 283. Moreover, oxygen contained in the insulating layer 280 or the like can be inhibited from being diffused to above the transistor 200 or the like through the insulating layer 282 or the like. When a film similar to one or both of the insulating layers 282 and 283 is provided below the transistor 200, impurities such as water and hydrogen can be inhibited from being diffused into the transistor 200 or the like from the substrate side.

An opening portion reaching the conductive layer 242a is formed in the insulating layers 285, 283, 282, 280, and 275, and a conductive layer 243a and an insulating layer 241a are provided in the opening portion. The insulating layer 241a is provided in contact with the side surface of the opening portion, and the conductive layer 243a is located inward from the insulating layer 241a.

An opening portion reaching the conductive layer 242b is formed in the insulating layers 285, 283, 282, 280, and 275, and a conductive layer 243b and an insulating layer 241b are provided in the opening portion. The insulating layer 241b is provided in contact with the side surface of the opening portion, and the conductive layer 243b is located inward from the insulating layer 241b. The conductive layer 243a and the conductive layer 243b are provided with the conductive layer 260 therebetween. The top surfaces of the conductive layers 243a and 243b are level with the top surface of the insulating layer 285.

The insulating layers 241a and 241b can be formed using a barrier insulator usable for the insulating layer 275 or the like. For example, the insulating layers 241a and 241b can be formed using silicon nitride. In this case, impurities such as water and hydrogen contained in the insulating layer 280 or the like can be inhibited from entering the semiconductor layer 230 through the conductive layers 243a and 243b. Furthermore, oxygen contained in the insulating layer 280 can be prevented from being absorbed by the conductive layers 243a and 243b.

The conductive layers 243a and 243b may each have a stacked-layer structure. FIG. 4A illustrates an example in which the conductive layer 243a has a two-layer structure of a conductive layer 243a1, which is in contact with the conductive layer 242a and the side surface of the insulating layer 241a, and a conductive layer 243a2 over the conductive layer 243a1, and the conductive layer 243b has a two-layer structure of a conductive layer 243b1, which is in contact with the conductive layer 242b and the side surface of the insulating layer 241b, and a conductive layer 243b2 over the conductive layer 243b1. For example, the conductive layers 243a1 and 243b 1 can be formed using titanium or titanium nitride, and the conductive layers 243a2 and 243b2 can be formed using tungsten, copper, or aluminum.

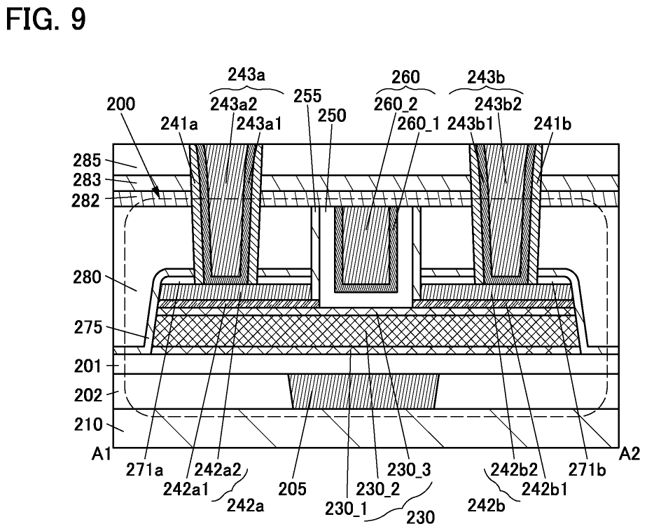

FIG. 9 illustrates a structure example in which the conductive layer 205 and the insulating layer 202 are provided in the structure illustrated in FIG. 6B.

### VARIATION EXAMPLES

Described below are structure examples partly different from the above-described structure examples. Note that components similar to those described above are not described below.

### Variation Example 1

In the above-described structure, the gate electrode is embedded in the insulating layer; a transistor described below has a structure different from the above.

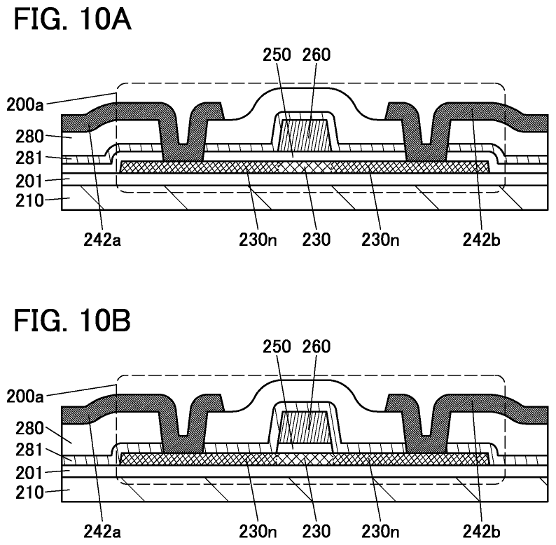

FIG. 10A is a cross-sectional view of a transistor 200a in the channel length direction. The transistor 200a includes the semiconductor layer 230, the insulating layer 250, the conductive layer 260, the conductive layer 242a, and the conductive layer 242b.

The insulating layer 250 is provided to cover the semiconductor layer 230, and the conductive layer 260 is provided in a position overlapping with the semiconductor layer 230 over the insulating layer 250. An insulating layer 281 and the insulating layer 280 are stacked to cover the insulating layer 250 and the conductive layer 260. A pair of opening portions reaching the semiconductor layer 230 are provided in the insulating layers 281, 280, and 250. The conductive layers 242a and 242b are provided over the insulating layer 280 and are in contact with the semiconductor layer 230 in the opening portions.

The insulating layer 281 can be formed using an insulator having a barrier property against hydrogen and oxygen like the insulating layer 275. This can inhibit diffusion of impurities contained in the insulating layer 280 into the semiconductor layer 230 and diffusion of oxygen contained in the semiconductor layer 230 to the insulating layer 280 side. Note that the insulating layer 281 can also have a stacked-layer structure of an insulating layer having a barrier property against hydrogen and an insulating layer having a barrier property against oxygen.

A region of the semiconductor layer 230 that overlaps with the conductive layer 260 functions as a channel formation region. A pair of regions 230n between which the channel formation region is interposed function as a source region and a drain region. The resistance of the region 230n is preferably lower than that of the channel formation region.

The region 230n preferably contains an element that imparts conductivity to the semiconductor layer 230, for example. Examples of the element include a typical non-metallic element other than hydrogen and oxygen, a typical metal element, and a transition element (transition metal). Specific examples include boron, phosphorus, magnesium, aluminum, and silicon. The above element can be introduced into part of the semiconductor layer 230 by a doping method, anion implantation method, a thermal diffusion method, or the like. For example, with the use of the conductive layer 260 as a mask, the above element can be introduced into a region of the semiconductor layer 230 that does not overlap with the conductive layer 260 with the insulating layer 250 therebetween by a doping method or an ion implantation method.

FIG. 10B illustrates an example in which the insulating layer 250 is positioned only in a region overlapping with the conductive layer 260 and is not provided over the region 230n of the semiconductor layer 230. In that case, when a film containing the above element is used as the insulating layer 281 in contact with the region 230n, the element can be introduced into the region 230n at the time of forming the insulating layer 281 or by heat treatment or the like performed later. For the insulating layer 281, silicon nitride containing hydrogen is preferably used, for example. Alternatively, an oxide containing the metal element among the above elements may be used.

### Variation Example 2

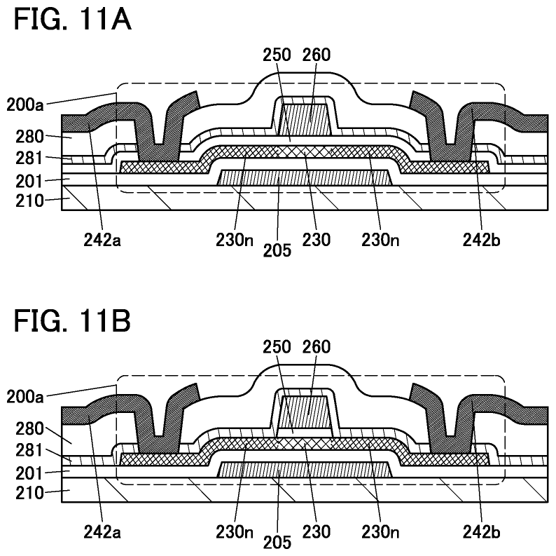

FIG. 11A illustrates an example in which the conductive layer 205 functioning as a second gate electrode is provided in the structure illustrated in FIG. 10A.

The conductive layer 205 is provided over the substrate 210, and the insulating layer 201 is provided to cover the conductive layer 205. The above description can be referred to for the structures, materials, and the like of the conductive layer 205 and the insulating layer 201.

FIG. 11B illustrates an example in which the insulating layer 250 is positioned only in a region overlapping with the conductive layer 260 and is not provided over the region 230n of the semiconductor layer 230.

### Variation Example 3

Described below is a transistor in which a conductive layer functioning as a gate electrode is positioned below a semiconductor layer.

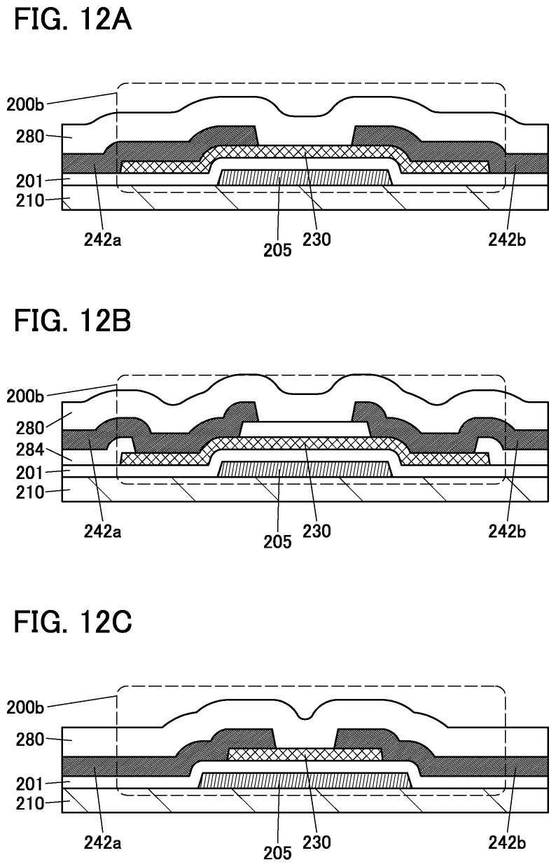

FIG. 12A is a cross-sectional view of a transistor 200b in the channel length direction. The transistor 200b includes the semiconductor layer 230, the insulating layer 201, the conductive layer 205, the conductive layer 242a, and the conductive layer 242b. The conductive layer 205 functions as a gate electrode of the transistor 200b. The insulating layer 201 functions as a gate insulating layer of the transistor 200b.

The above description can be referred to for the structures, materials, and the like of the substrate 210, the conductive layer 205, the insulating layer 201, and the semiconductor layer 230.

The conductive layers 242a and 242b each include a region in contact with the top surface of the semiconductor layer 230 and a region in contact with the side surface of the semiconductor layer 230. The insulating layer 280 is provided to cover the semiconductor layer 230, the conductive layer 242a, and the conductive layer 242b.

FIG. 12B illustrates an example in which an insulating layer 284 is provided in the structure illustrated in FIG. 12A.

The insulating layer 284 is provided to cover the semiconductor layer 230 and includes a first opening portion and a second opening portion that reach the semiconductor layer 230. The conductive layer 242a and the conductive layer 242b are in contact with the semiconductor layer 230 in the first opening portion and the second opening portion, respectively.

The insulating layer 284 functions as a channel protective film that protects a channel formation region at the time of forming the conductive layers 242a and 242b. The conductive layers 242a and 242b can be formed in the following manner: the insulating layer 284 is formed over the semiconductor layer 230, the first and second opening portions are formed in the insulating layer 284, a conductive film to be the conductive layers 242a and 242b is formed over the insulating layer 284, and the conductive film is processed. At the time of forming and processing the conductive film, the channel formation region is not exposed and thus can be inhibited from being damaged. Accordingly, the transistor having favorable electrical characteristics can be provided.

The insulating layer 284 can be formed using a material usable for the insulating layer 280.

FIG. 12C illustrates an example in which the side surface of the semiconductor layer 230 is located inward from the side surface of the conductive layer 205 in the structure illustrated in FIG. 12A. In this example, the conductive layer 205 includes a region not overlapping with the semiconductor layer 230. With such a structure, the area occupied by the transistor 200b can be reduced.

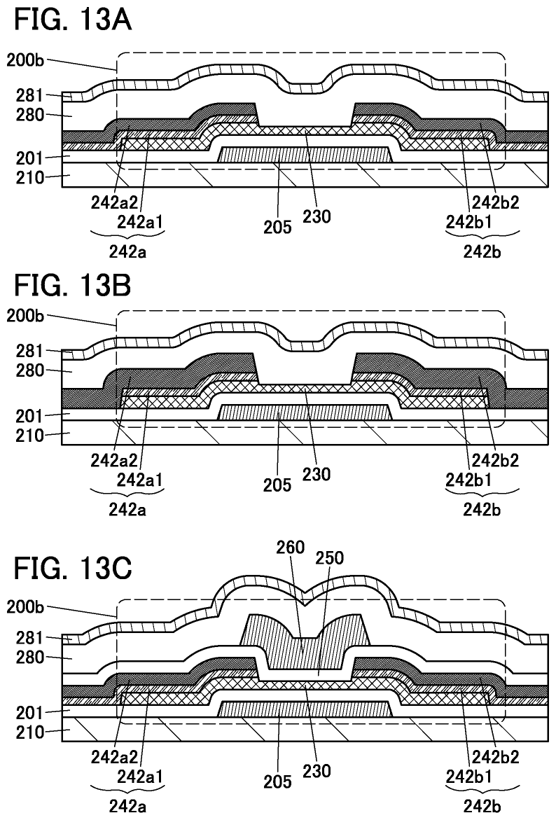

FIG. 13A illustrates an example in which the conductive layers 242a and 242b each have a two-layer structure in the structure illustrated in FIG. 12A. FIG. 13B illustrates an example in which a side end portion of the conductive layer 242a1 is aligned with one side end portion of the semiconductor layer 230, and a side end portion of the conductive layer 242b1 is aligned with another side end portion of the semiconductor layer 230 in the structure illustrated in FIG. 13A. With the structure illustrated in FIG. 13A or FIG. 13B, the contact resistance between the semiconductor layer and each of source and drain electrodes can be reduced while the source and drain electrodes maintain the conductivity necessary for wirings.

In the structure illustrated in FIG. 13A, the conductive layers 242a1 and 242b1 are partly in contact with the top surface and the side surface of the semiconductor layer 230. Accordingly, the contact area between the semiconductor layer 230 and each of the conductive layers 242a1 and 242b1 can be increased.

The above description can be referred to for the structures, materials, and the like of the conductive layers 242a1, 242a2, 242b1, and 242b2. For example, the conductive layers 242a1 and 242b1 can be formed using a metal oxide such as ITO or ITSO, and the conductive layers 242a2 and 242b2 can be formed using tungsten, copper, nickel, or the like.

In the structures illustrated in FIGS. 13A and 13B, the insulating layer 281 is provided over the insulating layer 280. The insulating layer 281 can be formed using an insulator having a barrier property against hydrogen and oxygen like the insulating layer 275. This can inhibit diffusion of impurities such as water and hydrogen from above the transistor 200b into the semiconductor layer 230.

In the structures illustrated in FIGS. 13A and 13B, a conductive layer to be the conductive layers 242a1 and 242b1 is formed and a region of the conductive layer that overlaps with the semiconductor layer 230 is partly removed by etching, whereby the conductive layers 242a1 and 242b1 are formed. Note that in the case where the conductive layer has low etching selectivity with respect to the semiconductor layer 230, an exposed region of the semiconductor layer 230 is partly etched while the conductive layer is etched, so that a groove portion is formed in the semiconductor layer 230.

FIG. 13C illustrates an example in which the conductive layer 260 functioning as a second gate electrode and the insulating layer 250 functioning as a second gate insulating layer are provided in the structure illustrated in FIG. 13A.

The insulating layer 250 is provided over the semiconductor layer 230, the conductive layer 242a, and the conductive layer 242b. The conductive layer 260 is provided over the insulating layer 250 to include a region overlapping with the semiconductor layer 230. The insulating layer 280 is provided to cover the conductive layer 260. The above description can be referred to for the structures, materials, and the like of the conductive layer 260 and the insulating layer 250.

With the use of the conductive layer 260 as a second gate electrode, the on-state current can be increased or the threshold voltage can be controlled. For example, when the conductive layers 205 and 260 are made to have the same potential and the transistor is driven as a double-gate transistor, the on-state current can be increased. When a potential different from that for the conductive layer 205 is supplied to the conductive layer 260, the threshold voltage can be controlled. Thus, by controlling the threshold voltage, the transistor can easily have normally-off characteristics.

### Variation Example 4

Described below is a vertical transistor in which a source electrode and a drain electrode are positioned at different levels.

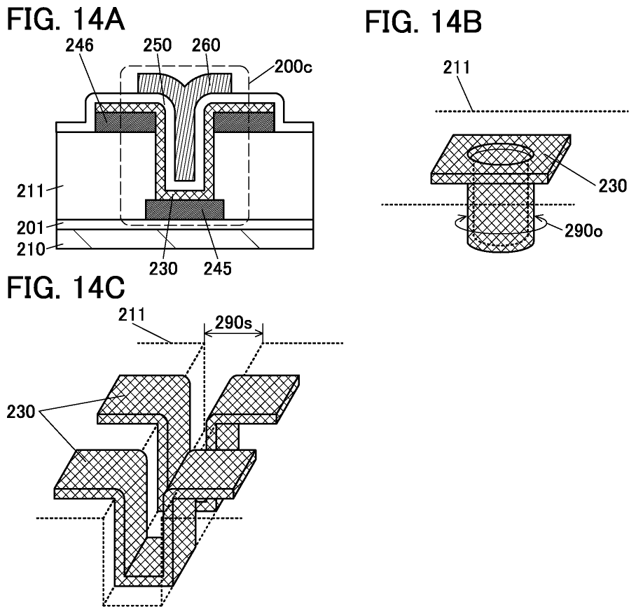

FIG. 14A is a schematic cross-sectional view of a transistor 200c. The transistor 200c includes the semiconductor layer 230, the insulating layer 250, the conductive layer 260, a conductive layer 245, and a conductive layer 246. The conductive layer 245 functions as one of a source electrode and a drain electrode of the transistor 200c, and the conductive layer 246 functions as the other.

The conductive layer 245 is provided over the insulating layer 201, and an insulating layer 211 is provided to cover the conductive layer 245. The conductive layer 246 is provided over the insulating layer 211. An opening portion reaching the conductive layer 245 is provided in the conductive layer 246 and the insulating layer 211. The semiconductor layer 230 is provided in contact with the side surface of the conductive layer 246, the side surface of the insulating layer 211, and the top surface of the conductive layer 245 in the opening portion and the top surface of the conductive layer 246. The insulating layer 250 is provided to cover the semiconductor layer 230 in the opening portion, and the conductive layer 260 is provided to cover the insulating layer 250.

In the transistor 200c, the source electrode and the drain electrode are positioned at different levels, so that current flows in the semiconductor layer in the height direction. In other words, the channel length direction can be regarded as including a height (vertical) component; therefore, the transistor 200c can be referred to as a vertical field effect transistor (VFET), a vertical transistor, a vertical-channel transistor, a vertical-channel-type transistor, or the like. Since two or more of the source electrode, the semiconductor layer, and the drain electrode can overlap with each other in the transistor 200c, the area occupied by the transistor 200c can be significantly smaller than that occupied by what is called a planar transistor (also referred to as a lateral transistor, a lateral FET (LFET), or the like) in which a semiconductor layer is positioned over a flat plane.

The channel length of the transistor 200c can be precisely adjusted by the thickness of the insulating layer 211 functioning as a spacer; thus, a variation in the channel length can be extremely smaller than that of a planar transistor. Furthermore, by reducing the thickness of the insulating layer 211, a transistor with an extremely short channel length can be manufactured. For example, it is possible to manufacture a transistor with a channel length of 2 μm or shorter, 1 μm or shorter, 500 nm or shorter, 300 nm or shorter, 200 nm or shorter, 100 nm or shorter, 50 nm or shorter, 30 nm or shorter, or 20 nm or shorter, and 5 nm or longer, 7 nm or longer, or 10 nm or longer. Thus, it is possible to provide a transistor with an extremely short channel length that could not be achieved with a light-exposure apparatus for mass production. Moreover, a transistor with a channel length shorter than 10 nm can also be provided without using an extremely expensive light-exposure apparatus used in the latest LSI technology.

In the transistor 200c, the opening portion provided in the insulating layer 211 can have a variety of shapes.

FIG. 14B is a perspective view selectively illustrating the insulating layer 211 and the semiconductor layer 230, and shows an example where the insulating layer 211 has a cylindrical opening portion 290o. In this case, the semiconductor layer 230 includes a cylindrical portion along the side surface of the opening portion 290o and flat portions parallel to the substrate surface in its bottom and upper portions. In the structure illustrated in FIG. 14B, the channel width of the transistor is substantially equal to the circumference of the cylindrical portion. Thus, with the structure illustrated in FIG. 14B, a short channel length and a large channel width are easily obtained, so that the transistor in which an extremely large amount of current can flow can be provided.

Meanwhile, FIG. 14C illustrates an example in which the insulating layer 211 has a slit-like opening portion 290s. As illustrated in FIG. 14C, a plurality of the semiconductor layers 230 can be arranged in the opening portion 290s, which is suitable for the case of arranging the transistors at high density. Although not illustrated here, the conductive layer 260 functioning as a gate electrode can be provided to be embedded in the opening portion 290s and used as a wiring provided along the direction where the opening portion 290s extends.

Note that in the structure illustrated in FIGS. 14A and 14B, a sidewall-shaped insulating layer can be provided between the side surface of the opening portion 290o and the semiconductor layer 230, and a conductive layer can be provided in contact with the side surface of the insulating layer that is opposite to the semiconductor layer 230.

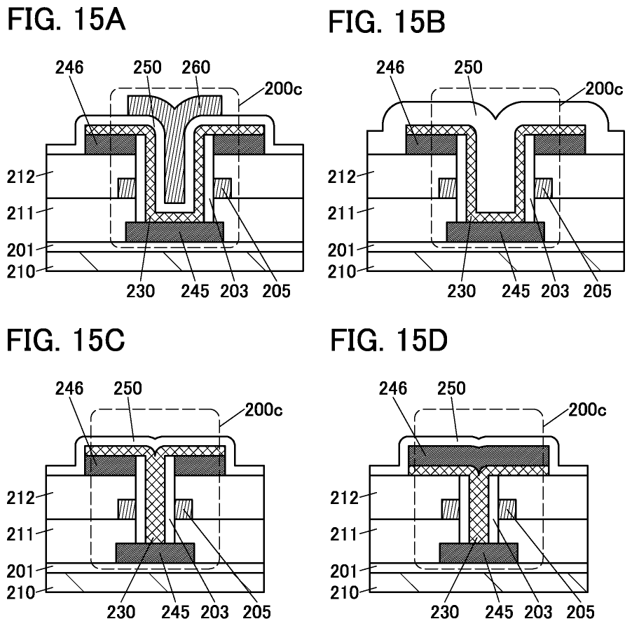

FIG. 15A illustrates the transistor 200c having the above structure. The transistor 200c illustrated in FIG. 15A is different from the transistor illustrated in FIG. 14A mainly in including an insulating layer 203 and the conductive layer 205. The insulating layer 203 is the above sidewall-shaped insulating layer, and the conductive layer 205 is the above conductive layer.

The conductive layer 205 is provided over the insulating layer 211, and an insulating layer 212 is provided to cover the conductive layer 205. The conductive layer 246 is provided over the insulating layer 212. An opening portion reaching the conductive layer 245 is provided in the conductive layer 246, the insulating layer 212, the conductive layer 205, and the insulating layer 211. The insulating layer 203 is provided in contact with the side surfaces of the conductive layer 246, the insulating layer 212, the conductive layer 205, and the insulating layer 211 and part of the top surface of the conductive layer 245 in the opening portion. The semiconductor layer 230 is provided to cover the insulating layer 203 in the opening portion. The semiconductor layer 230 is also in contact with another part of the top surface of the conductive layer 245 in the opening portion and the top surface of the conductive layer 246. The insulating layer 250 is provided to cover the semiconductor layer 230 in the opening portion, and the conductive layer 260 is provided to cover the insulating layer 250.

In the transistor 200c illustrated in FIG. 15A, the conductive layer 260, the insulating layer 250, the conductive layer 205, and the insulating layer 203 function as a first gate electrode, a first gate insulating layer, a second gate electrode, and a second gate insulating layer, respectively.

The semiconductor layer 230 includes a region overlapping with the conductive layer 205 with the insulating layer 203 therebetween and overlapping with the conductive layer 260 with the insulating layer 250 therebetween. At least part of the region functions as a channel formation region of the transistor 200c.

When a potential different from that for the conductive layer 260 is supplied to the conductive layer 205, the threshold voltage of the transistor 200c can be controlled. Thus, by controlling the threshold voltage, the transistor can easily have normally-off characteristics.

In the transistor 200c, either the conductive layer 260 or the conductive layer 205 may be used as a gate electrode or a back gate electrode. In the transistor 200c, it is particularly suitable to use the conductive layer 260 as the gate electrode and to use the conductive layer 205 as the back gate electrode in some cases. When the conductive layer 260 whose region facing the semiconductor layer 230 is larger than that of the conductive layer 205 is used as the gate electrode, a gate electric field is applied to the semiconductor layer 230 more efficiently; thus, the electrical characteristics of the transistor can be improved in some cases.

It is also possible to apply the same potential to the conductive layers 260 and 205. In this case, the on-state current can be increased, a variation in initial characteristics can be reduced, degradation of electrical characteristics in a negative gate bias-temperature (−GBT) stress test can be reduced, and drain-induced barrier lowering (DIBL) can be inhibited.

The conductive layer 205 can be formed using a conductive material usable for the conductive layer 260. The insulating layer 203 can be formed using an insulating material usable for the insulating layer 250. The insulating layer 212 can be formed using an insulating material usable for the insulating layer 211.

Note that in the structure illustrated in FIG. 15A, the conductive layer 260 is not necessarily provided. The transistor 200c illustrated in FIG. 15B is different from the transistor illustrated in FIG. 15A mainly in not including the conductive layer 260. In the transistor 200c illustrated in FIG. 15B, the conductive layer 205 functions as a gate electrode, and the insulating layer 203 functions as a gate insulating layer. Since the conductive layer 260 is not provided in the opening portion, the width of the opening portion can be reduced without changing the thicknesses of the semiconductor layer 230 and the insulating layer 250; thus, the transistor can be miniaturized or highly integrated. Alternatively, when the thickness of the insulating layer 250 is increased, the function of the insulating layer 250 can be improved, so that the transistor can have high field-effect mobility and high reliability. Alternatively, when the thickness of the semiconductor layer 230 is increased, the transistor can have a high on-state current and high field-effect mobility.

Furthermore, it is also possible to employ a structure where only the insulating layer 203 and the semiconductor layer 230 are provided in the opening portion, that is, a structure where the semiconductor layer 230 is embedded in the opening portion. FIG. 15C illustrates the transistor 200c having this structure. With the structure illustrated in FIG. 15C, it is not necessary to provide at least the conductive layer 260 in the opening portion, so that the width of the opening portion can be small. Thus, the transistor can be miniaturized or highly integrated.

In the structure illustrated in FIG. 15C, the conductive layer 246 may be provided between the semiconductor layer 230 and the insulating layer 250. FIG. 15D illustrates the transistor 200c having this structure. With the structure illustrated in FIG. 15D, the opening portion does not need to be formed in the conductive layer 246. Thus, the opening portion can be easily formed and the productivity of the semiconductor device can be increased.

Alternatively, the structure illustrated in FIG. 15D can be a structure where the semiconductor layer 230 is not positioned over the insulating layer 212, that is, a structure where the semiconductor layer 230 is positioned only in the opening portion. For example, after the formation of the semiconductor layer 230, CMP treatment is performed until the top surface of the insulating layer 212 is exposed, whereby the semiconductor layer 230 can be embedded in the opening portion. This can inhibit disconnection of the conductive layer 246 formed over the insulating layer 212 and the semiconductor layer 230.

### Variation Example 5

Described below is an example of a transistor in which a gate electrode surrounds a semiconductor layer.

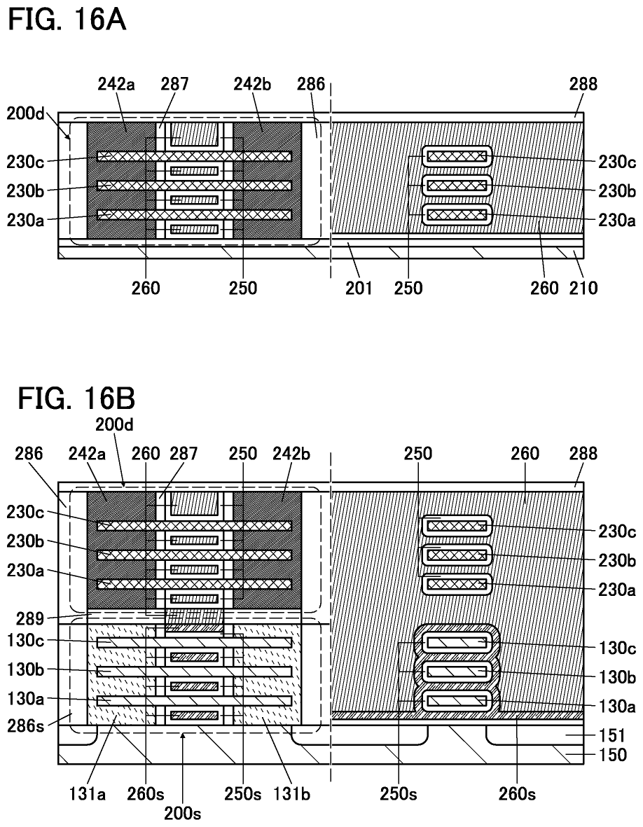

FIG. 16A is a schematic cross-sectional view of a semiconductor device including a transistor 200d. In FIG. 16A, a cross section in the channel length direction is on the left side of a dashed-dotted line, and a cross section in the channel width direction is on the right side of the dashed-dotted line. In the transistor 200d illustrated in FIG. 16A, a gate electrode is provided to surround semiconductor layers; thus, the transistor 200d can be regarded as a transistor having a gate all around (GAA) structure.

The transistor 200d includes a plurality of semiconductor layers overlapping with each other. In an example illustrated here, the transistor 200d includes a semiconductor layer 230a, a semiconductor layer 230b, and a semiconductor layer 230c from the bottom. The transistor 200d includes the conductive layer 242a, the conductive layer 242b, the conductive layer 260, and the insulating layer 250. The insulating layer 201 is provided between the substrate 210 and the transistor 200d, an insulating layer 286 is provided to surround the transistor 200d, and an insulating layer 288 is provided to cover the transistor 200d.

The conductive layer 260 functioning as a gate electrode includes a portion positioned below the semiconductor layer 230a, a portion positioned between the semiconductor layers 230a and 230b, a portion positioned between the semiconductor layers 230b and 230c, and a portion positioned above the semiconductor layer 230c. The insulating layer 250 functioning as a gate insulating layer includes portions positioned between the above-described portions of the conductive layer 260 and the corresponding semiconductor layers. When the gate electrode is provided to surround the semiconductor layers in this manner, a gate electric field is applied to surround the semiconductor layers, which can improve the controllability of the on and off states of the transistor 200d. Specifically, an effect of increasing the amount of source-drain current in the on state (on-state current) and reducing the amount of leakage current in the off state (off-state current) can be obtained.

In the channel length direction, the conductive layers 242a and 242b are provided so that the conductive layer 260 is interposed therebetween. The conductive layers 242a and 242b are in contact with the semiconductor layers.

An insulating layer 287 functioning as a spacer is provided between the insulating layer 250 and each of the conductive layers 242a and 242b. The insulating layer 287 can reduce the parasitic capacitance between the conductive layer 260 and each of the conductive layers 242a and 242b. Note that the insulating layer 287 may be omitted if not needed.

The insulating layers 286 and 288 function as interlayer insulating layers. As the insulating layer 288, an insulating film functioning as a protective insulating layer is preferably used.

Although the three semiconductor layers are stacked in the example described here, the number of semiconductor layers included in the transistor 200d is not limited thereto, and can be one, two, or four or more. As the number of semiconductor layers is smaller, the manufacturing process can be shortened, which leads to not only higher yield but also lower manufacturing cost. As the number of semiconductor layers is larger, the on-state current can be increased.

FIG. 16B illustrates an example in which two transistors each having a GAA structure are stacked. In FIG. 16B, a transistor 200s is provided below the transistor 200d.

The transistor 200s is provided over a substrate 150 and includes a plurality of semiconductor layers (a semiconductor layer 130a, a semiconductor layer 130b, and a semiconductor layer 130c), a conductive layer 131a, a conductive layer 131b, a conductive layer 260s, and an insulating layer 250s. The conductive layer 131a functions as one of a source electrode and a drain electrode, and the conductive layer 131b functions as the other. The conductive layer 260s functions as a gate electrode, and the insulating layer 250s functions as a gate insulating layer.

The transistor 200s is preferably a p-channel transistor. A combination of the p-channel transistor 200s and the n-channel transistor 200d makes it possible to form a complementary metal oxide semiconductor (CMOS) circuit. By stacking the transistors 200s and 200d in this manner, a complementary field-effect transistor (CFET) can be formed.

Typically, silicon can be used for the semiconductor layers 130a, 130b, and 130c. The semiconductor layers 130a, 130b, and 130c each preferably have a single crystal structure epitaxially grown from the substrate 150. For example, single crystal silicon germanium films and single crystal silicon films are alternately formed over the substrate 150 containing single crystal silicon, and the silicon germanium films are selectively removed, whereby the semiconductor layers 130a, 130b, and 130c can be formed.

An insulating layer 151 is embedded in the substrate 150 and functions as an element isolation layer. An insulating layer 286s functioning as an interlayer insulating layer is provided to surround the transistor 200s.

An insulating layer 289 for insulating two conductive layers is provided between the conductive layers 242a and 131a and between the conductive layers 242b and 131b.

The conductive layer 260s is provided to surround channel formation regions in the semiconductor layers 130a, 130b, and 130c with the insulating layer 250s therebetween. The conductive layer 260 functioning as the gate electrode of the transistor 200d is provided in contact with the conductive layer 260s. With such a structure, the gate electrode and the gate insulating layer can be formed separately for the transistor 200d and the transistor 200s. For example, the conductive layer 260s can be formed using a conductive material with a work function different from that of a conductive material usable for the conductive layer 260. In addition, not only a material but also a thickness can differ between the insulating layer 250s and the insulating layer 250.

With such a structure, the transistors 200d and 200s each having a high on-state current and a low off-state current can be stacked, so that a highly-integrated low-power semiconductor device capable of high-speed operation can be provided.

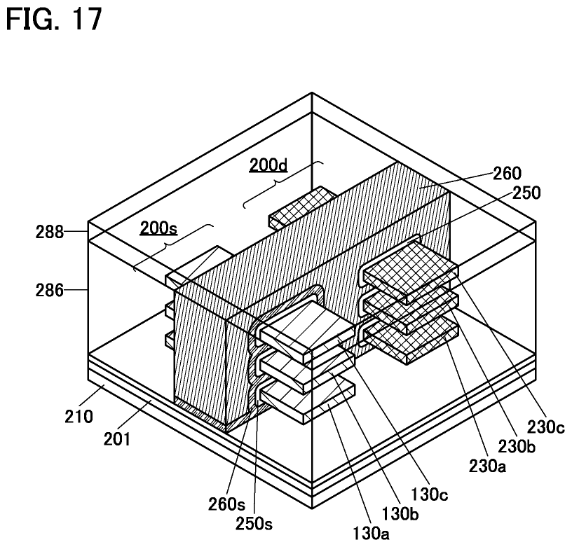

FIG. 17 illustrates an example in which two transistors each having a GAA structure are arranged side by side. FIG. 17 is a schematic perspective view of a semiconductor device. In FIG. 17, the transistors 200d and 200s are arranged side by side. In FIG. 17, the insulating layers 286 and 288 are only indicated as the outlines by solid lines. For simplicity, FIG. 17 does not illustrate the conductive layer 131a, the conductive layer 131b, the conductive layer 242a, the conductive layer 242b, the insulating layer 287, or the like; FIGS. 16A and 16B can be referred to for these components.

The semiconductor layers 130a, 130b, and 130c are stacked, and in a region not overlapping with them, the semiconductor layers 230a, 230b, and 230c are stacked. The conductive layer 260s is provided to surround the channel formation regions in the semiconductor layers 130a, 130b, and 130c with the insulating layer 250s therebetween. The conductive layer 260 functioning as the gate electrode of the transistor 200d is provided in contact with the conductive layer 260s. With such a structure, the gate electrode can be formed separately for the transistors 200s and 200d. Moreover, since a gate wiring can be shared between the two transistors, this structure enables higher integration than a structure where gate wirings are provided separately.

As compared with the structure illustrated in FIG. 16B, the structure illustrated in FIG. 17 occupies a large area but has high layout flexibility of the n-channel transistor 200d and the p-channel transistor 200s. Thus, this structure is preferable because it is such a versatile structure that not only a CMOS circuit but also a variety of circuit structures can be formed, and this structure can be easily employed for a conventional LSI.

The semiconductor layers 130a to 130c can also be formed using a metal oxide such as cuprous oxide (Cu₂O), copper aluminate (CuAlO₂), copper gallium oxide (CuGaO₂), stannous oxide (SnO), or tellurium oxide. Note that the semiconductor layers 130a to 130c can also be formed using a mixture of tellurium oxide and tellurium, for example.

When the semiconductor layers 130a to 130c are formed using a p-type metal oxide semiconductor and the semiconductor layers 230a to 230c are formed using an n-type metal oxide semiconductor, the semiconductor device can be manufactured at a relatively low process temperature. In addition, since each semiconductor layer is formed using a metal oxide, a material used for at least one of the source electrode, the drain electrode, the gate insulating layer, and the gate electrode can be common between the transistors 200s and 200d. The components of the transistors 200s and 200d that use a common material can be formed using the same apparatus, so that the manufacturing cost of the semiconductor device can be reduced.

The semiconductor layers 130a to 130c can also be formed using transition metal dichalcogenide such as WS₂, WSe₂, MoS₂, or MoSe₂.

In the case where the semiconductor layers 130a to 130c are formed using a metal oxide or transition metal dichalcogenide, a substrate other than a single crystal silicon substrate (the above-described insulator substrate, conductor substrate, or the like) can also be used as the substrate 150. Moreover, a structure can also be employed where an insulating layer is provided between the substrate 150 and the semiconductor layer and an element isolation layer is not provided.

### Variation Example 6

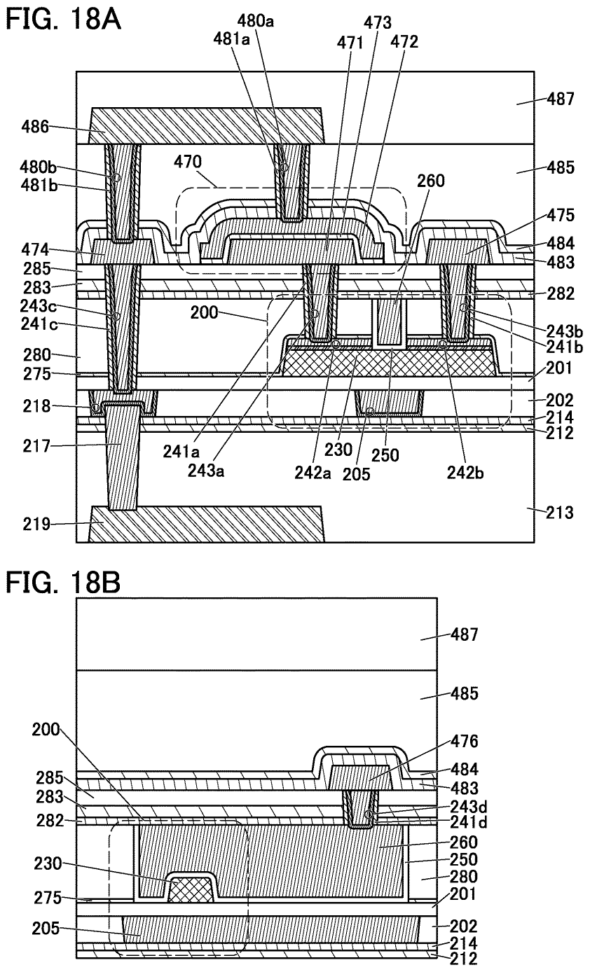

FIGS. 18A and 18B illustrate a semiconductor device in which wirings and a capacitor are formed in layers above and below the semiconductor device illustrated in FIG. 7A.

A variation example of the semiconductor device described in [Structure example of semiconductor device] will be described with reference to FIGS. 18A and 18B. FIGS. 18A and 18B are cross-sectional views of the semiconductor device including the transistor 200 and portions corresponding to the semiconductor device illustrated in FIG. 7A and the like. FIG. 18A corresponds to a cross section of the transistor 200 in the channel length direction. FIG. 18B corresponds to a cross section of the transistor 200 in the channel width direction.

The transistor 200 and the components in its vicinity illustrated in FIGS. 18A and 18B correspond to the transistor 200 illustrated in FIG. 7A. Differences from the above description of [Structure example of semiconductor device] are mainly described below, and the description of [Structure example of semiconductor device] is referred to for the same portions, and the description of the same portion is omitted in some cases.

As illustrated in FIG. 18A, a conductive layer 218 functioning as a wiring can be provided in the same layer as the conductive layer 205. An opening portion reaching the conductive layer 218 is formed in the insulating layers 285, 283, 282, 280, 275, and 201, an insulating layer 241c is provided in contact with the side surface of the opening portion, and a conductive layer 243c is located inward from the insulating layer 241c. The conductive layer 218 can be formed through the same process as the conductive layer 205, and is formed using a material similar to that for the conductive layer 205. The conductive layer 243c can be formed through the same process as the conductive layers 243a and 243b, and is formed using a material similar to those for the conductive layers 243a and 243b. The insulating layer 241c can be formed through the same process as the insulating layers 241a and 241b, and is formed using a material similar to those for the insulating layers 241a and 241b.

An insulating layer 214 is provided under the conductive layer 218, the conductive layer 205, and the insulating layer 202, and the insulating layer 212 is provided under the insulating layer 214. An insulator having a barrier property against hydrogen is preferably used for the insulating layer 212, and an insulator having a function of capturing or fixing hydrogen is preferably used for the insulating layer 214. Such a structure can inhibit diffusion of hydrogen from below the transistor 200. Hydrogen contained in the insulating layer 202 or the like can be captured or fixed by the insulating layer 214. This can reduce the hydrogen concentration in the semiconductor layer 230 and its vicinity.

An insulating layer 213 functioning as an interlayer film is provided under the insulating layer 212. The insulating layer 213 is formed to cover a conductive layer 219 functioning as a wiring. The insulating layer 213 can be formed using a material similar to that for the insulating layer 280. A conductive layer 217 is formed in an opening portion provided in the insulating layers 214, 212, and 213. The opening portion reaches the top surface of the conductive layer 219, and the conductive layer 217 is in contact with the top surface of the conductive layer 219. Thus, the conductive layer 219 and the conductive layer 218 are electrically connected to each other through the conductive layer 217 functioning as a via. The conductive layer 217 can be formed using a material similar to that for the conductive layers 243a to 243c. Note that the conductive layer 219 can also be connected to a wiring, a circuit element, or the like provided below the conductive layer 219.

As described above, the transistor 200 is provided in a region interposed between the insulating layers 212 and 283 having a barrier property against hydrogen, which prevents diffusion of hydrogen from a layer above or below the transistor 200. Note that as illustrated in FIG. 18A, the conductive layer 217 penetrates the insulating layer 212; thus, impurities such as hydrogen might be diffused into a region above the insulating layer 212 through the conductive layer 217. For example, since the conductive layer 219 connected to the conductive layer 217 is in contact with the insulating layer 213, hydrogen contained in the insulating layer 213 might be diffused through the conductive layers 219 and 217. Since the conductive layer 219 is also connected to a circuit element therebelow, hydrogen contained in the circuit element and an interlayer film in the vicinity thereof might be diffused through the conductive layer 219.

In view of the above, a conductive film having a barrier property against hydrogen is used as the conductive layer 218 and covers an upper portion of the conductive layer 217, whereby diffusion of hydrogen through the conductive layers 219 and 217 can be prevented. Even when part of the hydrogen is diffused from the conductive layer 218 into the insulating layer 202, the use of an insulator having a barrier property against hydrogen for the insulating layer 201 can prevent diffusion of the hydrogen into the semiconductor layer 230. Furthermore, even when another part of the hydrogen is diffused from the conductive layer 218 into the conductive layer 243c, the conductive film having a barrier property against hydrogen, which is used as the conductive layer 243c, and the insulating layer 241c can prevent diffusion of the hydrogen into the insulating layer 280. Such a structure can prevent formation of excess V_{O}H in the channel formation region in the semiconductor layer 230, whereby the transistor can be prevented from having normally-on characteristics. Accordingly, a semiconductor device having favorable electrical characteristics can be provided.

As illustrated in FIGS. 18A and 18B, a capacitor 470 and conductive layers 474, 475, and 476 functioning as wirings are provided over the insulating layer 285. An insulating layer 483 is provided to cover the capacitor 470 and the conductive layers 474, 475, and 476, an insulating layer 484 is provided to cover the insulating layer 483, and an insulating layer 485 is provided to cover the insulating layer 484.

The insulating layer 485 functions as an interlayer film and can be formed using a material similar to that for the insulating layer 280.

The capacitor 470 includes a conductive layer 471, an insulating layer 473 covering the conductive layer 471, and a conductive layer 472 over the insulating layer 473. In the capacitor 470, the conductive layer 471 functions as one electrode, the conductive layer 472 functions as the other electrode, and the insulating layer 473 functions as a dielectric. That is, the capacitor 470 is a metal-insulator-metal (MIM) capacitor.

The conductive layers 471 and 472 can be formed using a conductive material usable for the conductive layer 260. For example, the conductive layers 471 and 472 can be formed using tungsten. Here, when the conductive layer 472 covers the conductive layer 471, the side surface of the conductive layer 471 can function as the capacitor 470. This can increase the capacitance of the capacitor 470. In addition, the conductive layer 471 can be formed concurrently with the conductive layers 474, 475, and 476.

Although the conductive layers 471, 474, 475, 476, and 472 each have a single-layer structure in FIGS. 18A and 18B, the structure is not limited thereto and a stacked-layer structure of two or more layers may be employed. For example, a stacked-layer structure of a conductive film having a barrier property against hydrogen and a conductive film having high conductivity may be employed. For example, a stacked-layer structure of a titanium nitride film and a tungsten film over the titanium nitride film can be employed.

The insulating layer 473 is preferably formed using a high-k material. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium. Using such a high-k material allows the insulating layer 473 to be thick enough to inhibit leakage current and the capacitor 470 to have an adequately high capacitance. The insulating layer 473 is formed to cover the conductive layer 471 and thus is preferably formed by a film formation method that offers excellent coverage, such as an ALD method or a CVD method.

The insulating layer 473 may have a stacked-layer structure. It is preferable to employ a stacked-layer structure of a high-k material and a material having higher dielectric strength than the high-k material. Examples of the material having high dielectric strength (a material having a low dielectric constant) include silicon oxide, silicon oxynitride, silicon nitride oxide, silicon nitride, silicon oxide containing fluorine, silicon oxide containing carbon, and silicon oxide containing carbon and nitrogen. The insulating layer 473 can have, for example, a stacked-layer structure of a first layer containing aluminum oxide, which is a high-k material, and a second layer containing silicon oxide having high dielectric strength over the first layer.

As the insulating layer 473, for example, an insulating film in which zirconium oxide, aluminum oxide, and zirconium oxide are stacked in this order can be used. For another example, an insulating film in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. The stacking of such an insulating film having relatively high dielectric strength, such as aluminum oxide, can increase the dielectric strength and inhibit electrostatic breakdown of the capacitor 470.

The insulating layer 473 can also be formed using the above-described material that can have ferroelectricity.

Although the capacitor 470 of the semiconductor device illustrated in FIG. 18A is a planar capacitor, the semiconductor device described in this embodiment is not limited thereto. For example, the capacitor 470 may be a cylindrical capacitor.

An insulator having a function of capturing or fixing hydrogen is preferably used for the insulating layer 483. The insulating layer 483 can be formed using aluminum oxide, for example. The insulating layer 484 is preferably formed using an insulator having a barrier property against hydrogen. For example, the insulating layer 484 can be formed using silicon nitride having a higher hydrogen barrier property.

Furthermore, the insulating layer 483 preferably has a stacked-layer structure. For example, the insulating layer 483 can include an aluminum oxide film formed by a thermal ALD method as a first layer and an aluminum oxide film formed by a sputtering method as a second layer over the first layer. When the second layer of the insulating layer 483 is formed by a sputtering method after the first layer of the insulating layer 483 is formed, the capacitor 470 and the like can be protected from an impact of ion collision due to the film formation by sputtering. By forming the first layer of the insulating layer 483 by an ALD method that offers good step coverage, formation of a pinhole, disconnection, or the like at a step on the capacitor 470 or the like can be prevented.

Furthermore, the insulating layer 484 preferably has a stacked-layer structure. For example, the insulating layer 484 can have a stacked-layer structure of a first silicon nitride film formed by a sputtering method and a second silicon nitride film formed by a PEALD method over the first silicon nitride film. Even when a pinhole, disconnection, or the like is formed in the first silicon nitride film of the insulating layer 484 in the vicinity of a step on the capacitor 470 or the like, the second silicon nitride film formed by an ALD method that offers good step coverage covers the pinhole, the disconnection, or the like, whereby a barrier property against hydrogen can be maintained.

When the insulating layer 484 is provided over the capacitor 470 in this manner, diffusion of hydrogen from a layer above the capacitor 470 can be inhibited. When the insulating layer 483 is provided under the insulating layer 484, hydrogen contained in the capacitor 470, the insulating layer 285, and the like can be captured or fixed by the insulating layer 483.

The conductive layer 471, the conductive layer 475, the conductive layer 474, and the conductive layer 476 are formed in contact with the top surface of the conductive layer 243a, the top surface of the conductive layer 243b, the top surface of the conductive layer 243c, and the top surface of a conductive layer 243d, respectively. That is, the conductive layer 471, the conductive layer 475, the conductive layer 474, and the conductive layer 476 are electrically connected to the conductive layer 242a, the conductive layer 242b, the conductive layer 218, and the conductive layer 260, respectively. Note that the conductive layer 243d is formed in an opening portion provided in the insulating layers 285, 283, and 282. The opening portion reaches the top surface of the conductive layer 260, and the conductive layer 243d is in contact with the top surface of the conductive layer 260. An insulating layer 241d is formed to cover the side surface of the opening portion. The conductive layer 243d can be formed through the same process as the conductive layers 243a to 243c, and is formed using a material similar to those for the conductive layers 243a to 243c. The insulating layer 241d can be formed through the same process as the insulating layers 241a to 241c, and is formed using a material similar to those for the insulating layers 241a to 241c.

An insulating layer 487 functioning as an interlayer film is provided over the insulating layer 485. The insulating layer 487 is provided to cover a conductive layer 486 functioning as a wiring. The insulating layer 487 can be formed using a material similar to that for the insulating layer 280. The conductive layer 486 is provided in contact with the top surfaces of conductive layers 480a and 480b. The conductive layers 480a and 480b are provided in opening portions formed in the insulating layers 485, 484, and 483. The opening portion where the conductive layer 480a is provided reaches the top surface of the conductive layer 472, and the conductive layer 480a is in contact with the top surface of the conductive layer 472. An insulating layer 481a is provided to cover the side surface of the opening portion where the conductive layer 480a is provided. The opening portion where the conductive layer 480b is provided reaches the top surface of the conductive layer 474, and the conductive layer 480b is in contact with the top surface of the conductive layer 474. An insulating layer 481b is provided to cover the side surface of the opening portion where the conductive layer 480b is provided. The conductive layers 480a and 480b can be formed by the same method as the conductive layers 243a to 243d, and can be formed using a material similar to those for the conductive layers 243a to 243d. The insulating layers 481a and 481b can be formed by the same method as the insulating layers 241a to 241d, and can be formed using a material similar to those for the insulating layers 241a to 241d. Since the conductive layers 480a and 480b are positioned above the insulating layer 283, the insulating layers 481a and 481b can be omitted as long as impurities such as hydrogen diffused into the layers of the conductive layers 243a to 243d can be sufficiently reduced.

Although the conductive layer 486 has a single-layer structure in FIG. 18A, the structure is not limited thereto, and a stacked-layer structure of two or more layers may be employed. For example, a structure where a metal material having high conductivity is interposed between metal materials having high heat resistance can be employed. As the metal material having high conductivity, aluminum, copper, or the like can be used. As the metal material having high heat resistance, a metal material such as molybdenum, titanium, or tungsten, a nitride of the metal material, or the like can be used.

Note that the connection structure of the wirings and the circuit elements of the semiconductor device described in this embodiment is not limited to that illustrated in FIG. 18A or the like. For example, the conductive layers 219, 218, 474, and 486 functioning as wirings in the respective layers are all connected to each other through the conductive layers 217, 243c, and 480b functioning as vias in FIG. 18A; however, the present invention is not limited thereto, and wirings and vias can be selected from the above wirings and vias to form a given circuit. For example, although the conductive layer 219 is connected to the conductive layer 472 functioning as an upper electrode of the capacitor 470 through the conductive layer 486 or the like in FIG. 18A, the present invention is not limited thereto. For example, it is also possible to employ a structure where the conductive layer 486 is divided so that one part of the conductive layer 486 is provided in contact with the conductive layer 480b and the other part of the conductive layer 486 is provided in contact with the conductive layer 480a, so that the conductive layer 219 and the conductive layer 472 are not electrically connected to each other. Although one wiring layer is provided under the transistor 200 and another one is provided over the capacitor 470 in FIG. 18A, the present invention is not limited thereto, and two or more wiring layers can be provided under the transistor 200 and over the capacitor 470. Although the conductive layer 471 functioning as one electrode of the capacitor 470 and the conductive layers 474 and 475 functioning as wirings are provided in the same layer in FIG. 18A, the present invention is not limited thereto. For example, the conductive layer 471 can be formed in a layer above the conductive layers 474 and 475, and the capacitor 470 can be formed above a wiring layer including the conductive layers 474 and 475. As described above, the transistors, the circuit elements, and the wirings in the respective layers can be connected to each other through the vias to form a circuit with a given structure in this embodiment. For example, a pixel circuit or the like of a display device can be formed.

The above is the description of the variation examples.

At least part of this embodiment can be implemented as appropriate in combination with any of the other embodiments described in this specification.

### Embodiment 3

Described in this embodiment is an indium oxide film usable for the semiconductor layer of the transistor included in the semiconductor device of one embodiment of the present invention.

Note that in this specification and the like, indium oxide including at least a crystal part or a crystal region in a film is referred to as crystal indium oxide (crystal IO) or crystalline indium oxide (crystalline IO). Examples of crystal IO or crystalline IO include single crystal indium oxide, polycrystal indium oxide, and microcrystal indium oxide.

Indium oxide is a semiconductor material having physical properties completely different from those of an oxide semiconductor such as IGZO or zinc oxide.

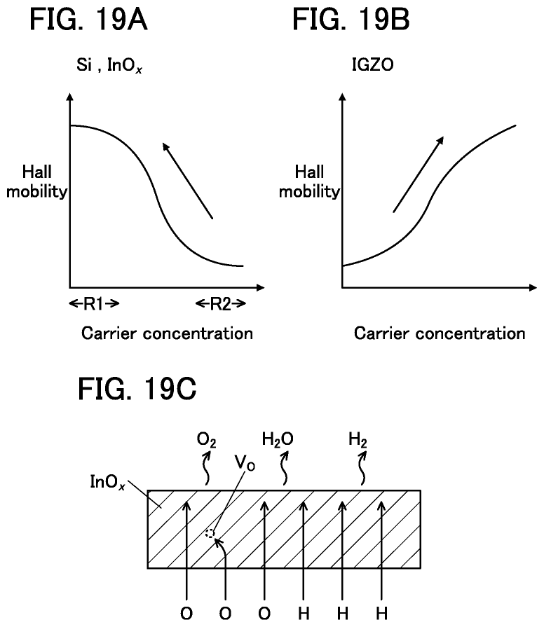

The dependence of the Hall mobility on the carrier concentration of indium oxide, silicon, and IGZO will be described. FIG. 19A is a schematic view showing the dependence of the Hall mobility on the carrier concentration of silicon (Si) and indium oxide (InO_{X}), and FIG. 19B is a schematic view showing the dependence of the Hall mobility on the carrier concentration of IGZO.

As indicated by an arrow in FIG. 19B, IGZO has a tendency in which the Hall mobility is higher as the carrier concentration is higher. By contrast, as indicated by an arrow in FIG. 19A, indium oxide has a tendency in which the Hall mobility is higher as the carrier concentration is lower (see Non-Patent Document 4). This tendency is similar to that of silicon; as the concentration of a dopant (impurity) in a material is lower, impurity scattering is inhibited more and thus the Hall mobility is higher. That is, indium oxide having higher purity and being more intrinsic has higher Hall mobility. Consequently, the physical properties of indium oxide are different from those of IGZO and similar to those of silicon. Note that the characteristics of indium oxide in FIG. 19A are based on the assumption of single crystal indium oxide; thus, the characteristics of non-single-crystal (e.g., polycrystal) indium oxide are sometimes different from those in FIG. 19A.

In FIG. 19A, the Hall mobility is extremely high in a range R1 with a low carrier concentration; thus, the range R1 can be regarded as a carrier concentration range suitable for a channel formation region of a transistor, for example. In the case of indium oxide, for example, the range R1 is a range including a carrier concentration of 1×10¹⁵ cm⁻³, e.g., a range with a carrier concentration higher than or equal to 1×10¹⁴ cm⁻³ and lower than or equal to 1×10¹⁸ cm⁻³ The adequately lowered carrier concentration will increase the Hall mobility to approximately 270 cm²/(V·s).

A region of indium oxide where the carrier concentration falls within the range R1 can include an element that reduces the carrier concentration. Examples of the element that reduces the carrier concentration include magnesium, calcium, zinc, cadmium, and copper. When indium is replaced with any of these elements, the carrier concentration can be reduced. Other examples of the element that reduces the carrier concentration include nitrogen, phosphorus, arsenic, and antimony. For example, when oxygen is replaced with nitrogen, phosphorus, arsenic, or antimony, the carrier concentration can be reduced.

The element that reduces the carrier concentration can be regarded as an element that imparts p-type conductivity. An indium oxide film to which the element that reduces the carrier concentration is added is likely to be i-type or substantially i-type in some cases. In that case, the concentration of the element that reduces the carrier concentration of the indium oxide film is preferably higher than or equal to 1×10¹⁶ atoms/cm³ and lower than or equal to 8×10²⁰ atoms/cm³, further preferably higher than or equal to 1×10¹⁶ atoms/cm³ and lower than or equal to 4×10²⁰ atoms/cm³, still further preferably higher than or equal to 1×10¹⁶ atoms/cm³ and lower than or equal to 8×10¹⁹ atoms/cm³, yet still further preferably higher than or equal to 1×10¹⁶ atoms/cm³ and lower than or equal to 5×10¹⁹ atoms/cm³. With such a concentration, the carrier concentration can be reduced while the crystal structure of the indium oxide is maintained.

A range R2 with a high carrier concentration has low electric resistance and is a carrier concentration range suitable for a source region and a drain region of a transistor, a resistor, or a transparent conductive film, for example. The range R2 is a range including a carrier concentration of 1×10²⁰ cm⁻³, e.g., a range with a carrier concentration higher than or equal to 1×10¹⁹ cm⁻³ and lower than or equal to 1×10²² cm⁻³. The adequately increased carrier concentration will decrease the resistivity to 1×10⁻⁴ Ω·cm or lower.

A region of indium oxide where the carrier concentration falls within the range R2 can include an element that increases the carrier concentration. For example, the region preferably includes the same element as those of a source electrode and a drain electrode of a transistor. Examples of the element that increases the carrier concentration include titanium, zirconium, hafnium, tantalum, tungsten, molybdenum, tin, and boron. It is particularly preferable that an oxide of the element have conductivity or semiconductor properties. As a method for supplying the element that increases the carrier concentration, a method in which a film containing the element is formed to diffuse the element, an ion implantation method, an ion doping method, a plasma immersion ion implantation method, or plasma treatment can be employed. In this specification and the like, whether or not mass separation is performed is not limited, unless otherwise specified. In this specification and the like, a method by which mass-separated ions are supplied is referred to as an ion implantation method, and a method by which non-mass-separated ions are supplied is referred to as an ion doping method, for example.

The element that increases the carrier concentration can be regarded as an element that imparts n-type conductivity. The concentration of the element that increases the carrier concentration of the indium oxide film is preferably higher than or equal to 1×10¹⁶ atoms/cm³ and lower than or equal to 8×10²⁰ atoms/cm³, further preferably higher than or equal to 1×10¹⁶ atoms/cm³ and lower than or equal to 4×10²⁰ atoms/cm³, still further preferably higher than or equal to 1×10¹⁶ atoms/cm³ and lower than or equal to 8×10¹⁹ atoms/cm³, yet still further preferably higher than or equal to 1×10¹⁶ atoms/cm³ and lower than or equal to 5×10¹⁹ atoms/cm³. With such a concentration, the carrier concentration can be increased while the crystal structure of the indium oxide is maintained. In some cases, antimony also functions as the element that increases the carrier concentration.

Since indium oxide is an oxide whose valence electron can be controlled, the threshold voltage of a transistor using a semiconductor layer containing indium oxide can be controlled. In addition, the region with a low carrier concentration and the region with a high carrier concentration of indium oxide can be used as a channel formation region and source and drain regions, respectively, of a transistor. As for IGZO, distortion due to stress of an electrode in contact with IGZO is formed in a source region and a drain region and n-type regions are formed in some cases. Since a valence electron can be controlled in indium oxide unlike in IGZO, formation of distortion can be inhibited in a film of indium oxide. The film with less distortion will have higher reliability. For example, when the region where the carrier concentration falls within the range R1 and the region where the carrier concentration falls within the range R2, which are shown in FIG. 19A, are separately formed in an indium oxide film, what is called an n-i-n junction (a junction between an n-type region, an i-type region, and an n-type region) can be formed. Although valence electron control in a transistor containing silicon is generally known, valence electron control in a transistor containing indium oxide is a novel technical idea that cannot be conceived usually.

With the use of the above technical idea, a transistor containing indium oxide in this specification and the like has two or more, preferably three or more, further preferably four or more, and most preferably all of the following features (1) to (5): (1) high on-state current (i.e., high mobility); (2) low off-state current; (3) normally-off characteristics; (4) high reliability; and (5) high cutoff frequency (fT). For example, the transistor containing indium oxide in this specification and the like has high mobility, low off-state current, and normally-off characteristics. This transistor is different from a normally-on transistor having high mobility.

The expression “a semiconductor is of an i-type” can be replaced with the expression “the Fermi level (Ef) is equal to the intrinsic Fermi level (Ei) (Ef=Ei)”. As shown in FIG. 19B, the Hall mobility is lower as the carrier concentration is lower in IGZO. Accordingly, in the case where Ef eventually becomes equal to Ei, carriers disappear (i.e., the physical properties of IGZO become similar to those of an insulator) and a transistor containing IGZO cannot operate. By contrast, the Hall mobility is higher as the carrier concentration is lower in indium oxide as shown in FIG. 19A. In the case where Ef eventually becomes equal to Ei, the Hall mobility is the highest. That is, a transistor containing indium oxide can have high field-effect mobility when Ef is equal to Ei. Note that a transistor containing indium oxide has a low carrier concentration and thus tends to have normally-off characteristics. Hence, a transistor containing indium oxide can have both normally-off characteristics and high field-effect mobility.

Normally off means a state where no current flows through a transistor when a potential is not applied to its gate or its gate-source voltage is 0 V. The normally-off characteristics can be evaluated using the threshold voltage (Vth) or shift value (Vsh) of a transistor. Note that Vth is calculated by a constant current method unless otherwise specified. Specifically, Vth is gate voltage (Vg) at which a value of drain current (Id)×channel length (L)÷channel width (W) in the Id−Vg characteristics of a transistor is 1 nA (1×10⁻⁹ A). Vsh is gate voltage (Vg) at a point of intersection of a straight line of Id=1 pA (1×10⁻¹² A) and a tangent line of drain current (Id) on a logarithmic scale that has the highest gradient in the Id−Vg characteristics of the transistor, or gate voltage (Vg) at a point of intersection of a straight line of Id=1 pA and a straight line extrapolated from two points where the slope of Id on a logarithmic scale has the highest gradient in the Id-Vg characteristics of the transistor. For example, when at least one of Vth and Vsh is 0 or a positive value, the transistor can be regarded as having normally-off characteristics.

In order that a semiconductor can be of an i-type, i.e., Ef can be equal to Ei, in a transistor containing indium oxide, the structure of a film in contact with an indium oxide film is important. For example, a transistor containing indium oxide can have a film structure in which a silicon oxide film, which is in contact with an indium oxide film, a hafnium oxide film, and a silicon nitride film are stacked. Such a film structure can achieve Ef=Ei, enabling a semiconductor device to have high reliability.

In the above film structure, a film containing oxygen, such as a silicon oxynitride film, a silicon nitride oxide film, an aluminum oxide film, or a gallium oxide film, can be used instead of the silicon oxide film. Also in the above film structure, a silicon nitride oxide film, a silicon oxynitride film, or the like can be used instead of the silicon nitride film. The hafnium oxide film that is closer to the indium oxide film than the silicon nitride film is functions as a hydrogen gettering site.

The above film structure can be regarded as a structure in which a film that is capable of supplying oxygen to the indium oxide film (e.g., the silicon oxide film), a film that is capable of gettering hydrogen (e.g., the hafnium oxide film), and a film that is capable of inhibiting entry of oxygen and hydrogen (e.g., the silicon nitride film) are stacked in this order from the indium oxide film side. With this structure, oxygen vacancies in the indium oxide film are filled with oxygen in the silicon oxide film. Moreover, hydrogen in the indium oxide film is captured in the hafnium oxide film by heat treatment or the like. Providing the silicon nitride film inhibits entry of oxygen and hydrogen from the outside. That is, the above film structure enables the indium oxide film to be closer to an i-type film. Thus, a transistor including the indium oxide film has high field-effect mobility and high reliability.

Next, an indium oxide film used for a transistor will be described. The indium oxide film preferably has crystallinity (i.e., has a crystal grain). Examples of a film having a crystal grain include a single crystal film, a polycrystal film, and an amorphous film having a crystal grain (also referred to as a microcrystal film). In particular, the indium oxide film is preferably a polycrystal film, further preferably a single crystal film. A single crystal film does not have a crystal grain boundary (also referred to as a grain boundary). Impurities that block the carrier flow (typically, an insulating impurity, an insulating oxide, or the like) are likely to be segregated at a crystal grain boundary. The use of a single crystal film can inhibit carrier scattering or the like at the crystal grain boundary, thereby achieving a transistor having high field-effect mobility. In addition, the use of a single crystal film produces an excellent effect of reducing a variation in transistor characteristics caused by the crystal grain boundary.

A polycrystal film is preferable because it can reduce carrier scattering as compared with a microcrystal film or an amorphous film and enables a transistor to have high field-effect mobility. In the case of using a polycrystal film, it is preferable to use a film that has as large a crystal grain size as possible and few crystal grain boundaries. Note that in the case where the crystal grain boundary is neither included nor observed in a channel formation region of a transistor including a polycrystal indium oxide film, the channel formation region is positioned in a single crystal region included in the polycrystal film and thus the transistor can be regarded as a transistor containing single crystal indium oxide.

The crystallinity of indium oxide can be analyzed with XRD, TEM, or ED, for example. Alternatively, two or more of these methods may be combined for the analysis.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be referred to as a single crystal film. A semiconductor layer where the direction of a crystal axis is continuously changed with another crystal axis or a crystal orientation as a rotation axis in one crystal grain in a channel formation region can also be referred to as a single crystal film.

A channel formation region refers to a region of a semiconductor layer that overlaps with (or faces) a gate electrode with a gate insulating layer therebetween and is positioned between a region in contact with a source electrode and a region in contact with a drain electrode. A current path in a channel formation region is the shortest distance between a source electrode and a drain electrode. Thus, a crystal grain, a crystal grain boundary, a crystal axis, a crystal orientation, or the like in a channel formation region can be confirmed in observation of a cross section including a semiconductor layer, a source electrode, and a drain electrode.

The impurity concentration in an indium oxide film in a channel formation region is preferably as low as possible. Impurities in the indium oxide film in the channel formation region can function as a carrier scattering source and cause a reduction in field-effect mobility. Such impurities might inhibit crystal growth of the indium oxide film. Examples of the impurities for the indium oxide film include boron. The concentrations of the impurities in the indium oxide film are each preferably lower than or equal to 0.1%, further preferably lower than or equal to 0.01% (100 ppm). Note that carbon, hydrogen, and the like are elements that would be contained in a film formation gas or a precursor in film formation, and the amounts of these elements remaining in the indium oxide film might be larger than those of the impurities.

The indium oxide film may contain an element that can form a trivalent cation like indium as long as the cubic crystal structure (bixbyite structure) is retained. Examples of the element include Group 13 elements such as gallium and aluminum and Group 3 elements in the periodic table. These elements are each more strongly bonded to oxygen than indium is; thus, by adding these elements to the indium oxide film, formation of oxygen vacancies (V_{O}) in the indium oxide film can be inhibited. Moreover, since these elements exist mainly as trivalent cations in oxides, the carrier concentration of the indium oxide film can be kept low. Thus, the threshold voltage of the transistor can be shifted positively. Moreover, the transistor can have normally-off characteristics. Accordingly, the transistor having favorable electrical characteristics can be provided.

The concentration of the above element in the indium oxide film is preferably higher than or equal to 1×10¹⁶ atoms/cm³ and lower than or equal to 8×10²⁰ atoms/cm³, further preferably higher than or equal to 1×10¹⁶ atoms/cm³ and lower than or equal to 4×10²¹ atoms/cm³, still further preferably higher than or equal to 1×10¹⁶ atoms/cm³ and lower than or equal to 8×10¹⁹ atoms/cm³, yet still further preferably higher than or equal to 1×10¹⁶ atoms/cm³ and lower than or equal to 5×10¹⁹ atoms/cm³.

Note that the element that imparts n-type conductivity, the element that imparts p-type conductivity, and the element that can be a trivalent cation can each be added to the indium oxide film by an ion doping method, an ion implantation method, a thermal diffusion method, or the like. Alternatively, the element that imparts n-type conductivity, the element that imparts p-type conductivity, and the element that can be a trivalent cation can each be added to a sputtering target, a film formation gas, a precursor for ALD deposition, or the like at the time of forming the indium oxide film. Alternatively, the element that imparts n-type conductivity, the element that imparts p-type conductivity, and the element that can be a trivalent cation can each be autodoped from a chamber where the indium oxide film is formed. Note that autodoping refers to automatic addition of an element contained in, for example, a member of the film-formation chamber into the indium oxide film during the film formation.

An indium oxide film in this specification and the like has high film density. The theoretical film density of the indium oxide film is 7.18 g/cm³. The film density of the indium oxide film in this specification and the like ranges from 6.70 g/cm³ to 7.18 g/cm³, preferably from 6.90 g/cm³ to 7.18 g/cm³, further preferably from 7.00 g/cm³ to 7.18 g/cm³.

The film density can be evaluated by Rutherford backscattering spectrometry (RBS) or X-ray reflection (XRR), for example. A difference in film density can be evaluated using a cross-sectional TEM image in some cases. In TEM observation, a transmission electron (TE) image is dark-colored (dark) when the film density is high, and a TE image is pale (bright) when the film density is low.

One feature of an indium oxide film is to have a higher property of transmitting (diffusing) oxygen than an IGZO film. As shown in FIG. 19C, oxygen (O) diffused in an indium oxide film (denoted as InO_{X}) is transmitted through the indium oxide film and released as an oxygen molecule (O₂). When reacting with hydrogen contained in the film, oxygen is released as a water molecule (H₂O) in some cases. In the case where the film includes oxygen vacancies (Vₒ), the oxygen vacancies are filled with diffused oxygen atoms. Since oxygen is easily diffused in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

As shown in FIG. 19C, hydrogen is diffused in the indium oxide film. Hydrogen diffused into the indium oxide film from the outside is transmitted through the indium oxide film and is released as a hydrogen molecule (H₂). When reacting with oxygen contained in the film, hydrogen is released as a water molecule. Note that oxygen and hydrogen described above are diffused in the indium oxide film by heat treatment. The temperature of the heat treatment is higher than or equal to 200 °C and lower than or equal to 700 °C, preferably higher than or equal to 350 °C and lower than or equal to 650 °C, further preferably higher than or equal to 400 °C and lower than or equal to 500 °C.

A transistor including an indium oxide film is an accumulation-type transistor in which electrons are majority carriers. Assuming that the relaxation time of carriers is constant, the electron (carrier) mobility is higher as the effective mass of electrons (carriers) is smaller. That is, a transistor containing indium oxide with a small effective mass of electrons can have a high on-state current or high field-effect mobility.

Table 1 shows the effective mass in each of single crystal indium oxide (here, In₂O₃) and single crystal silicon (Si). As shown in Table 1, indium oxide has features of a small effective mass of electrons and a large effective mass of holes. In addition, the effective mass of electrons in indium oxide hardly depends on the crystal orientation. Thus, a transistor containing indium oxide having crystallinity can have high field-effect mobility and high frequency characteristics (also referred to as f characteristics). A large effective mass of holes allows a transistor to have an extremely low off-state current. Since indium oxide has a smaller effective mass of electrons and a larger effective mass of holes than silicon as shown in Table 1, a transistor containing indium oxide can have higher field-effect mobility and a lower off-state current than a Si transistor.

TABLE 1
Effective mass in In₂O₃

| Electron | | | |
|---|---|---|---|
| [100] direction | [110] direction | [111] direction | Hole |
| 0.17 | 0.18 | 0.19 | 3.56 |

Effective mass in Si

| Electron | Hole |
|---|---|
| 0.26 | 0.17 |

A seed layer is preferably provided in contact with at least part of the indium oxide film having crystallinity. A material of the seed layer is preferably selected such that the difference in a lattice constant (also referred to as lattice mismatch) between the crystal included in indium oxide and the crystal included in the material is small. In this case, the crystallinity of the indium oxide film can be improved. As a layer in contact with at least part of the indium oxide film having crystallinity, a substrate (e.g., a single crystal substrate) may be used.

One of methods for evaluating a lattice mismatching level is a method using a value of a lattice mismatch degree described below. A lattice mismatch degree Δa [%] of a crystal included in a film to be formed (here, the indium oxide film) with respect to the crystal included in the seed layer is calculated by the formula: Δa=((L₁−L₂)/L₂)×100. Here, L₁ is the lattice constant or the length of the unit lattice vector of the crystal included in the film to be formed, and L₂ is the lattice constant or the length of the unit lattice vector of the crystal included in the seed layer.

The absolute value of the lattice mismatch degree Δa between the seed layer and the indium oxide film is preferably as small as possible, most preferably 0. For example, Aa can be greater than or equal to −5% and less than or equal to 5%, preferably greater than or equal to −4% and less than or equal to 4%, further preferably greater than or equal to −3% and less than or equal to 3%, still further preferably greater than or equal to −2% and less than or equal to 2%.

Indium oxide has a cubic crystal structure (a bixbyite structure). For example, an yttria-stabilized zirconia (YSZ) can have a cubic crystal structure (a fluorite crystal structure). The lattice mismatch degree of an indium oxide crystal with respect to a YSZ crystal having the cubic crystal structure is within the range of −2% to 2%, which enables epitaxial growth of a single crystal film of indium oxide on the YSZ substrate.

The crystal structures of the seed layer and the indium oxide film do not necessarily have the same crystal system or crystal orientation in some cases. For example, a film including a crystal with a hexagonal crystal structure or a trigonal crystal structure can be provided below an indium oxide film having a cubic crystal structure. For example, when the crystal orientation of a seed layer surface is set to [001] and the crystal orientation of a bottom surface of the indium oxide film is set to [111], the necessary condition for crystal orientation in epitaxial growth can be satisfied. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO. A single crystal film of indium oxide can be formed not only over a YSZ substrate but also over an insulating film. By contrast, a single crystal film of silicon is not easily formed over an insulating film. Note that a silicon crystal has a diamond structure. Thus, although indium oxide and silicon exhibit similar characteristics as single crystals, they differ in whether a single crystal can be formed over an insulating film.

At least part of this embodiment can be implemented as appropriate in combination with any of the other embodiments described in this specification.

### Embodiment 4

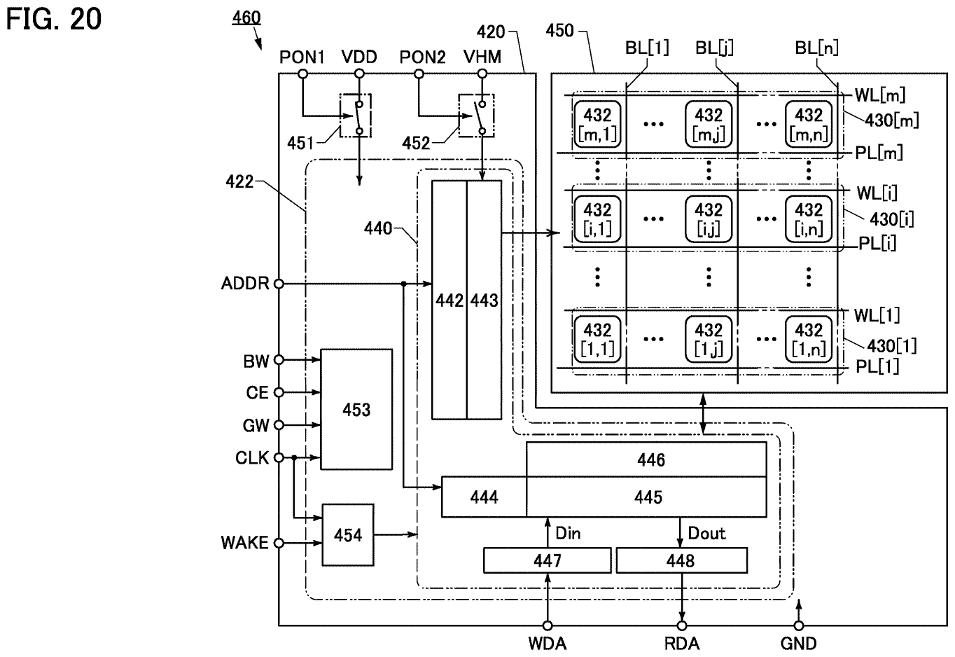

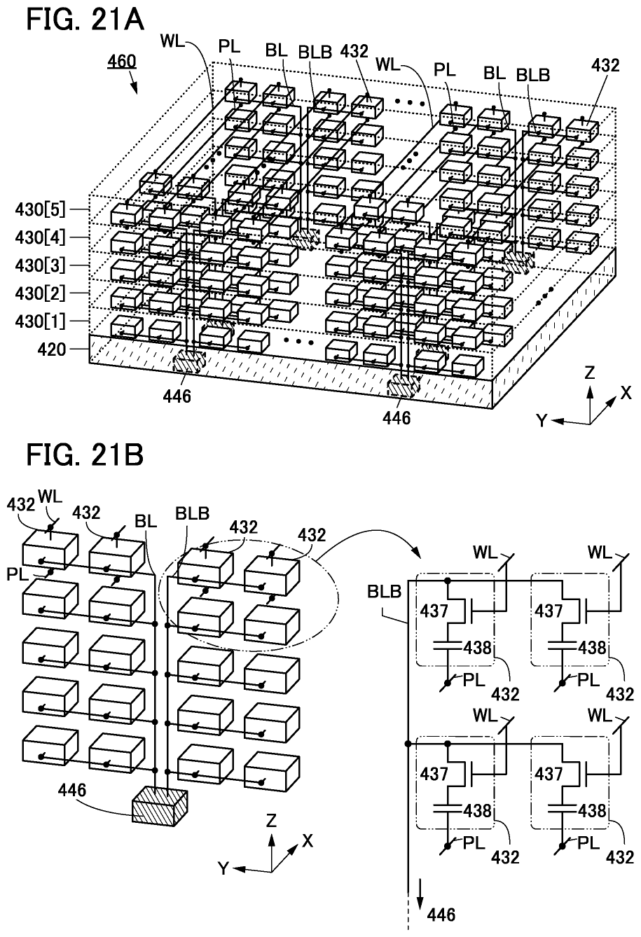

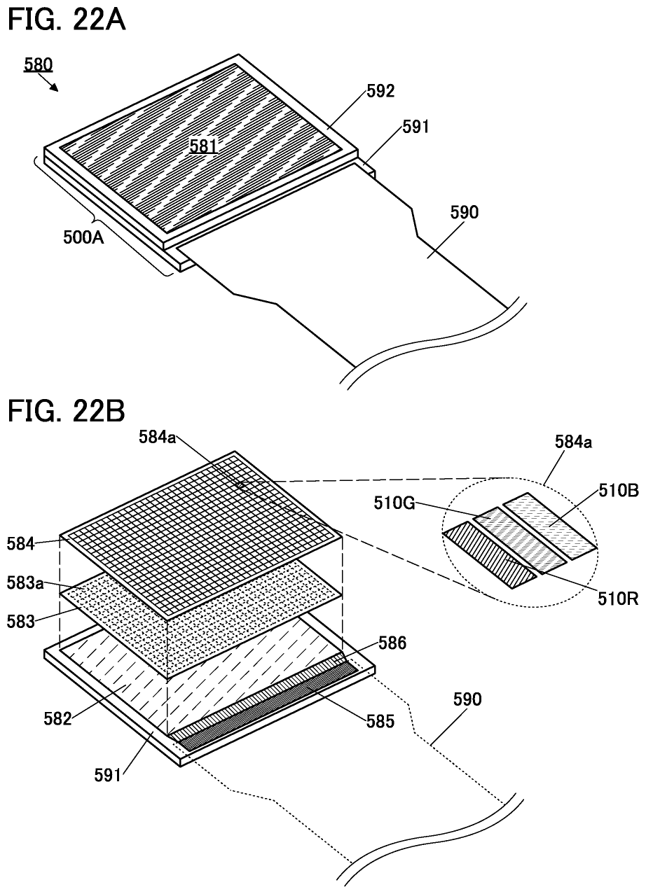

In this embodiment, a memory device of one embodiment of the present invention will be described with reference to FIG. 20, FIGS. 21A and 21B, and FIGS. 22A and 22B. Described in this embodiment is a structure example of a memory device in which a layer including memory cells is stacked over a layer provided with a driver circuit including a sense amplifier.

The transistor (denoted as an OS transistor) in which a channel is formed in an oxide semiconductor, which is exemplified in Embodiment 2, can be used as a transistor included in a memory cell exemplified below.

### Structure Example of Memory Device

FIG. 20 is a block diagram illustrating a structure example of a memory device 460 of one embodiment of the present invention. The memory device 460 illustrated in FIG. 20 includes a layer 420 and a layer 450 stacked thereover.

The layer 420 is a layer including Si transistors. The layer 450 is provided with element layers 430[1] to 430[m] (m is an integer greater than or equal to 2) as stacked layers. The element layers 430[1] to 430[m] include OS transistors. The layer 450 provided with the stacked layers including OS transistors can be stacked over the layer 420.

Elements such as OS transistors and capacitors included in the element layers 430[1] to 430[m] form memory cells. FIG. 20 illustrates an example in which the element layers 430[1] to 430[m] include a plurality of memory cells 432 arranged in a matrix of m rows and n columns (n is an integer greater than or equal to 2).

In FIG. 20, the memory cell 432 in the first row and the first column is denoted by a memory cell 432[1,1] and the memory cell 432 in the m-th row and the n-th column is denoted by a memory cell 432[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 432 in the i-th row and the j-th column is referred to as a memory cell 432[i,j]. Note that in this embodiment and the like, “i+α” (α is a positive or negative integer) is not below 1 and does not exceed m.

Similarly, “j+α” is not below 1 and does not exceed n.

FIG. 20 illustrates m wirings WL extending in a row direction, m wirings PL extending in the row direction, and n wirings BL extending in a column direction. In this embodiment and the like, a first (first row) wiring WL is referred to as a wiring WL[1] and an m-th (m-th row) wiring WL is referred to as a wiring WL[m]. Similarly, a first (first row) wiring PL is referred to as a wiring PL[l] and an m-th (m-th row) wiring PL is referred to as a wiring PL[m]. Similarly, a first (first column) wiring BL is referred to as a wiring BL[1] and an n-th (n-th column) wiring BL is referred to as a wiring BL[n]. Note that the number of the element layers 430[1] to 430[m] is not necessarily the same as the number of the wirings WL (and the wirings PL).

The plurality of memory cells 432 provided in the i-th row are electrically connected to the wiring WL in the i-th row (a wiring WL[i]) and the wiring PL in the i-th row (a wiring PL[i]). The plurality of memory cells 432 provided in the j-th column are electrically connected to the wiring BL in the j-th column (a wiring BL[j]).

The wiring BL functions as a bit line for writing and reading data. The wiring WL functions as a word line for controlling on and off (a conduction state and a non-conduction state) of an access transistor serving as a switch. The wiring PL has a function of a constant potential line connected to a capacitor. Note that a wiring for transmitting a back gate potential can be additionally provided.

The memory cells 432 in the element layers 430[1] to 430[m] are connected to a sense amplifier 446 through the wirings BL. The wirings BL can be provided horizontally and perpendicularly to the surface of a substrate provided with the layer 420. When the wirings BL extending from the memory cells 432 in the element layers 430[1] to 430[m] are composed of not only wirings provided horizontally to the substrate surface but also wirings provided perpendicularly to the substrate surface, the length of the wiring between the element layer 430 and the sense amplifier 446 can be shortened. The signal transmission distance between the memory cell and the sense amplifier can be shortened and the resistance and parasitic capacitance of the bit line can be significantly reduced, so that the power consumption and signal delay can be reduced. Thus, power consumption and signal delay of the memory device 460 can be reduced. Moreover, operation is possible even when the capacitance of the capacitors included in the memory cells 432 is reduced. Accordingly, the memory device 460 can be downsized.

The layer 420 includes a PSW 451 (power switch), a PSW 452, and a peripheral circuit 422. The peripheral circuit 422 includes a driver circuit 440, a control circuit 453, and a voltage generation circuit 454. Note that each circuit included in the layer 420 includes a Si transistor.

In the memory device 460, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 453.

The control circuit 453 is a logic circuit having a function of controlling the entire operation of the memory device 460. For example, the control circuit performs logical operation on the signals CE, GW, and BW to determine an operation mode (e.g., write operation or read operation) of the memory device 460. Alternatively, the control circuit 453 generates a control signal for the driver circuit 440 so that the operation mode is executed.

The voltage generation circuit 454 has a function of generating negative voltage. The signal WAKE has a function of controlling the input of the signal CLK to the voltage generation circuit 454. For example, when an H-level signal is supplied as the signal WAKE, the signal CLK is input to the voltage generation circuit 454, and the voltage generation circuit 454 generates negative voltage.

The driver circuit 440 is a circuit for writing and reading data to/from the memory cells 432. The driver circuit 440 includes the above-described sense amplifier 446 in addition to a row decoder 442, a column decoder 444, a row driver 443, a column driver 445, an input circuit 447, and an output circuit 448.

The row decoder 442 and the column decoder 444 have a function of decoding the signal ADDR. The row decoder 442 is a circuit for specifying a row to be accessed, and the column decoder 444 is a circuit for specifying a column to be accessed. The row driver 443 has a function of selecting the wiring WL specified by the row decoder 442. The column driver 445 has a function of writing data to the memory cells 432, a function of reading data from the memory cells 432, a function of retaining the read data, and the like.

The input circuit 447 has a function of retaining the signal WDA. Data retained by the input circuit 447 is output to the column driver 445. Data output from the input circuit 447 is data (Din) to be written to the memory cells 432. Data (Dout) read from the memory cells 432 by the column driver 445 is output to the output circuit 448. The output circuit 448 has a function of retaining Dout. In addition, the output circuit 448 has a function of outputting Dout to the outside of the memory device 460. Data output from the output circuit 448 is the signal RDA.

The PSW 451 has a function of controlling the supply of VDD to the peripheral circuit 422. The PSW 452 has a function of controlling the supply of VHM to the row driver 443. Here, in the memory device 460, a high power supply potential is VDD and a low power supply potential is GND (a ground potential). In addition, VHM is a high power supply potential used to set the word line at a high level and is higher than VDD. The on/off of the PSW 451 is controlled by the signal PON1, and the on/off of the PSW 452 is controlled by the signal PON2. The number of power domains to which VDD is supplied is one in the peripheral circuit 422 in FIG. 20 but can be two or more. In that case, a power switch is provided for each power domain.

The element layers 430[1] to 430[m] can be stacked over the layer 420. FIG. 21A illustrates a perspective view of the memory device 460 in which five (m=5) element layers 430[1] to 430[5] are stacked over the layer 420.

In FIG. 21A, the element layer 430 in the first layer, the element layer 430 in the second layer, and the element layer 430 in the fifth layer are denoted by the element layer 430[1], the element layer 430[2], and the element layer 430[5], respectively. FIG. 21A also illustrates the wiring WL and the wiring PL provided to extend in the X direction and the wiring BL and a wiring BLB provided to extend in the Y direction and the Z direction (the direction perpendicular to the surface of the substrate where the driver circuit is provided). The wiring BLB is an inverted bit line. Note that for easy viewing of the drawing, some of the wirings WL and the wirings PL included in the element layers 430 are not illustrated.

FIG. 21B is a schematic view illustrating a structure example of the sense amplifier 446 connected to the wirings BL and BLB and the memory cells 432 included in the element layers 430[1] to 430[5] connected to the wirings BL and BLB, which are illustrated in FIG. 21A. Note that a structure where a plurality of memory cells (the memory cells 432) are electrically connected to one wiring BL and one wiring BLB is also referred to as “memory string”.

FIG. 21B illustrates an example of a circuit structure of the memory cell 432 connected to the wiring BLB. The memory cell 432 includes a transistor 437 and a capacitor 438. As for the transistor 437, the capacitor 438, and the wirings (e.g., the wiring BL and the wiring WL), for example, a wiring BL[1] and a wiring WL[1] are referred to as the wiring BL and the wiring WL in some cases.

In the memory cell 432, one of a source and a drain of the transistor 437 is connected to the wiring BL. The other of the source and the drain of the transistor 437 is connected to one electrode of the capacitor 438. The other electrode of the capacitor 438 is connected to the wiring PL. A gate of the transistor 437 is connected to the wiring WL.

The wiring PL is a wiring for supplying a constant potential for retaining the potential of the capacitor 438. When a plurality of the wirings PL are connected to each other and used as one wiring, the number of wirings can be reduced.

As the memory cell 432 illustrated in FIG. 21B, the semiconductor device described in Embodiment 1 can be used. For example, the transistor 200 illustrated in FIG. 18A can be used as the transistor 437, and the capacitor 470 illustrated in FIG. 18A can be used as the capacitor 438. In this case, the wiring WL corresponds to the conductive layer 260 or the conductive layer 476, the wiring BLB corresponds to the conductive layer 475, and the wiring PL corresponds to the conductive layer 486.

In one embodiment of the present invention, OS transistors are provided in stacked layers and a wiring functioning as a bit line is provided in the direction perpendicular to the surface of the substrate provided with the layer 420. In addition, the transistors 437 and the capacitors 438 included in the memory cells 432 are arranged in the direction perpendicular to the surface of the substrate provided with the layer 420. When the elements and the wirings are provided in the direction perpendicular to the substrate surface, the length of a wiring between element layers can be shortened and the density of elements per unit area can be increased. Thus, the memory device can have excellent memory capacity and be excellent in reducing power consumption.

At least part of this embodiment can be implemented as appropriate in combination with any of the other embodiments described in this specification.

### Embodiment 5

Described in this embodiment are structure examples of a display device that can employ the transistor of one embodiment of the present invention.

Since the transistor of one embodiment of the present invention can be extremely minute, a display device that employs the transistor of one embodiment of the present invention can be an extremely high-resolution display device. For example, a display device of one embodiment of the present invention can be used for display portions of information terminal devices (wearable devices) such as wristwatch-type and bracelet-type information terminal devices and display portions of devices that can be worn on a head (head-mounted displays (HMD)) such as a headset-type device for virtual reality (VR) and a glasses-type device for augmented reality (AR).

In the display device of one embodiment of the present invention, a driver circuit and a pixel circuit can be provided to overlap with each other. In that case, the transistor in which a channel is formed in an oxide semiconductor, which is exemplified in Embodiment 2, can be used as a transistor included in a pixel.

### [Display Module]

FIG. 22A is a perspective view of a display module 580. The display module 580 includes a display device 500A and an FPC 590.

The display module 580 includes a substrate 591 and a substrate 592. The display module 580 includes a display portion 581. The display portion 581 is a region where an image is displayed.

FIG. 22B is a perspective view schematically illustrating a structure on the substrate 591 side. Over the substrate 591, a circuit portion 582, a pixel circuit portion 583 over the circuit portion 582, and a pixel portion 584 over the pixel circuit portion 583 are stacked. In addition, a terminal portion 585 to be connected to the FPC 590 is provided in a portion over the substrate 591 that does not overlap with the pixel portion 584. The terminal portion 585 and the circuit portion 582 are electrically connected to each other through a wiring portion 586 formed of a plurality of wirings.

The pixel portion 584 includes a plurality of pixels 584a arranged periodically. An enlarged view of one pixel 584a is illustrated on the right side in FIG. 22B. The pixel 584a includes a light-emitting element 510R that emits red light, a light-emitting element 510G that emits green light, and a light-emitting element 510B that emits blue light.

The pixel circuit portion 583 includes a plurality of pixel circuits 583a arranged periodically. One pixel circuit 583a is a circuit for controlling light emission of three light-emitting devices included in one pixel 584a. One pixel circuit 583a may be provided with three circuits for controlling light emission of one light-emitting device. For example, the pixel circuit 583a can include at least one selection transistor, one current control transistor (driving transistor), and a capacitor for one light-emitting device. In that case, a gate signal is input to a gate of the selection transistor, and a source signal is input to a source of the selection transistor. Thus, an active-matrix display panel is achieved.

The circuit portion 582 includes a circuit for driving the pixel circuits 583a in the pixel circuit portion 583. For example, the circuit portion 582 preferably includes one or both ofa gate line driver circuit and a source line driver circuit. The circuit portion 582 may further include at least one of an arithmetic circuit, a memory circuit, a power supply circuit, and the like. In addition, a transistor provided in the circuit portion 582 may constitute part of the pixel circuit 583a. That is, the pixel circuit 583a maybe constituted by a transistor included in the pixel circuit portion 583 and a transistor included in the circuit portion 582.

The FPC 590 functions as a wiring for supplying a video signal, a power supply potential, and the like to the circuit portion 582 from the outside. In addition, an IC may be mounted on the FPC 590.

The display module 580 can have a structure in which one or both of the pixel circuit portion 583 and the circuit portion 582 are stacked below the pixel portion 584; thus, the aperture ratio (effective display area ratio) of the display portion 581 can be significantly high. For example, the aperture ratio of the display portion 581 can be greater than or equal to 40% and less than 100%, preferably greater than or equal to 50% and less than or equal to 95%, further preferably greater than or equal to 60% and less than or equal to 95%. Furthermore, the pixels 584a can be arranged extremely densely and thus the display portion 581 can have extremely high resolution. For example, the pixels 584a are preferably arranged in the display portion 581 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 580 has extremely high resolution, and thus is suitable for a device for VR such as a head-mounted display, or a glasses-type device for AR. For example, even with a structure in which the display portion of the display module 580 is viewed through a lens, pixels of the extremely-high-resolution display portion 581 included in the display module 580 are not recognized even when the display portion is enlarged by the lens, so that display providing a high sense of immersion can be performed. Without being limited thereto, the display module 580 is suitable for an electronic apparatus having a comparatively small display portion. For example, the display module 580 is suitable for a display portion of a wearable electronic apparatus, such as a wristwatch.

### [Display Device 500A]

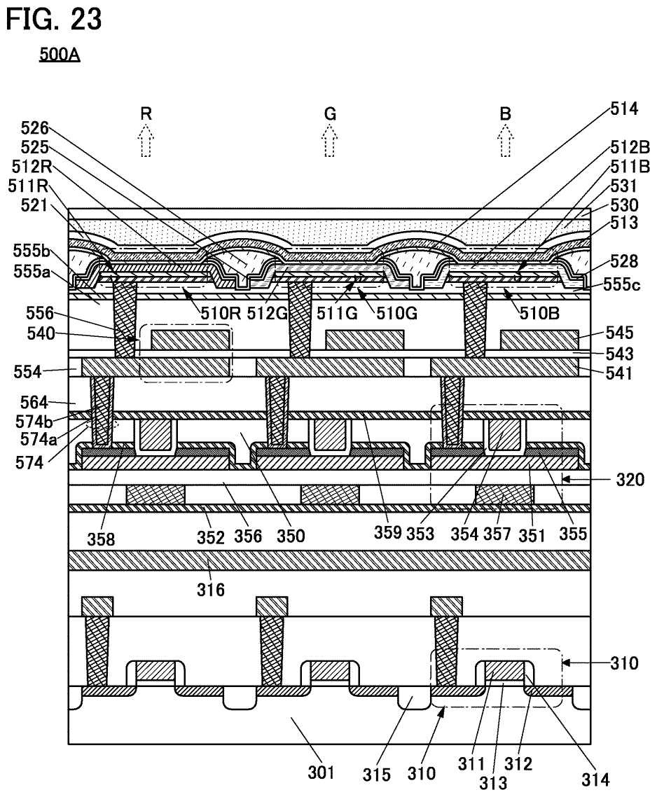

The display device 500A illustrated in FIG. 23 includes a substrate 301, the light-emitting element 510R, the light-emitting element 510G, the light-emitting element 510B, a capacitor 540, a transistor 310, and a transistor 320.

The transistor 310 is a transistor in which a channel is formed in a single crystal substrate. As the transistor 320, the transistor exemplified in Embodiment 2, in which a channel is formed in an oxide semiconductor, can be used.

The transistor 310 is a transistor that includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance regions 312 are regions where the substrate 301 is doped with an impurity, and serve as a source and a drain. The insulating layer 314 is provided to cover side surfaces of the conductive layer 311.

An element isolation layer 315 is provided between two adjacent transistors 310 to be embedded in the substrate 301.

The transistor 320 includes a semiconductor layer 351, an insulating layer 353, a conductive layer 354, a pair of conductive layers 355, an insulating layer 356, and a conductive layer 357.

An insulating layer 352 is provided over a layer where the transistor 310 is provided with a wiring layer 316 and an interlayer insulating layer therebetween. The insulating layer 352 functions as a barrier layer that prevents diffusion of impurities from the substrate 301 side into the transistor 320 and release of oxygen from the semiconductor layer 351 to the insulating layer 352 side. As the insulating layer 352, for example, a film in which hydrogen or oxygen is less likely to be diffused than in a silicon oxide film, such as an aluminum oxide film, a hafnium oxide film, or a silicon nitride film, can be used.

The conductive layer 357 is provided over the insulating layer 352, and the insulating layer 356 is provided to cover the conductive layer 357. The conductive layer 357 functions as a second gate electrode of the transistor 320, and part of the insulating layer 356 functions as a second gate insulating layer. An oxide insulating film such as a silicon oxide film is preferably used for at least a region of the insulating layer 356 that is in contact with the semiconductor layer 351. The top surface of the insulating layer 356 is preferably planarized.

The semiconductor layer 351 is provided over the insulating layer 356. The semiconductor layer 351 preferably includes a metal oxide (also referred to as oxide semiconductor) film exhibiting semiconductor characteristics. The pair of conductive layers 355 are provided on and in contact with the semiconductor layer 351, and function as a source electrode and a drain electrode.

An insulating layer 358 and an insulating layer 350 are provided to cover top surfaces and side surfaces of the pair of conductive layers 355, side surfaces of the semiconductor layer 351, and the like. The insulating layer 358 functions as a barrier layer that prevents diffusion of impurities such as water and hydrogen into the semiconductor layer 351 and release of oxygen from the semiconductor layer 351. As the insulating layer 358, an insulating film similar to the insulating layer 352 can be used.

An opening portion reaching the semiconductor layer 351 is provided in the insulating layers 358 and 350. The conductive layer 354 and the insulating layer 353 that is in contact with the top surface of the semiconductor layer 351 are embedded in the opening portion. The conductive layer 354 functions as a first gate electrode, and the insulating layer 353 functions as a first gate insulating layer.

The top surface of the conductive layer 354, the top surface of the insulating layer 353, and the top surface of the insulating layer 350 are subjected to planarization treatment so that they are level with each other, and an insulating layer 359 is provided to cover these layers. The insulating layer 359 functions as a barrier layer that prevents diffusion of impurities such as water and hydrogen into the transistor 320. As the insulating layer 359, an insulating film similar to the insulating layer 352 can be used.

A structure in which the semiconductor layer where a channel is formed is interposed between two gates is employed for the transistor 320. The two gates may be connected to each other and supplied with the same signal to drive the transistor. Alternatively, a potential for controlling the threshold voltage may be applied to one of the two gates and a potential for driving may be applied to the other of the two gates to control the threshold voltage of the transistor.

An insulating layer 564 is provided over the insulating layer 359. The insulating layer 564 functions as an interlayer insulating layer.

A plug 574 electrically connected to one of the conductive layers 355 is provided to be embedded in the insulating layers 564, 359, 350, and 358. Here, the plug 574 preferably includes a conductive layer 574a that covers the side surface of the opening portion in the insulating layer 564 and the like and part of the top surface of the conductive layer 355, and a conductive layer 574b in contact with the top surface of the conductive layer 574a. In that case, a conductive material in which oxygen is less likely to be diffused is preferably used for the conductive layer 574a.

The capacitor 540 is provided over the insulating layer 564. The capacitor 540 includes a conductive layer 541, a conductive layer 545, and an insulating layer 543 positioned therebetween. The conductive layer 541 functions as one electrode of the capacitor 540, the conductive layer 545 functions as the other electrode of the capacitor 540, and the insulating layer 543 functions as a dielectric of the capacitor 540.

The conductive layer 541 is embedded in an insulating layer 554 provided over the insulating layer 564. The conductive layer 541 is electrically connected to the conductive layer 355 of the transistor 320 through the plug 574. The insulating layer 543 is provided to cover the conductive layer 541. The conductive layer 545 is provided in a region overlapping with the conductive layer 541 with the insulating layer 543 therebetween.

An insulating layer 555a is provided to cover the capacitor 540, an insulating layer 555b is provided over the insulating layer 555a, and an insulating layer 555c is provided over the insulating layer 555b.

An inorganic insulating film can be suitably used for each of the insulating layers 555a, 555b, and 555c. For example, it is preferable that a silicon oxide film be used for each of the insulating layers 555a and 555c and that a silicon nitride film be used for the insulating layer 555b. This enables the insulating layer 555b to function as an etching protective film. Although this embodiment describes an example in which the insulating layer 555c is partly etched and a depressed portion is formed, the depressed portion is not necessarily provided in the insulating layer 555c.

The light-emitting elements 510R, 510G, and 510B are provided over the insulating layer 555c.

The light-emitting element 510R includes a pixel electrode 511R, an organic layer 512R, a common layer 514, and a common electrode 513. The light-emitting element 510G includes a pixel electrode 511G, an organic layer 512G, the common layer 514, and the common electrode 513. The light-emitting element 510B includes a pixel electrode 511B, an organic layer 512B, the common layer 514, and the common electrode 513. The common layer 514 and the common electrode 513 are shared by the light-emitting elements 510R, 510G, and 510B. Note that the pixel electrodes 511R, 511G, and 511B are collectively referred to as a pixel electrode 511 in some cases.

The organic layer 512R included in the light-emitting element 510R contains at least a light-emitting organic compound that emits red light. The organic layer 512G included in the light-emitting element 510G contains at least a light-emitting organic compound that emits green light. The organic layer 512B included in the light-emitting element 510B contains at least a light-emitting organic compound that emits blue light. Each of the organic layers 512R, 512G, and 512B can also be referred to as an EL layer and includes at least a layer containing a light-emitting substance (a light-emitting layer).

In the display device 500A, since the light-emitting devices of different colors are separately formed, a change in chromaticity between light emission at low luminance and light emission at high luminance is small. Furthermore, since the organic layers 512R, 512G, and 512B are separated from each other, crosstalk generated between adjacent subpixels can be inhibited while the display panel has high resolution. It is thus possible to achieve a display panel that has high resolution and high display quality.

In a region between adjacent light-emitting elements, an insulating layer 525, a resin layer 526, and a layer 528 are provided.

The pixel electrodes 511R, 511G, and 511B are each electrically connected to the conductive layer 355 of the transistor 320 through a plug 556 that is embedded in the insulating layers 555a, 555b, and 555c, the conductive layer 541 that is embedded in the insulating layer 554, and the plug 574. The top surface of the insulating layer 555c and the top surface of the plug 556 are level with each other. A variety of conductive materials can be used for the plugs.

A protective layer 521 is provided over the light-emitting elements 510R, 510G, and 510B. A substrate 530 is attached onto the protective layer 521 with an adhesive layer 531.

An insulating layer covering an end portion of the top surface of the pixel electrode 511 is not provided between two adjacent pixel electrodes 511. Thus, the distance between adjacent light-emitting elements can be extremely narrowed. Accordingly, the display device can have high resolution or high definition.

At least part of this embodiment can be implemented as appropriate in combination with any of the other embodiments described in this specification.

### Embodiment 6

This embodiment will describe structure examples of pixel circuits usable in the display device of one embodiment of the present invention.

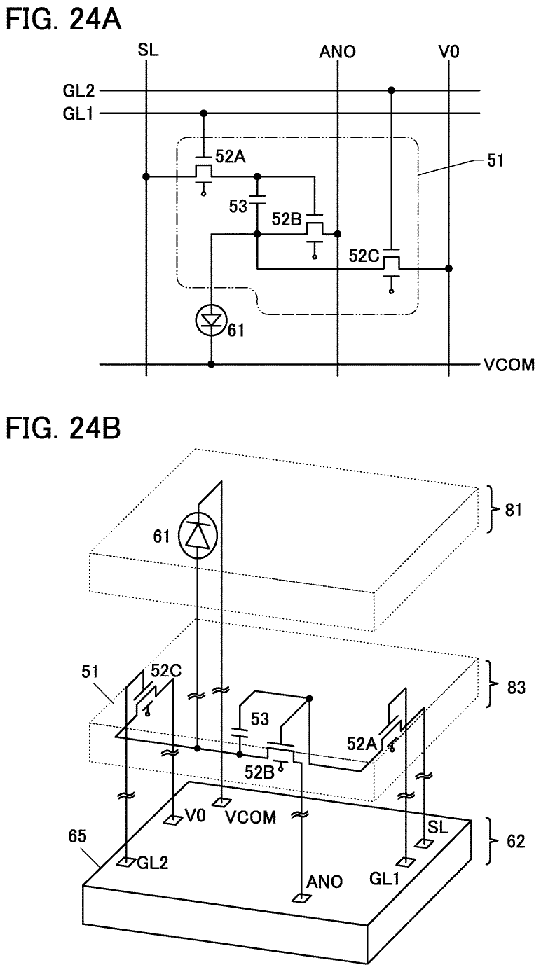

FIGS. 24A and 24B illustrate a structure example of a pixel circuit 51 and a light-emitting device 61 connected to the pixel circuit 51. In the display device, one pixel can include at least one pixel circuit 51 and one light-emitting device 61. Furthermore, when one pixel is composed of three subpixels (a red-light-emitting subpixel, a green-light-emitting subpixel, and a blue-light-emitting subpixel), each of which includes one pixel circuit 51 and one light-emitting device 61, the display device can perform full-color display.

FIG. 24A illustrates a structure example of the pixel circuit 51. FIG. 24B schematically illustrates the vertical relation between an element layer 62 including a peripheral driver circuit 65 including a scan line driver circuit, an image signal line driver circuit, and the like; an element layer 83 including a plurality of transistors of the pixel circuit 51; and an element layer 81 including the light-emitting device 61.

The pixel circuit 51 illustrated as an example in FIGS. 24A and 24B includes a transistor 52A, a transistor 52B, a transistor 52C, and a capacitor 53. The transistors 52A to 52C can be OS transistors. The transistors 52A to 52C, which are OS transistors, each preferably include a back gate, in which case the back gate and a gate can be supplied with the same signals or different signals.

A gate of the transistor 52A is connected to a wiring GL1, one of a source and a drain of the transistor 52A is connected to a wiring SL, and the other of the source and the drain of the transistor 52A is connected to a gate of the transistor 52B and one electrode of the capacitor 53. The wiring SL is supplied with an image signal. The conduction state (also referred to as “on state”) and non-conduction state (also referred to as “off state”) of the transistor 52A are controlled in accordance with the potential of the wiring GL1.

One of a source and a drain of the transistor 52B is connected to a wiring ANO, and the other of the source and the drain of the transistor 52B is connected to one of a source and a drain of the transistor 52C, the other electrode of the capacitor 53, and an anode of the light-emitting device 61. The transistor 52B has a function of controlling the amount of current flowing through the light-emitting device 61. That is, the transistor 52B has a function of controlling the amount of light emitted from the light-emitting device 61. Thus, the transistor 52B can be referred to as a driving transistor.

The pixel circuit 51 can control the intensity of light emitted from the light-emitting device 61 in accordance with an image signal supplied to the gate of the transistor 52B. Furthermore, a variation in the gate-source voltage of the transistor 52B can be reduced by the reference potential of a wiring V0 supplied through the transistor 52C.

A gate of the transistor 52C is connected to a wiring GL2, and the other of the source and the drain of the transistor 52C is connected to the wiring V0. The on and off states of the transistor 52C are controlled in accordance with the potential of the wiring GL2.

A cathode of the light-emitting device 61 is connected to a wiring VCOM. The wiring ANO supplies a potential for supplying current to the light-emitting device 61. The wiring VCOM is supplied with a potential lower than the potential supplied to the wiring ANO.

The wiring V0 is a wiring for supplying the reference potential to the pixel circuit 51. The wiring V0 can be used as a wiring for outputting current flowing through the pixel circuit 51 to the peripheral driver circuit 65 or a functional circuit that is formed in the element layer 62. A current value usable for setting pixel parameters can be output through the wiring V0, for example. Specifically, the wiring V0 can function as a monitor line for outputting current flowing through the transistor 52B or current flowing through the light-emitting device 61 to the outside. Current output to the wiring V0 is converted into voltage by a source follower circuit or the like, and the voltage is output to the outside. Alternatively, current output to the wiring V0 can be converted into a digital signal by an A-D converter or the like and the digital signal can be output to the functional circuit or the like formed in the element layer 62.

A light-emitting device described in one embodiment of the present invention refers to a self-luminous display element such as an organic EL element (also referred to as an organic light-emitting diode (OLED)). Note that the light-emitting device connected to a pixel circuit can be a self-luminous light-emitting device such as a light-emitting diode (LED), a micro LED, a quantum-dot light-emitting diode (QLED), or a semiconductor laser.

As illustrated in FIG. 24B, the element layers 62, 83, and 81 can be provided to overlap with each other. When the element layers 62 and 83 are provided to overlap with each other, a wiring for connecting the pixel circuit 51 and the peripheral driver circuit 65 can be shortened. Thus, the wiring resistance of the wiring can be reduced. The reduction in wiring resistance enables high-speed data writing, leading to high-speed operation of the display device. Therefore, even when the display device includes a large number of pixel circuits 51, a sufficiently long frame period can be ensured and thus the pixel density of the display device can be increased. In addition, the increased pixel density of the display device can increase the resolution of an image displayed by the display device. For example, the pixel density of the display device can be 1000 ppi or higher, 5000 ppi or higher, or 7000 ppi or higher. Thus, the display device of this embodiment can be, for example, a display device for AR or VR and can be suitably used in an electronic apparatus with a short distance between the display portion and the user, such as an HMD.

Although FIGS. 24A and 24B illustrate, as an example, the pixel circuit 51 including three transistors in total, one embodiment of the present invention is not limited thereto. Structure examples of pixel circuits usable as the pixel circuit 51 will be described below.

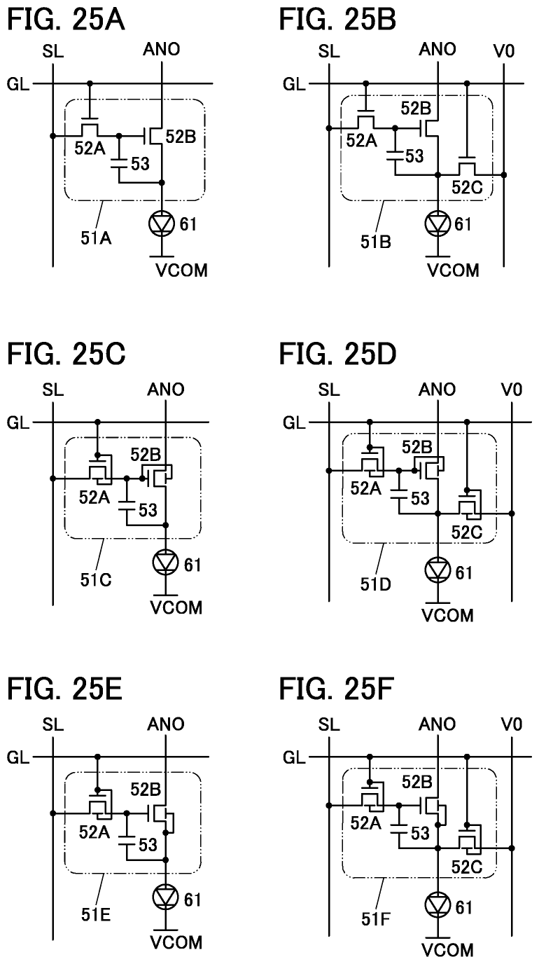

A pixel circuit 51A illustrated in FIG. 25A includes the transistor 52A, the transistor 52B, and the capacitor 53. FIG. 25A also illustrates the light-emitting device 61 connected to the pixel circuit 51A. The wirings SL, ANO, and VCOM and a wiring GL are connected to the pixel circuit 51A. The pixel circuit 51A has a structure where the transistor 52C is removed from the pixel circuit 51 illustrated in FIG. 24A and the wirings GL1 and GL2 in FIG. 24A are replaced with the wiring GL.

The gate of the transistor 52A is connected to the wiring GL, one of the source and the drain of the transistor 52A is connected to the wiring SL, and the other of the source and the drain of the transistor 52A is connected to the gate of the transistor 52B and one electrode of the capacitor 53. One of the source and the drain of the transistor 52B is connected to the wiring ANO, and the other of the source and the drain of the transistor 52B is connected to the anode of the light-emitting device 61. The other electrode of the capacitor 53 is connected to the anode of the light-emitting device 61. The cathode of the light-emitting device 61 is connected to the wiring VCOM.

A pixel circuit 51B illustrated in FIG. 25B has a structure where the transistor 52C is added to the pixel circuit 51A. The pixel circuit 51B has a structure similar to that of the pixel circuit 51 illustrated in FIG. 24A but is different from the pixel circuit 51 in that the gate of the transistor 52C is connected to the wiring GL.

A pixel circuit 51C illustrated in FIG. 25C and a pixel circuit 51E illustrated in FIG. 25E are each an example of the case where a transistor including a back gate is used for the pixel circuit 51A. A pixel circuit 51D illustrated in FIG. 25D and a pixel circuit 51F illustrated in FIG. 25F are each an example of the case where a transistor including a back gate is used for the pixel circuit 51B.

In the examples illustrated in FIGS. 25C to 25F, transistors each including a back gate are used as the transistors 52A to 52C. In the examples illustrated in FIGS. 25C and 25D, the gate and the back gate are connected to each other in each of the transistors 52A to 52C. This can increase the on-state current (current flowing between the source and the drain when the transistor is in an on state) of the transistor.

As in the transistor 52B illustrated in FIGS. 25E and 25F, the back gate can be connected to the other of the source and the drain. When the back gate is connected to the source or the drain that mainly functions as a source, the transistor can operate stably and have high reliability.

Although a transistor including a back gate is used for all the transistors in the above example, the present invention is not limited thereto. It is also possible to use a transistor including a back gate for some of the transistors as needed. The same applies to all the pixel circuits disclosed in this embodiment and the like.

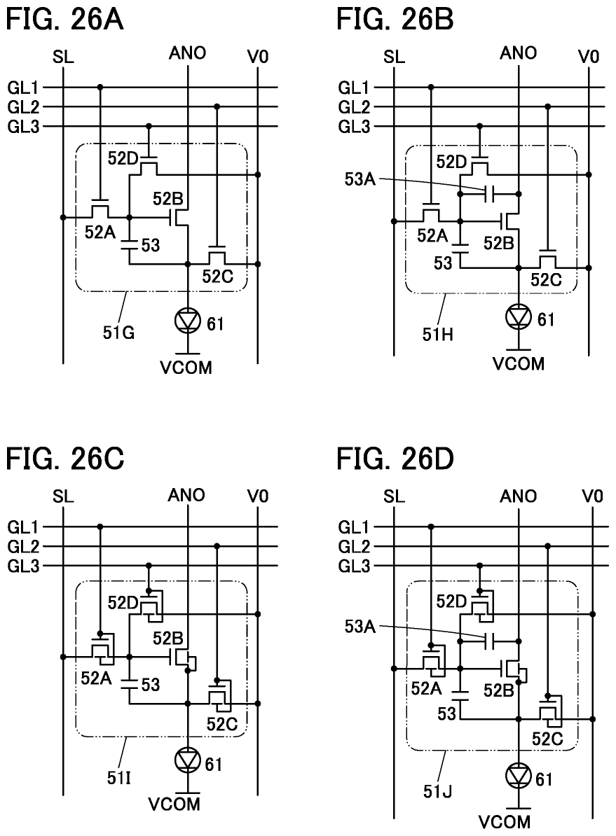

A pixel circuit 51G illustrated in FIG. 26A has a structure where a transistor 52D is added to the pixel circuit 51B. The wiring GL1, the wiring GL2, and a wiring GL3 functioning as gate lines are connected to the pixel circuit 51G. In this embodiment and the like, the wirings GL1 to GL3 are collectively referred to as the wiring GL in some cases. Thus, the wiring GL may be one wiring or a plurality of wirings.

A gate of the transistor 52D is connected to the wiring GL3, and one of a source and a drain of the transistor 52D is connected to the gate of the transistor 52B, the other of the source and the drain of the transistor 52A, and one electrode of the capacitor 53. The other of the source and the drain of the transistor 52D is connected to the wiring V0. The gate of the transistor 52A is connected to the wiring GL1, and the gate of the transistor 52C is connected to the wiring GL2.

When the transistors 52C and 52D are turned on at the same time, the other of the source and the drain and the gate of the transistor 52B have the same potential, so that the transistor 52B can be turned off. Thus, current flowing to the light-emitting device 61 can be blocked forcibly. Such a pixel circuit is suitable for using a display method in which display periods and non-lighting periods are alternately provided to suppress generation of an afterimage at the time of displaying a moving image (such a display method is also referred to as “black insertion driving”, “duty driving”, or “time division driving”).

A pixel circuit 51H illustrated in FIG. 26B is an example in which a capacitor 53A is added to the pixel circuit 51G. One electrode of the capacitor 53A is connected to the gate of the transistor 52B, the other of the source and the drain of the transistor 52A, one of the source and the drain of the transistor 52D, and one electrode of the capacitor 53. The capacitor 53A functions as a storage capacitor.

A pixel circuit 51I illustrated in FIG. 26C is an example of the case where a transistor including a back gate is used for the pixel circuit 51G. A pixel circuit 51J illustrated in FIG. 26D is an example of the case where a transistor including a back gate is used for the pixel circuit 51H. In FIGS. 26C and 26D, the gate and the back gate are connected to each other in each of the transistors 52A, 52C, and 52D, and the other of the source and the drain and the back gate are connected to each other in the transistor 52B.

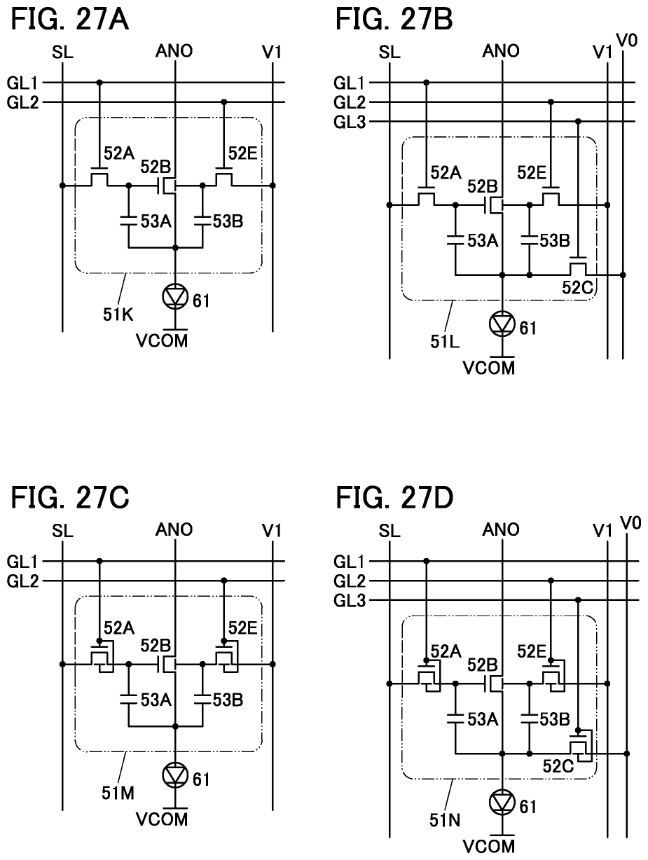

A pixel circuit 51K illustrated in FIG. 27A is capable of obtaining the threshold voltage (also referred to as “Vth”) of the transistor 52B and correcting the Vth of the transistor 52B to 0 V. Thus, a variation in Vths of the transistors 52B between a plurality of pixel circuits can be reduced. Consequently, the display quality of a display device including the pixel circuit can be increased.

The pixel circuit 51K includes the transistor 52A, the transistor 52B, a transistor 52E, the capacitor 53A, and a capacitor 53B. A transistor including aback gate is used as the transistor 52B.

In the pixel circuit 51K, the gate of the transistor 52A is connected to the wiring GL1, one of the source and the drain of the transistor 52A is connected to the wiring SL, and the other of the source and the drain of the transistor 52A is connected to the gate of the transistor 52B and one electrode of the capacitor 53A. One of the source and the drain of the transistor 52B is connected to the wiring ANO, and the other of the source and the drain of the transistor 52B is connected to the anode of the light-emitting device 61 and the other electrode of the capacitor 53A. The back gate of the transistor 52B is connected to one electrode of the capacitor 53B and one of a source and a drain of the transistor 52E. The other of the source and the drain of the transistor 52E is connected to a wiring V1. A gate of the transistor 52E is connected to the wiring GL2.

The on and off states of the transistor 52E are controlled in accordance with the potential of the wiring GL2. The wiring V1 is supplied with a potential for performing initialization operation at the time of obtaining the Vth of the transistor 52B.

The other electrode of the capacitor 53A and the other electrode of the capacitor 53B are connected to the anode of the light-emitting device 61. The cathode of the light-emitting device 61 is connected to the wiring VCOM.

A pixel circuit 51L illustrated in FIG. 27B is an example in which the transistor 52C is added to the pixel circuit 51K. One of the source and the drain of the transistor 52C is connected to the other of the source and the drain of the transistor 52B, the other electrode of the capacitor 53A, the other electrode of the capacitor 53B, and the anode of the light-emitting device 61. In the pixel circuit 51L, the gate of the transistor 52C is connected to the wiring GL3, and the other of the source and the drain of the transistor 52C is connected to the wiring V0. Thus, the on and off states of the transistor 52C are controlled in accordance with the potential of the wiring GL3.

A pixel circuit 51M illustrated in FIG. 27C is an example in which a transistor including aback gate is used as each of the transistors 52A and 52E of the pixel circuit 51K. A pixel circuit 51N illustrated in FIG. 27D is an example in which a transistor including a back gate is used as each of the transistors 52A, 52C, and 52E of the pixel circuit 51L. In FIGS. 27C and 27D, the back gate and the gate are connected to each other in each of the transistors 52A, 52C, and 52E.

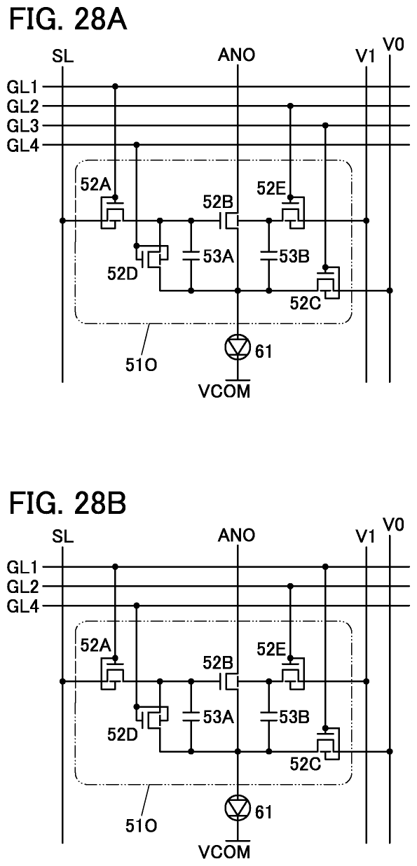

A pixel circuit 51O illustrated in FIG. 28A is an example in which the transistor 52D is added to the pixel circuit 51N. The gate of the transistor 52D is connected to a wiring GL4, one of the source and the drain of the transistor 52D is connected to the gate of the transistor 52B, the other of the source and the drain of the transistor 52A, and one electrode of the capacitor 53A, and the other of the source and the drain of the transistor 52D is connected to the other of the source and the drain of the transistor 52B, one of the source and the drain of the transistor 52C, the other electrode of the capacitor 53A, the other electrode of the capacitor 53B, and the anode of the light-emitting device 61.

The on and off states of the transistor 52D are controlled in accordance with the potential of the wiring GL4. The transistor 52D is turned on at the time of obtaining the Vth of the transistor 52B and correcting the Vth to 0 V, whereby the Vth of the transistor 52B can be corrected more accurately.

Alternatively, as illustrated in FIG. 28B, the gate of the transistor 52C can be connected to the wiring GL1. In this case, the on and off states of the transistors 52A and 52C are controlled in accordance with the potential of the wiring GL1. In addition, both of the gate of the transistor 52A and the gate of the transistor 52C are connected to the wiring GL1, so that the wiring GL3 can be omitted.

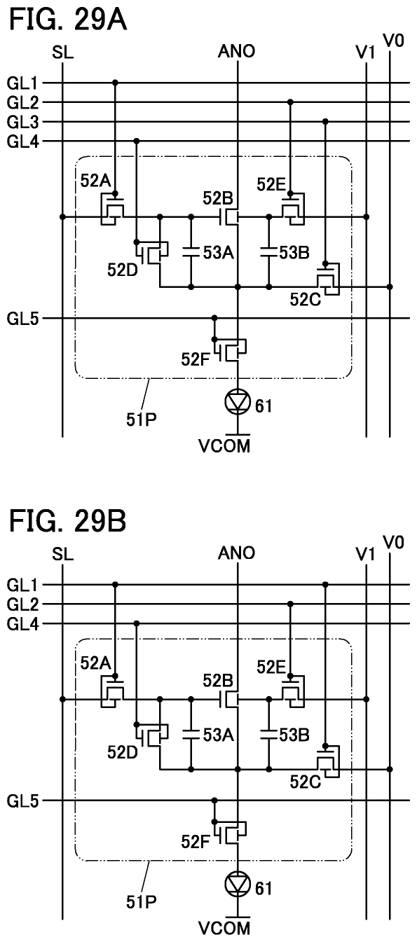

A pixel circuit 51P illustrated in FIG. 29A is a structure example in which a transistor 52F is added to the pixel circuit 51O. The transistor 52F is provided between the other of the source and the drain of the transistor 52B and the anode of the light-emitting device 61. Specifically, one of a source and a drain of the transistor 52F is connected to the other of the source and the drain of the transistor 52B, one of the source and the drain of the transistor 52C, the other of the source and the drain of the transistor 52D, the other electrode of the capacitor 53A, and the other electrode of the capacitor 53B. The other of the source and the drain of the transistor 52F is connected to the anode of the light-emitting device 61. A gate and a back gate of the transistor 52F are connected to a wiring GL5. The on and off states of the transistor 52F are controlled in accordance with the potential of the wiring GL5.

Provision of the transistor 52F enables light emission by the light-emitting device 61 to be stopped in a given period without changing the gate potential of the transistor 52B. Provision of the transistor 52F facilitates adjustment of a light-emitting period and a quenching period in time division driving. Consequently, the display quality of the display device can be improved.

As illustrated in FIG. 29B, the wiring GL3 can be omitted in the pixel circuit 51P as in the pixel circuit 51O illustrated in FIG. 28B.

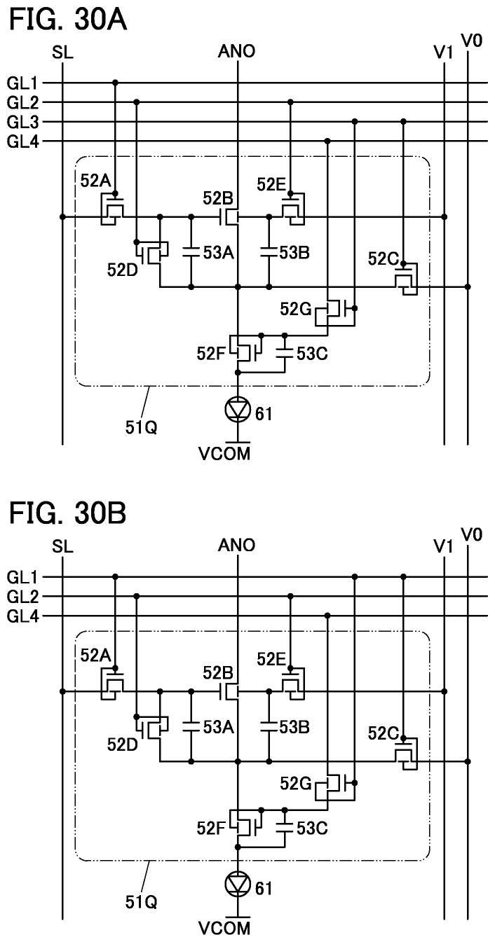

A pixel circuit 51Q illustrated in FIG. 30A is a structure example in which a transistor 52G and a capacitor 53C are added to the pixel circuit 51P. A gate and a back gate of the transistor 52G are connected to the wiring GL3, one of a source and a drain of the transistor 52G is connected to the wiring GL4, and the other of the source and the drain of the transistor 52G is connected to the gate and the back gate of the transistor 52F and one electrode of the capacitor 53C. The other electrode of the capacitor 53C is connected to the other of the source and the drain of the transistor 52F and the anode of the light-emitting device 61.

The other of the source and the drain of the transistor 52F mainly functions as a source. When the transistor 52F is turned on and current flows to the light-emitting device 61, the potential of the anode increases in accordance with the amount of current. That is, the source potential of the transistor 52F increases. In the case where the wiring GL5 has a constant potential in the pixel circuit 51P, an increase in the source potential of the transistor 52F reduces the potential difference between the gate and source (also referred to as “Vgs”) of the transistor 52F. When the Vgs decreases, the on-state current of the transistor 52F decreases. Therefore, an increase in the emission luminance of the light-emitting device 61 makes it difficult to achieve light emission at a luminance corresponding to an image signal.

In the structure of the pixel circuit 51Q, by turning off the transistor 52G, the gate of the transistor 52F can be brought into a floating state. The capacitor 53C is provided between the other of the source and the drain and the gate of the transistor 52F, so that the other of the source and the drain and the gate are capacitively coupled with each other. In the circuit structure of the pixel circuit 51Q, by turning on the transistor 52F and then bringing its gate into a floating state, the gate potential of the transistor 52F can be increased in accordance with an increase in the source potential. Thus, the light-emitting device 61 can emit light at a luminance corresponding to an image signal. The capacitor 53C functions as a bootstrap capacitor.

As illustrated in FIG. 30B, the wiring GL3 can be omitted in the pixel circuit 51Q as in the pixel circuit 51O illustrated in FIG. 28B.

In each of the pixel circuits 51A to 51Q, the capacitor 53A retains charge corresponding to an image signal, and the capacitor 53B retains charge for correcting the Vth of the transistor 52B to 0 V. A change in charge retained in each of the capacitors 53A and 53B greatly affects the display quality of the display device. Therefore, the influence of external noise is preferably small. When the capacitors 53A and 53B each have a large capacitance, the influence of external noise can be reduced, so that a display device with high display quality can be provided.

The capacitors 53A and 53B each preferably retain charge in a period longer than one frame period, preferably longer than or equal to 1 second, further preferably longer than or equal to 1 minute, still further preferably longer than or equal to 1 hour. In the pixel circuit 51Q, the capacitor 53C may have a smaller capacitance than the capacitors 53A and 53B as long as the capacitor 53C can retain voltage that can adequately make the transistor 52F in an on state.

As the transistors included in the pixel circuits 51A to 51Q, OS transistors are preferably used. Since the off-state current of an OS transistor is extremely low, charge supplied to the capacitors 53A to 53C can be retained for a long time. For example, in the case of displaying a still image for which rewriting every frame is not required, displaying an image can be kept even when the operation of a peripheral driver circuit is stopped. Such a driving method in which the operation of a peripheral driver circuit is stopped during displaying a still image is also referred to as “idling stop driving”. Power consumption of the display device can be reduced by performing idling stop driving.

An OS transistor has a high withstand voltage between its source and drain. For example, in the case where a tandem light-emitting device is used as the light-emitting device 61, a high voltage is applied to the light-emitting device 61. Thus, an OS transistor is suitable as the transistor included in the pixel circuit. In addition, an OS transistor has favorable saturation characteristics and small hysteresis of electrical characteristics. Therefore, an OS transistor is particularly suitable as the transistor 52B.

The transistor 52B functioning as a driving transistor is required to have a high on-state current. An OS transistor in which indium oxide having crystallinity is used for a semiconductor layer where a channel is formed has a high on-state current and thus is suitable as the transistor 52B.

It is also possible to use multi-channel transistors (also referred to as “multi-gate transistors”) as the transistors included in the pixel circuits 51A to 51Q. A multi-channel transistor includes a plurality of gates connected to each other and includes, between a source and a drain, a plurality of regions where a semiconductor layer and the gates overlap with each other. That is, a multi-channel transistor includes a plurality of gates connected to each other and a plurality of channel formation regions between a source and a drain. A multi-channel transistor can also be regarded as a transistor in which a plurality of single-gate transistors are connected in series such that gates of the transistor are connected to each other.

A multi-channel transistor is equivalent to a transistor having a long channel length. Thus, a multi-channel transistor has more favorable electrical characteristics in a saturation region (also referred to as “saturation characteristics”) than a single-gate transistor. For example, in the case where a driving transistor or the like operates in a saturation region, the channel length of the transistor may be increased to improve its electrical characteristics in the saturation region. A multi-channel transistor can be used as a transistor having a long channel length. Moreover, a multi-channel transistor can have a lower off-state current than a single-gate transistor.

At least part of this embodiment can be implemented as appropriate in combination with any of the other embodiments described in this specification.

### Embodiment 7

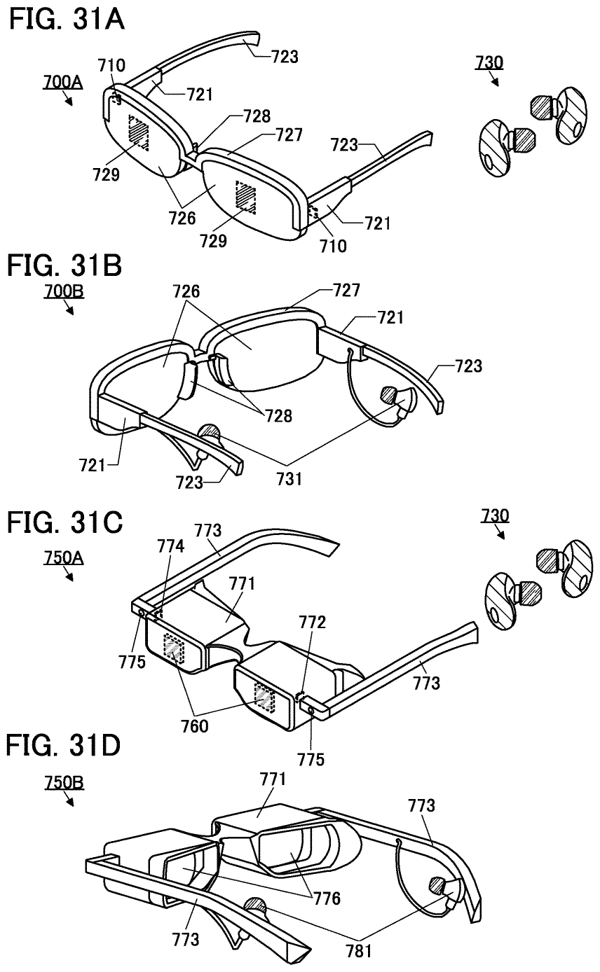

In this embodiment, electronic apparatuses of one embodiment of the present invention will be described with reference to FIGS. 31A to 31D, FIGS. 32A to 32F, and FIGS. 33A to 33G.

Electronic apparatuses in this embodiment each include a display panel (display device) employing the transistor of one embodiment of the present invention in a display portion. The display device of one embodiment of the present invention can easily achieve higher resolution and definition and can achieve high display quality. Thus, the display device of one embodiment of the present invention can be used for display portions of a variety of electronic apparatuses.

Examples of the electronic apparatuses include a digital camera, a digital video camera, a digital photo frame, a cellular phone, a portable game machine, a portable information terminal, and an audio reproducing device, in addition to electronic apparatuses with comparatively large screens, such as a television device, a desktop or laptop computer, a monitor for a computer or the like, digital signage, and a large game machine such as a pachinko machine.

In particular, the display panel of one embodiment of the present invention can have higher resolution, and thus is suitable for an electronic apparatus having a comparatively small display portion. Examples of such an electronic apparatus include wristwatch-type and bracelet-type information terminal devices (wearable devices) and a wearable device that can be worn on a head, such as a device for VR such as a head-mounted display, a glasses-type device for AR, or a device for mixed reality (MR).

The definition of the display panel of one embodiment of the present invention is preferably as high as HD (pixel count: 1280×720), FHD (pixel count: 1920×1080), WQHD (pixel count: 2560×1440), WQXGA (pixel count: 2560×1600), 4K (pixel count: 3840×2160), or 8K (pixel count: 7680×4320). In particular, the definition of 4K, 8K, or higher is preferable. In addition, the pixel density (resolution) of the display panel of one embodiment of the present invention is preferably higher than or equal to 100 ppi, further preferably higher than or equal to 300 ppi, still further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the use of such a display panel with one or both of high definition and high resolution, realistic sensation, sense of depth, and the like can be further increased. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic apparatus in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays).

The electronic apparatus in this embodiment can have a variety of functions. For example, the electronic apparatus can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices that can be worn on a head are described with reference to FIGS. 31A to 31D. These wearable devices have one or both of a function of displaying AR contents and a function of displaying VR contents. Note that the wearable devices may have a function of displaying substitutional reality (SR) or MR contents, in addition to AR and VR contents. The electronic apparatus having a function of displaying contents of at least one of AR, VR, SR, MR, and the like enables the user to feel a higher sense of immersion.

An electronic apparatus 700A illustrated in FIG. 31A and an electronic apparatus 700B illustrated in FIG. 31B each include a pair of display panels 710, a pair of housings 721, a communication portion (not illustrated), a pair of wearing portions 723, a control portion (not illustrated), an imaging portion (not illustrated), a pair of optical members 726, a frame 727, and a pair of nose pads 728.

The display panel of one embodiment of the present invention can be employed for the display panel 710. Thus, the electronic apparatus can perform display with extremely high resolution.

The electronic apparatus 700A and the electronic apparatus 700B can each project images displayed on the display panels 710 onto display regions 729 of the optical members 726. Since the optical members 726 have a light-transmitting property, the user can see images displayed on the display regions that are superimposed on transmission images seen through the optical members 726. Thus, the electronic apparatus 700A and the electronic apparatus 700B are electronic apparatuses capable of AR display.

In each of the electronic apparatus 700A and the electronic apparatus 700B, a camera capable of capturing images of the front side may be provided as the imaging portion.

Furthermore, when each of the electronic apparatus 700A and the electronic apparatus 700B is provided with an acceleration sensor such as a gyroscope sensor, the orientation of a user's head can be sensed and an image corresponding to the orientation can be displayed on the display region 729.

The communication portion includes a wireless communication device, and a video signal and the like can be supplied by the wireless communication device. Note that instead of or in addition to the wireless communication device, a connector to which a cable supplied with a video signal and a power supply potential can be connected may be provided.

Each of the electronic apparatuses 700A and 700B is provided with a battery (not illustrated) so that charging can be performed wirelessly and/or by wire.

A touch sensor module may be provided in the housing 721. The touch sensor module has a function of detecting a touch on an outer surface of the housing 721. A tap operation, a slide operation, or the like by the user can be detected with the touch sensor module, so that a variety of processing can be executed. For example, processing such as a pause or a restart of a moving image can be executed by a tap operation, and processing such as fast forward or fast rewind can be executed by a slide operation. When the touch sensor module is provided in each of the two housings 721, the range of the operation can be increased.

A variety of touch sensors can be employed for the touch sensor module. For example, touch sensors of a variety of types such as a capacitive type, a resistive film type, an infrared type, an electromagnetic induction type, a surface acoustic wave type, and an optical type can be employed. In particular, a capacitive sensor or an optical sensor is preferably employed for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic apparatus 750A illustrated in FIG. 31C and an electronic apparatus 750B illustrated in FIG. 31D each include a pair of display portions 760, a housing 771, a communication portion 772, a pair of wearing portions 773, a control portion 774, a pair of imaging portions 775, and a pair of lenses 776.

The display panel of one embodiment of the present invention can be employed for the display portion 760. Thus, the electronic apparatus can perform display with extremely high resolution. This enables the user to feel a high sense of immersion.

The display portions 760 are positioned inside the housing 771 to be seen through the lenses 776. Furthermore, when the pair of display portions 760 display different images, 3D display using parallax can be also performed.

The electronic apparatuses 750A and 750B can be regarded as electronic apparatuses for VR. The user who wears the electronic apparatus 750A or 750B can see images displayed on the display portions 760 through the lenses 776.

The electronic apparatuses 750A and 750B each preferably include a mechanism for adjusting the lateral positions of the lenses 776 and the display portions 760 so that the lenses 776 and the display portions 760 are positioned optimally in accordance with the positions of the user's eyes. In addition, the electronic apparatuses 750A and 750B preferably include a mechanism for adjusting focus by changing the distance between the lenses 776 and the display portions 760.

The electronic apparatus 750A or 750B can be worn on the user's head with the wearing portions 773. Note that FIG. 31C and the like illustrate examples where the wearing portion 773 has a shape like a temple of glasses; however, one embodiment of the present invention is not limited thereto. The wearing portion 773 can have any shape with which the user can wear and can have a shape of a helmet or a band, for example.

The imaging portion 775 has a function of obtaining external information. Data obtained by the imaging portion 775 can be output to the display portion 760. An image sensor can be used for the imaging portion 775. Moreover, a plurality of cameras may be provided to support a plurality of fields of view, such as a telescope field of view and a wide field of view.

Although an example of including the imaging portion 775 is shown here, a range sensor (hereinafter also referred to as a sensing portion) capable of measuring the distance between the user and an object just needs to be provided. That is, the imaging portion 775 is one embodiment of the sensing portion. For the sensing portion, an image sensor or a distance image sensor such as a light detection and ranging (LiDAR) sensor can be used, for example. By using images obtained by the camera and images obtained by the distance image sensor, more information can be obtained and a gesture operation with higher accuracy is possible.

The electronic apparatus 750A may include a vibration mechanism that functions as bone-conduction earphones. For example, any one or more of the display portion 760, the housing 771, and the wearing portion 773 can include the vibration mechanism. Thus, without additionally requiring an audio device such as headphones, earphones, or a speaker, the user can enjoy a video and sound only by wearing the electronic apparatus 750A.

The electronic apparatuses 750A and 750B may each include an input terminal. To the input terminal, a cable for supplying a video signal from a video output device or the like, power for charging a battery provided in the electronic apparatus, and the like can be connected.

An electronic apparatus of one embodiment of the present invention may have a function of performing wireless communication with earphones 730. The earphones 730 include a communication portion (not illustrated) and have a wireless communication function. The earphones 730 can receive information (e.g., audio data) from the electronic apparatus with the wireless communication function. For example, the electronic apparatus 700A illustrated in FIG. 31A has a function of transmitting information to the earphones 730 with the wireless communication function. As another example, the electronic apparatus 750A illustrated in FIG. 31C has a function of transmitting information to the earphones 730 with the wireless communication function.

The electronic apparatus may include an earphone portion. The electronic apparatus 700B illustrated in FIG. 31B includes earphone portions 731. For example, a structure in which the earphone portions 731 and the control portion are connected to each other by wire can be employed. Part of a wiring that connects the earphone portions 731 and the control portion may be positioned inside the housing 721 or the wearing portion 723.

Similarly, the electronic apparatus 750B illustrated in FIG. 31D includes earphone portions 781. For example, the earphone portions 781 and the control portion 774 can be connected to each other by wire. Part of a wiring that connects the earphone portions 781 and the control portion 774 may be positioned inside the housing 771 or the wearing portion 773. Alternatively, the earphone portions 781 and the wearing portions 773 may include magnets. This is preferred because the earphone portions 781 can be fixed to the wearing portions 773 with magnetic force and thus can be easily housed.

Note that the electronic apparatus may include an audio output terminal to which earphones, headphones, or the like can be connected. The electronic apparatus may include one or both of an audio input terminal and an audio input mechanism. As the audio input mechanism, a sound collecting device such as a microphone can be used, for example. The electronic apparatus may have a function of what is called a headset by including the audio input mechanism.

As described above, both the glasses-type device (e.g., the electronic apparatuses 700A and 700B) and the goggles-type device (e.g., the electronic apparatuses 750A and 750B) are suitable for the electronic apparatus of one embodiment of the present invention.

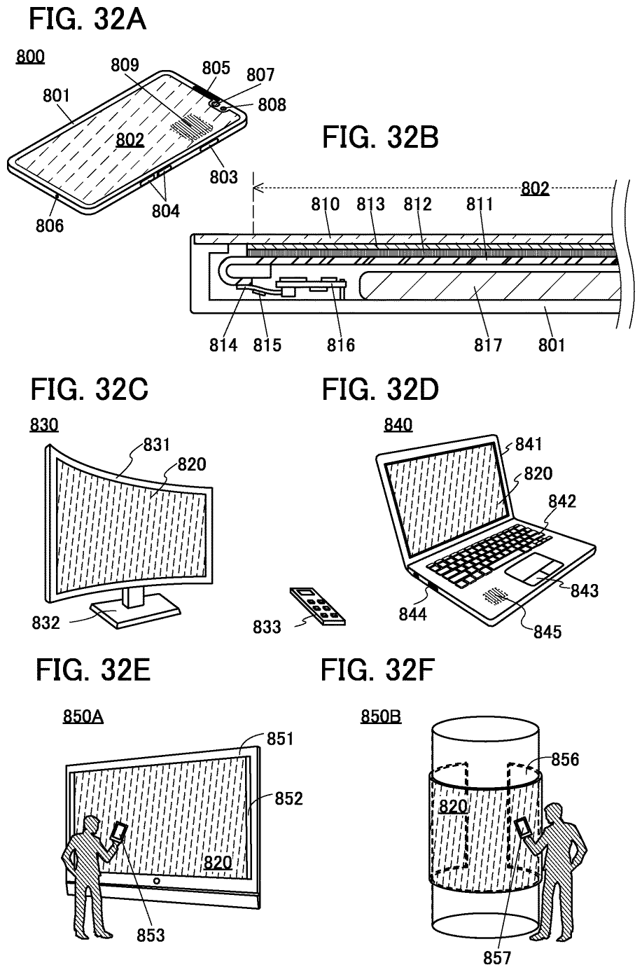

An electronic apparatus 800 illustrated in FIG. 32A is a portable information terminal device usable as a smartphone.

The electronic apparatus 800 includes a housing 801, a display portion 802, a power button 803, buttons 804, a speaker 805, a microphone 806, a camera 807, a light source 808, a control device 809, and the like. The display portion 802 has a touch panel function. Note that one or more selected from a CPU, a graphics processing unit (GPU), and a memory device are included as the control device 809, for example. The semiconductor device of one embodiment of the present invention can be employed for the display portion 802, the control device 809, and the like. The semiconductor device of one embodiment of the present invention is suitably used for the control device 809 because power consumption can be reduced.

The display panel of one embodiment of the present invention can be employed for the display portion 802.

FIG. 32B is a schematic cross-sectional view including an end portion of the housing 801 on the microphone 806 side.

A protection member 810 having a light-transmitting property is provided on a display surface side of the housing 801, and a display panel 811, an optical member 812, a touch sensor panel 813, a printed circuit board 816, a battery 817, and the like are provided in a space surrounded by the housing 801 and the protection member 810.

The display panel 811, the optical member 812, and the touch sensor panel 813 are fixed to the protection member 810 with an adhesive layer (not illustrated).

Part of the display panel 811 is folded back in a region outside the display portion 802, and an FPC 814 is connected to the part that is folded back. An IC 815 is mounted on the FPC 814. The FPC 814 is connected to a terminal provided on the printed circuit board 816.

The display device of one embodiment of the present invention can be employed for the display panel 811. Thus, an extremely lightweight electronic apparatus can be achieved. In addition, since the display panel 811 is extremely thin, the battery 817 with high capacity can be mounted while the thickness of the electronic apparatus is reduced. Moreover, part of the display panel 811 is folded back so that a connection portion with the FPC 814 is provided on the back side of a pixel portion, so that an electronic apparatus with a narrow bezel can be achieved.

FIG. 32C illustrates an example of a television device. In a television device 830, a display portion 820 is incorporated in a housing 831. Here, a structure in which the housing 831 is supported by a stand 832 is illustrated.

Operation of the television device 830 illustrated in FIG. 32C can be performed with an operation switch provided in the housing 831 and a separate remote control 833. Alternatively, the display portion 820 may include a touch sensor, and the television device 830 may be operated by touch on the display portion 820 with a finger or the like. The remote control 833 may include a display portion for displaying information output from the remote control 833. With operation keys or a touch panel provided in the remote control 833, channels and volume can be controlled and a video displayed on the display portion 820 can be controlled.

Note that the television device 830 includes a receiver, a modem, and the like. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 32D illustrates an example of a laptop computer. A laptop computer 840 includes a housing 841, a keyboard 842, a pointing device 843, an external connection port 844, a control device 845, and the like. The display portion 820 is incorporated in the housing 841. One or more selected from a CPU, a GPU, and a memory device are included as the control device 845, for example. The semiconductor device of one embodiment of the present invention can be employed for the display portion 820, the control device 845, and the like. The semiconductor device of one embodiment of the present invention is suitably used for the control device 845 because power consumption can be reduced.

FIGS. 32E and 32F illustrate examples of digital signage.

Digital signage 850A illustrated in FIG. 32E includes a housing 851, the display portion 820, a speaker 852, and the like. Furthermore, the digital signage 850A can include an LED lamp, an operation key (including a power switch or an operation switch), a connection terminal, a variety of sensors, a microphone, and the like.

FIG. 32F is digital signage 850B attached to a cylindrical pillar 856. The digital signage 850B includes the display portion 820 provided along a curved surface of the pillar 856.

A larger display portion 820 can increase the amount of information that can be provided at a time. The larger display portion 820 attracts more attention, so that advertising effects can be increased, for example.

The use of a touch panel in the display portion 820 is preferable because in addition to display of an image or a moving image on the display portion 820, an intuitive operation by the user is possible. Moreover, for an application for providing information such as route information or traffic information, usability can be increased by an intuitive operation.

As illustrated in FIGS. 32E and 32F, it is preferable that the digital signage 850A or 850B can work with an information terminal device 853 or an information terminal device 857 such as a user's smartphone through wireless communication. For example, information of an advertisement displayed on the display portion 820 can be displayed on a screen of the information terminal device 853 or 857. Furthermore, by the operation of the information terminal device 853 or 857, display on the display portion 820 can be switched.

It is also possible to make the digital signage 850A or 850B execute a game with the use of the screen of the information terminal device 853 or 857 as an operation means (a controller). Thus, an unspecified number of users can join in and enjoy the game concurrently.

The display panel of one embodiment of the present invention can be employed for the display portion 820 illustrated in each of FIGS. 32C to 32F.

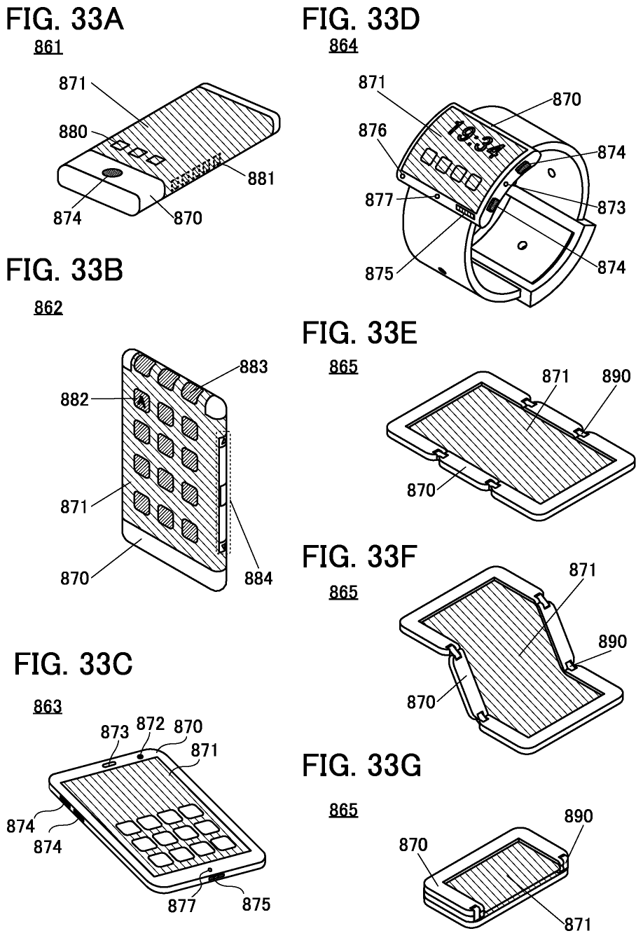

Electronic apparatuses illustrated in FIGS. 33A to 33G include a housing 870, a display portion 871, a camera 872, a speaker 873, an operation key 874 (including a power switch or an operation switch), a connection terminal 875, a sensor 876 (a sensor having a function of sensing, detecting, or measuring force, displacement, a position, speed, acceleration, angular velocity, rotational frequency, a distance, light, liquid, magnetism, temperature, a chemical substance, sound, time, hardness, an electric field, current, voltage, power, radiation, flow rate, humidity, a gradient, oscillation, an odor, or infrared rays), a microphone 877, and the like.

The electronic apparatuses illustrated in FIGS. 33A to 33G have a variety of functions. For example, the electronic apparatuses can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic apparatuses are not limited thereto, and the electronic apparatuses can have a variety of functions. The electronic apparatuses may include a plurality of display portions. In addition, the electronic apparatuses may each be provided with a camera or the like and have a function of taking a still image or a moving image and storing the taken image in a recording medium (an external recording medium or a recording medium incorporated in the camera), a function of displaying the taken image on the display portion, or the like.

The electronic apparatuses illustrated in FIGS. 33A to 33G are described in detail below.

FIG. 33A is a perspective view illustrating a portable information terminal 861. For example, the portable information terminal 861 can be used as a smartphone. Note that the portable information terminal 861 may be provided with the camera 872, the speaker 873, the connection terminal 875, the sensor 876, or the like. The portable information terminal 861 can display characters and image information on its plurality of surfaces. FIG. 33A illustrates an example in which three icons 880 are displayed. Furthermore, information 881 indicated by dashed rectangles can be displayed on another surface of the display portion 871. Examples of the information 881 include notification of incoming e-mails, SNS messages, calls, and the like, the titles and senders of e-mails, SNS messages, and the like, the date, the time, remaining battery, and radio field intensity. Alternatively, the icon 880 or the like may be displayed at the position where the information 881 is displayed.

FIG. 33B is a perspective view illustrating a portable information terminal 862. The portable information terminal 862 has a function of displaying information on three or more surfaces of the display portion 871. Here, an example in which information 882, information 883, and information 884 are displayed on different surfaces is shown. For example, the user can check the information 883 displayed such that it can be seen from above the portable information terminal 862, with the portable information terminal 862 put in a breast pocket of his/her clothes. The user can see display without taking out the portable information terminal 862 from the pocket and decide whether to answer a call, for example.

FIG. 33C is a perspective view illustrating a tablet terminal 863. The tablet terminal 863 is capable of executing a variety of applications such as mobile phone calls, e-mailing, viewing and editing texts, music reproduction, Internet communication, and a computer game, for example. The tablet terminal 863 includes the display portion 871, the camera 872, the speaker 873, and the microphone 877 on a front surface of the housing 870; the operation keys 874 as buttons for operations on a left side surface of the housing 870; and the connection terminal 875 on a bottom surface of the housing 870.

FIG. 33D is a perspective view illustrating a wristwatch-type portable information terminal 864. For example, the portable information terminal 864 can be used as a Smartwatch (registered trademark). A display surface of the display portion 871 is provided to be curved, and display can be performed along the curved display surface. Mutual communication between the portable information terminal 864 and, for example, a headset capable of wireless communication enables hands-free calling. With the connection terminal 875, the portable information terminal 864 can perform mutual data transmission with another information terminal and charging. Note that the charging operation may be performed by wireless power feeding.

FIGS. 33E to 33G are perspective views illustrating a foldable portable information terminal 865. FIG. 33E is a perspective view of the portable information terminal 865 that is opened, FIG. 33G is a perspective view of the portable information terminal 865 that is folded, and FIG. 33F is a perspective view of the portable information terminal 865 that is shifted from one of the states in FIGS. 33E and 33G to the other. The portable information terminal 865 is highly portable in the folded state and is highly browsable in the opened state because of a seamless large display region. The display portion 871 of the portable information terminal 865 is supported by three housings 870 joined together by hinges 890. For example, the display portion 871 can be bent with a radius of curvature greater than or equal to 0.1 mm and less than or equal to 150 mm.

At least part of this embodiment can be implemented as appropriate in combination with any of the other embodiments described in this specification.

### Embodiment 8

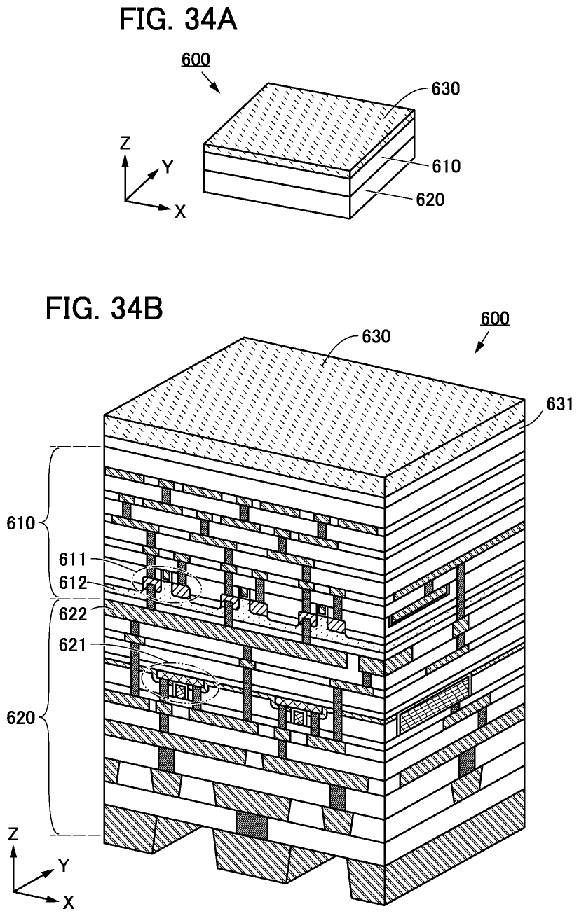

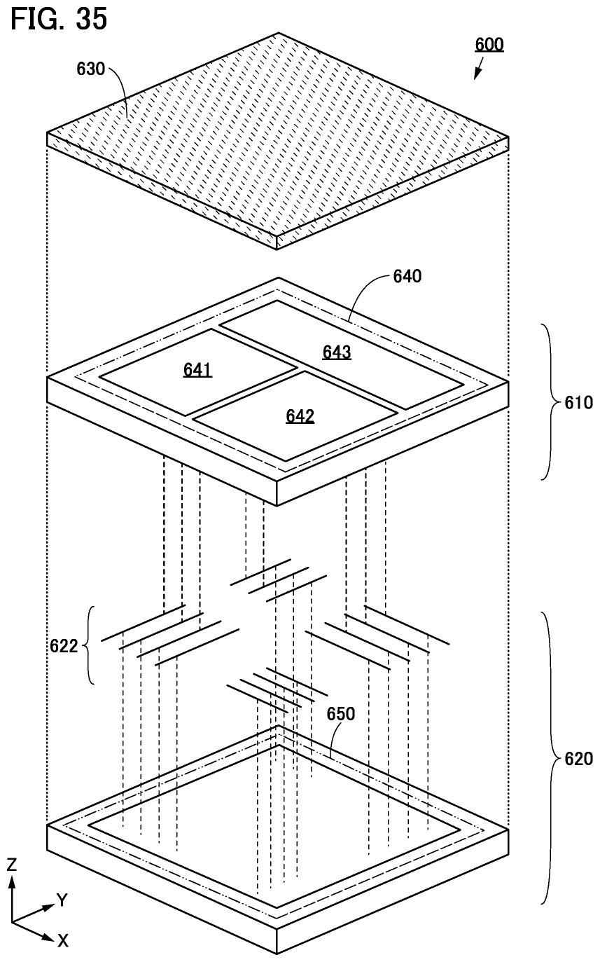

A semiconductor device of one embodiment of the present invention will be described. FIG. 34A is a schematic perspective view of a semiconductor device 600 of one embodiment of the present invention. FIG. 34B is a schematic perspective view of part of the semiconductor device 600. FIG. 35 is a schematic perspective view illustrating a structure of the semiconductor device 600.

In FIGS. 34A and 34B and FIG. 35, the semiconductor device 600 includes an element layer 620 under an element layer 610 including a substrate 612 that is a semiconductor substrate, and a support substrate 630 over the element layer 610 with an insulating layer 631 therebetween. The element layer 610 includes a plurality of transistors 611 included in a functional circuit 640. The element layer 620 includes a plurality of transistors 621 included in a switch circuit 650. The transistor 621 functions as a switch for controlling conduction and non-conduction between a line for supplying power from the outside and a conductive layer 622 functioning as a power supply line.

As the transistor 621, the transistor exemplified in Embodiment 2 can be used.

The transistor 611 included in the element layer 610 is formed on a surface (also referred to as a “first surface”) side of the substrate 612. The element layer 620 is formed on the rear surface (also referred to as a surface opposite to the surface or a “second surface”) side of the substrate 612. Thus, the transistor 621 included in the element layer 620 is formed on the second surface side of the substrate 612.

In FIG. 35, a CPU 641, a GPU 642, and a memory 643 are shown as examples of the functional circuit 640.

Note that the functional circuit 640 is not limited to the CPU 641, the GPU 642, and the memory 643, and one or more of these can be used. In addition, the functional circuit can include a circuit having other functions.

In order to realize an increase in operating speed, an increase in mounting density, and power saving of the semiconductor device 600, scaling down and thinning of a transistor, a wiring, and the like and a reduction in power supply potential are required for the functional circuit 640. The switch circuit 650 is capable of controlling whether to supply or stop voltage supplied from the outside to each circuit included in the functional circuit 640. Thus, supply of a power supply potential to a circuit in a standby state can be stopped, so that power consumption can be reduced.

The transistor included in the switch circuit 650 is required to have high withstand voltage. One of effective ways of increasing the withstand voltage of the transistor is to increase the thickness of a gate insulating film. In this manner, the transistors 611 and 621 are required to have different performances. Thus, different measures for improving the characteristics are required for the transistors 611 and 621.

The functional circuit 640 is required to be scaled down and thinned. Thus, when the switch circuit 650 and the functional circuit 640 are formed with the same process node, not only a lead wiring but also a wiring for supplying power (power supply line) becomes thin, so that sufficient power cannot be supplied to the functional circuit 640. In addition, scaling down increases the wiring resistance to easily cause unevenness of the power supply potential in the functional circuit 640 due to a voltage drop. To stably supply power to the functional circuit 640, the wiring included in the switch circuit 650 preferably has a lower wiring resistance than the wiring included in the functional circuit 640. In particular, the wiring functioning as a power supply line preferably has a lower wiring resistance than the wiring included in the functional circuit 640. One of effective ways of reducing the wiring resistance is to increase the cross-sectional area of a conductive layer functioning as a wiring. Note that in order to increase the cross-sectional area of the conductive layer, it is necessary to increase one or both of the width and the height of the conductive layer. In view of the above, different process nodes are suitably used for the functional circuit 640 and the switch circuit 650.

In the semiconductor device 600 of one embodiment of the present invention, the functional circuit 640 and the switch circuit 650 are provided in different element layers, whereby different improvement measures can be taken for the functional circuit 640 and the switch circuit 650. The functional circuit 640 and the switch circuit 650 can be formed with different process nodes.

In one embodiment of the present invention, a plurality of conductive layers 622 functioning as power supply lines and the switch circuit 650 can be placed under the functional circuit 640, so that the area occupied by the semiconductor device 600 can be reduced. The element layer 620 provided to overlap with the element layer 610 is preferably formed by a thin film formation technique such as a CVD method or a sputtering method. Thus, the transistor 621 included in the element layer 620 is preferably a thin film transistor.

At least some of the plurality of conductive layers 622 included in the element layer 620 can function as a power supply line. In the case where the element layer 620 includes a clock signal generation circuit, at least some of the plurality of conductive layers 622 can function as a clock signal line. One or both of power supply and a clock signal that are supplied from the outside can be supplied to the functional circuit 640 included in the element layer 610 through at least some of the plurality of conductive layers 622.

For example, it is possible to manufacture a die (a semiconductor chip) including the functional circuit 640 and a die including the switch circuit 650 separately to be mechanically bonded to each other by a three-dimensional integration technique. However, a reduction in the pitch of a connection portion is difficult to achieve in the three-dimensional integration technique because the dies are mechanically bonded to each other, which makes it difficult to improve the alignment accuracy, and the size of a bump used for connecting the dies is difficult to reduce, for example. As a result, there is a problem in that the wiring lead distance for supplying power to an intended portion of the functional circuit 640 is difficult to be shortened.

In one embodiment of the present invention, the element layer 620 including the switch circuit 650 is formed on the rear surface side of the substrate 612 by a thin film formation technique and a photolithography technique, for example. Thus, the semiconductor device 600 of one embodiment of the present invention is a semiconductor device having a monolithic stacked-layer structure.

When the element layer 620 is formed with use of a thin film formation technique, alignment with high accuracy at a photolithography level can be achieved. Furthermore, the conductive layer functioning as a power supply line can be connected to an intended portion of the functional circuit 640 with an extremely short distance. Thus, power with a required voltage can be supplied to an intended portion of the functional circuit 640. In the semiconductor device 600 of one embodiment of the present invention, the connection distance between the switch circuit 650 and the functional circuit 640 is short; thus, power loss due to power transmission is reduced, so that power consumption can be reduced.

At least part of this embodiment can be implemented as appropriate in combination with any of the other embodiments described in this specification.

### Embodiment 9

In this embodiment, application examples of the semiconductor device of one embodiment of the present invention will be described. The semiconductor device of one embodiment of the present invention can be used for an electronic component, an electronic apparatus, a large computer, space equipment, and a data center (also referred to as DC), for example. An electronic component, an electronic apparatus, a large computer, space equipment, and a data center each using the semiconductor device of one embodiment of the present invention are effective in achieving high performance, e.g., reducing power consumption.

An electronic component or the like employing the semiconductor device of one embodiment of the present invention can be employed for the electronic apparatus exemplified in Embodiment 7.

### [Electronic Component]

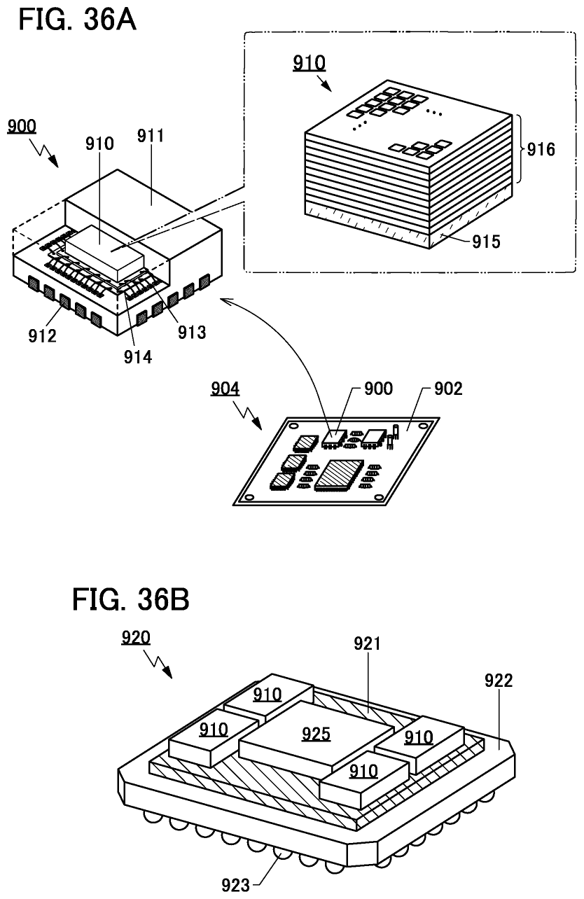

FIG. 36A is a perspective view of a substrate (a mounting board 904) on which an electronic component 900 is mounted. The electronic component 900 illustrated in FIG. 36A includes a semiconductor device 910 in a mold 911. FIG. 36A omits illustrations of some parts to show the inside of the electronic component 900. The electronic component 900 includes lands 912 outside the mold 911. The land 912 is electrically connected to an electrode pad 913, and the electrode pad 913 is electrically connected to the semiconductor device 910 via a wire 914. The electronic component 900 is mounted on a printed circuit board 902, for example. A plurality of such electronic components are combined and electrically connected on the printed circuit board 902, so that the mounting board 904 is completed.

The semiconductor device 910 includes a driver circuit layer 915 and a memory layer 916. Note that the memory layer 916 has a structure where a plurality of memory cell arrays are stacked. A stacked-layer structure of the driver circuit layer 915 and the memory layer 916 can be a monolithic stacked-layer structure. In the monolithic stacked-layer structure, layers can be connected without using a through electrode technique such as a through silicon via (TSV) technique and a bonding technique such as Cu-to-Cu direct bonding. The monolithic stacked-layer structure of the driver circuit layer 915 and the memory layer 916 enables, for example, what is called an on-chip memory structure where a memory is directly formed on a processor. The on-chip memory structure allows an interface portion between the processor and the memory to operate at high speed.

With the on-chip memory structure, the size of a connection wiring and the like can be made smaller than that when the technique using through electrodes such as TSVs is employed; thus, the number of connection pins can be increased. The increase in the number of connection pins enables parallel operation, which can improve the bandwidth of the memory (also referred to as memory bandwidth).

It is preferable that the plurality of memory cell arrays included in the memory layer 916 be formed using OS transistors and be monolithically stacked. The monolithic stacked-layer structure of a plurality of memory cell arrays can improve one or both of the bandwidth of the memory and the access latency of the memory. Note that the bandwidth refers to the data transfer amount per unit time, and the access latency refers to a period of time from data access to the start of data transmission. In the case where Si transistors are used for the memory layer 916, the monolithic stacked-layer structure is difficult to form as compared with the case where OS transistors are used for the memory layer 916. Therefore, OS transistors are superior to Si transistors in the monolithic stacked-layer structure.

The semiconductor device 910 may be called a die. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Examples of semiconductor materials usable for the die include silicon (Si), silicon carbide (SiC), and gallium nitride (GaN). For example, a die obtained from a silicon substrate (also referred to as a silicon wafer) is referred to as a silicon die in some cases.

FIG. 36B is a perspective view of an electronic component 920. The electronic component 920 is an example of a system in package (SiP) or a multi-chip module (MCM). In the electronic component 920, an interposer 921 is provided on a package substrate 922 (a printed circuit board), and a semiconductor device 925 and a plurality of semiconductor devices 910 are provided on the interposer 921.

The electronic component 920 using the semiconductor devices 910 as high bandwidth memories (HBM) is illustrated as an example. The semiconductor device 925 can be used for an integrated circuit such as a CPU, a GPU, or a field programmable gate array (FPGA).

As the package substrate 922, a ceramic substrate, a plastic substrate, or a glass epoxy substrate can be used, for example. As the interposer 921, a silicon interposer or a resin interposer can be used, for example.

The interposer 921 includes a plurality of wirings and has a function of electrically connecting a plurality of integrated circuits with different terminal pitches. The plurality of wirings are provided in a single layer or multiple layers. The interposer 921 also has a function of electrically connecting an integrated circuit provided on the interposer 921 to an electrode provided on the package substrate 922. Accordingly, the interposer is sometimes referred to as a “redistribution substrate” or an “intermediate substrate”. In some cases, a through electrode is provided in the interposer 921 to be used for electrically connecting an integrated circuit and the package substrate 922. In a silicon interposer, a TSV can also be used as the through electrode.

In an HBM, many wirings need to be connected to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in the expansion coefficient between an integrated circuit and the interposer is less likely to occur. Furthermore, a surface of a silicon interposer has high flatness, so that poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Accordingly, in the case where the size of the electronic component 920 is to be reduced, the width of the terminal pitch becomes an issue, which sometimes makes it difficult to provide a large number of wirings for achieving a wide memory bandwidth. For this reason, the monolithic stacked-layer structure using the OS transistors is suitable, as described above. A composite structure where memory cell arrays stacked using a TSV and monolithically stacked memory cell arrays are combined may be employed.

A heat sink (a radiator plate) may be provided to overlap with the electronic component 920. In the case where a heat sink is provided, integrated circuits provided on the interposer 921 preferably have the same height. For example, in the electronic component 920 described in this embodiment, the semiconductor devices 910 and the semiconductor device 925 preferably have the same height.

Electrodes 923 may be provided on a bottom part of the package substrate 922 to mount the electronic component 920 on another substrate. FIG. 36B illustrates an example in which the electrodes 923 are formed of solder balls. When the solder balls are provided in a matrix on the bottom part of the package substrate 922, ball grid array (BGA) mounting can be achieved. Alternatively, the electrodes 923 may be formed of conductive pins. When the conductive pins are provided in a matrix on the bottom part of the package substrate 922, pin grid array (PGA) mounting can be achieved.

The electronic component 920 can be mounted on another substrate by a variety of mounting methods other than BGA and PGA. Examples of mounting methods include staggered pin grid array (SPGA), land grid array (LGA), quad flat package (QFP), quad flat J-leaded package (QFJ), and quad flat non-leaded package (QFN).

### [Large Computer]

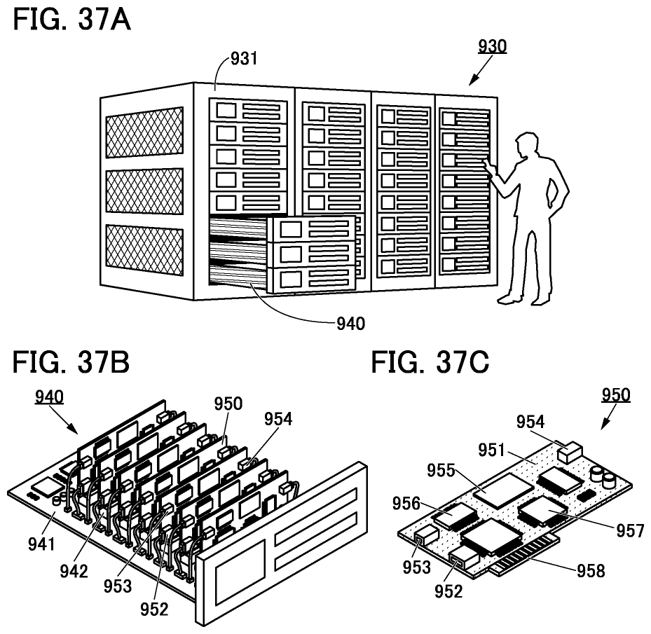

FIG. 37A is a perspective view of a large computer 930. In the large computer 930, a plurality of rack mount computers 940 are stored in a rack 931. Note that the large computer 930 may also be referred to as a supercomputer.

FIG. 37B is a perspective view of an example of the computer 940. The computer 940 includes a motherboard 941. The motherboard 941 is provided with a plurality of slots 942 and a plurality of connection terminals. A PC card 950 is inserted in the slot 942. In addition, the PC card 950 includes a connection terminal 952, a connection terminal 953, and a connection terminal 954, each of which is connected to the motherboard 941.

FIG. 37C illustrates an example of the PC card 950. The PC card 950 is a processing board provided with a CPU, a GPU, a memory device, and the like, for example. The PC card 950 includes a board 951, and components mounted on the board 951, such as the connection terminal 952, the connection terminal 953, the connection terminal 954, an electronic component 955, an electronic component 956, an electronic component 957, and a connection terminal 958. Note that FIG. 37C illustrates the electronic components 955, 956, and 957 and the other components.

The connection terminal 958 has a shape that can be inserted in the slot 942 of the motherboard 941, and the connection terminal 958 functions as an interface for connecting the PC card 950 and the motherboard 941. An example of the standard for the connection terminal 958 is PCIe.

The connection terminals 952, 953, and 954 can each serve as, for example, an interface for performing power supply, signal input, or the like to the PC card 950. As another example, the connection terminals 952, 953, and 954 can each serve as an interface for outputting a signal calculated by the PC card 950. Examples of the standard for each of the connection terminals 952, 953, and 954 include Universal Serial Bus (USB), Serial ATA (SATA), and Small Computer System Interface (SCSI). In the case where video signals are output from the connection terminals 952, 953, and 954, an example of the standard therefor is HDMI (registered trademark).

The electronic component 955 includes a terminal (not illustrated) for inputting and outputting signals, and when the terminal is inserted in a socket (not illustrated) of the board 951, the electronic component 955 and the board 951 can be electrically connected to each other.

The electronic components 956 and 957 each include a plurality of terminals, and when the terminals are reflow-soldered, for example, to wirings of the board 951, the electronic components 956 and 957 can be mounted. Examples of the electronic component 956 include an FPGA, a GPU, and a CPU. The electronic component 920 can be used as the electronic component 956, for example. An example of the electronic component 957 is a memory device. The electronic component 900 can be used as the electronic component 957, for example.

The large computer 930 can also function as a parallel computer. When the large computer 930 is used as a parallel computer, large-scale computation necessary for artificial intelligence learning and inference can be performed, for example.

At least part of this embodiment can be implemented as appropriate in combination with any of the other embodiments described in this specification.

This application is based on Japanese Patent Application Serial No. 2025-078691 filed with Japan Patent Office on May 9, 2025, the entire contents of which are hereby incorporated by reference.

What is claimed is:

1. A semiconductor device comprising:
a first metal oxide layer;
a second metal oxide layer;
a first insulating layer; and
a conductive layer,
wherein the first insulating layer is over the first metal oxide layer,
wherein the conductive layer is over the first insulating layer,
wherein the second metal oxide layer is in contact with the first metal oxide layer,
wherein the first metal oxide layer comprises indium, and
wherein the second metal oxide layer comprises indium and divalent silicon oxide.

2. A semiconductor device comprising:
a first metal oxide layer;
a second metal oxide layer;
a first insulating layer; and
a conductive layer,
wherein the first insulating layer is over the first metal oxide layer,
wherein the conductive layer is over the first insulating layer,
wherein the second metal oxide layer is in contact with the first metal oxide layer,
wherein the first metal oxide layer comprises indium, and
wherein the second metal oxide layer comprises indium and divalent silicon.

3. The semiconductor device according to claim 1,
wherein the second metal oxide layer is below the first metal oxide layer.

4. The semiconductor device according to claim 3, further comprising a third metal oxide layer between the first metal oxide layer and the first insulating layer,
wherein the third metal oxide layer has a lower electron affinity than the first metal oxide layer.

5. The semiconductor device according to claim 4,
wherein the third metal oxide layer comprises indium and gallium.

6. The semiconductor device according to claim 3, further comprising a second insulating layer in contact with a bottom surface of the second metal oxide layer,
wherein the second insulating layer comprises silicon and oxygen.

7. The semiconductor device according to claim 2,
wherein the second metal oxide layer is below the first metal oxide layer.

8. The semiconductor device according to claim 7, further comprising a third metal oxide layer between the first metal oxide layer and the first insulating layer,
wherein the third metal oxide layer has a lower electron affinity than the first metal oxide layer.

9. The semiconductor device according to claim 8,
wherein the third metal oxide layer comprises indium and gallium.

10. The semiconductor device according to claim 7, further comprising a second insulating layer in contact with a bottom surface of the second metal oxide layer,
wherein the second insulating layer comprises silicon and oxygen.

11. The semiconductor device according to claim 1,
wherein the second metal oxide layer is between the first metal oxide layer and the first insulating layer.

12. The semiconductor device according to claim 2,
wherein the second metal oxide layer is between the first metal oxide layer and the first insulating layer.

13. A method for manufacturing a semiconductor device, comprising the steps of:
a first step of forming a first insulating layer comprising silicon and oxygen;
a second step of forming a first metal oxide layer over the first insulating layer; and
a third step of forming a second metal oxide layer over the first metal oxide layer,
wherein during the second step, divalent silicon oxide is added to the first metal oxide layer.

14. The method for manufacturing a semiconductor device according to claim 13,
wherein each of the first metal oxide layer and the second metal oxide layer is formed by a sputtering method using an indium oxide sputtering target, and
wherein the first metal oxide layer is formed at a higher power than the second metal oxide layer.

15. The method for manufacturing a semiconductor device according to claim 13,
wherein the first metal oxide layer is formed by a sputtering method using an indium oxide sputtering target, and
wherein the second metal oxide layer is formed by an atomic layer deposition method using an oxidizer and a precursor comprising indium.

16. The method for manufacturing a semiconductor device according to claim 13,
wherein each of the first metal oxide layer and the second metal oxide layer is formed by an atomic layer deposition method using an oxidizer and a first precursor comprising indium, and
wherein delta doping is performed in forming the first metal oxide layer.

17. The method for manufacturing a semiconductor device according to claim 15,
wherein the second step comprises:
a fourth step of introducing the first precursor and introducing the oxidizer after the introduction of the first precursor; and
a fifth step of introducing a second precursor comprising silicon, and wherein the fifth step is performed a smaller number of times than the fourth step.
